(19) United States
(12) Patent Application Publication
(10) Pub. No.: US 2005/0029666 A1
(43) Pub. Date: Feb. 10, 2005

(54) Semiconductor device structural body and electronic device

(76) Inventors: Yasutoshi Kurihara, Hitachinaka (JP); Yoshimasa Takahashi, Hitachi (JP); Tsuneo Endoh, Komoro (JP); Mikio Negishi, Komoro (JP); Masashi Yamaura, Komoro (JP); Hirokazu Nakajima, Saku (JP); Yosuke Sakurai, Yokohama (JP); Hironori Kodama, Mito (JP)

Correspondence Address: Crowell & Moring, 1001 Pennsylvania Avenue NW, Washington, DC, 20004-2595, US

(21) Appl. No.: 10/487,990

(22) PCT Filed: Aug. 27, 2002
(86) PCT No.: PCT/JP02/08631

(30) Foreign Application Priority Data
Aug. 31, 2001 (JP) 2001-262647

(51) Int. Cl. H01L 23/48

(52) U.S. Cl. 257/772

(57) ABSTRACT

A semiconductor device, in which a solder layer bonding chip parts and wiring members are enclosed with the resin layer, and the solder layer is comprised of a compound body in which metal powder is distributed in the matrix metal, is disclosed. When a semiconductor device in which the chip parts are installed in the wiring member with the solders, the soldering part is sealed with the resin is mounted secondly on the external wiring member, the outflow of the solders and the short circuit due to the outflow, the disconnections, and the displacement of the chip parts can be prevented.

### TECHNICAL FIELD

The present invention relates to a semiconductor device in which the circuit elements (chip parts) installed on a wiring member are sealed with resin.

### BACKGROUND ART

The Japanese Patent Application Laid-Open No. 6-61417 discloses a semiconductor device in which one or more semiconductor devices are fixed to predetermined conductive pattern formed on the first main respect of electric non-conductivity substrate made by alumina, and are sealed with resin. The Japanese Patent Application Laid-Open No. 7-235565 discloses an electric circuit device which has a wiring substrate, and circuit parts connected electrically onto the wiring substrate through a bump comprising solder, in which solid corpuscles to control the height of the bump in said bump are distributed. Here, the bump is Pb—Sn system alloy with the melting point of 183° C. Moreover, the solid corpuscle is Cu, Fe, Ni, Pt, Ag, these alloys, the stainless steel balls, Mo powder, and the resin-coating metal powder. Intermetallic compound with Sn grows up on the surface of each solid corpuscle and unites when the chip parts are soldered by using such a solders. Therefore, the adjustment of the height of the bump is easy, and even when the balance of surface tension of the bump collapses at the chip component mounting, it is possible to prevent the chip parts from being equipped at a tilt.

It is desired to substitute the Pb—Sn system alloy material that has been applied for the equipment of electronic parts so far with the Pb free alloy from the viewpoint of the environmental protection in recent years. The Pb free solders suitable for the practical use is the alloy which contains an overwhelming amount of Sn, of which melting point is 240° C. or less. The problem of the short circuit and the disconnection of wiring, and the displacement of the chip parts is caused by the re-melting of the solders of the semiconductor device at the second mounting to external wiring substrates etc. when the Pb free solders is applied in the resin-sealed type semiconductor device in which chip parts are installed on the substrate by using the solders.

In the invention disclosed in the above-mentioned Japanese Patent Application Laid-Open No. 6-61417, the re-melting of the solder layer caused when the solders for first mounting is sealed up with the sealing material and the short circuit of an internal circuit due to the remelting and the deterioration in the circuit functions is not considered.

Moreover, although it is possible to prevent the chip parts from being equipped at a tilt and to adjust the height of the bump by the solid corpuscle and the intermetallic compound which grows up to its surface in the electric circuit device disclosed in the above-mentioned Japanese Patent Application Laid-Open No. 7-235565, the solution means for the above-mentioned problems in the system where the solders for the first mounting is sealed up with the above-mentioned sealing material is not given.

Moreover, because the solder matrix in the preceding technology is Pb—Sn system alloy, it is not possible to correspond to making the above-mentioned Pb free.

### DISCLOSURE OF INVENTION

An object of the present invention is to provide a semiconductor device which can prevent from the outflow of the first mounting solders, and the short circuit, the disconnecting and the displacement of the chip parts due to the outflow when the semiconductor device where the chip parts as a circuit element are installed on the substrate, and the chip parts installed are sealed up with resin is installed in an external wiring substrate, a structural body using the semiconductor device, or an electronic equipment using them.

In the semiconductor device of the present invention, a solder layer bonding chip parts and wiring members are enclosed with the resin layer, and the solder layer is comprised of a compound body in which metal powder is distributed in the matrix metal.

In the structural body of the present invention, a semiconductor device, in which a solder layer bonding chip parts and wiring members are sealed with the resin layer and the solder layer is comprised of a compound body in which metal powder is distributed in the matrix metal, is bonded to an external wiring member through a connection layer.

In the electronic equipment of the present invention, a semiconductor device, in which a solder layer bonding chip parts and wiring members are enclosed with the resin layer and the solder layer is comprised of a compound body in which metal powder is distributed in the matrix metal, or a structural body in which said semiconductor device is bonded to an external wiring member through a connection layer is built, is installed.

Here, the accumulator device, the high-frequency power amplifying device, the electric power measuring device, the liquid crystal display device or the converter device, etc. are enumerated for instance as an electronic equipment.

### BRIEF DESCRIPTION OF THE DRAWINGS

FIG. 1 is a diagrammatic sectional view of the semiconductor device of the present invention.

FIG. 2 is a diagrammatic sectional view of the solder layer applied to the semiconductor device of the present invention.

FIG. 3 is a diagrammatic sectional view showing the problem when the solder layer comprises only the matrix metal.

FIG. 4 is a graph illustrating the decrease of the melting point when Au is fused to Sn-10 wt % Sb solders.

FIG. 5 is a graph illustrating the decrease of the melting point when Sn is fused to Pb-12 wt % Sn-8 wt % Sb-1 wt % Ag solders.

FIG. 6 is a diagrammatic sectional view of the structural body according to the present invention.

FIG. 7 is a graph illustrating the influence of the particle size of W powder on the short circuit rejection rate after the second mounting of a semiconductor device.

FIG. 8 is a graph illustrating the influence of the amount of addition of W powder on the short circuit rejection rate after the second mounting of a semiconductor device.

FIG. 9 is a graph where the influence of the amount of addition of W powder on the disconnection defect rate of the present invention structural body.

FIG. 10 is a diagrammatic sectional view of the lithium ion accumulator that is one example of the present invention electronic equipment.

FIG. 11 is a circuit block diagram of the semiconductor device built into the lithium ion accumulator that is one example of the electronic equipment.

FIG. 12 is a view showing the multi-layer glass ceramics substrate applied to one embodiment semiconductor device.

FIG. 13 is a sectional view showing the manufacture process of a semiconductor device.

FIG. 14 is a graph illustrating the short circuit rejection rate of the structural body where the semiconductor device exposed to the high temperature high humidity atmosphere is applied.

FIG. 15 is a circuit block diagram of the electric power multiplication circuit arrangement as the semiconductor device of one embodiment.

FIG. 16 is a block diagram of the magnetic field generation part.

FIG. 17 is a diagrammatic sectional view showing the high frequency power module as another embodiment semiconductor device.

FIG. 18 is a circuit diagram showing another embodiment semiconductor device.

FIG. 19 is a diagrammatic sectional view showing a structural body for the cellular phone.

FIG. 20 is a circuit block diagram of the cellular phone where another embodiment structural body is applied.

FIG. 21 is a graph illustrating the disconnection defect rate and the thermal resistance increase defect rate in another embodiment structural body.

FIG. 22 is a diagrammatic sectional view showing the high frequency power module as another embodiment semiconductor device.

FIG. 23 is a diagrammatic sectional view showing a structural body for the cellular phone.

FIG. 24 is a diagrammatic sectional view showing another embodiment semiconductor device.

FIG. 25 is a diagrammatic sectional view showing another embodiment structural body.

FIG. 26 is a diagrammatic sectional view showing another embodiment semiconductor device and a structural body using the same.

FIG. 27 is a diagrammatic sectional view showing the CSP type semiconductor device in another form.

FIG. 28 is a diagrammatic sectional view showing another embodiment semiconductor device and a structural body using the same.

FIG. 29 is a diagrammatic sectional view showing another embodiment semiconductor device and a structural body using the same.

FIG. 30 is a diagrammatic sectional view showing another embodiment semiconductor device and a structural body using the same.

FIG. 31 is a diagrammatic sectional view showing the example of the modified structural body according to another embodiment.

FIG. 32 is a diagrammatic sectional view showing a semiconductor device of another embodiment and a structural body using the same.

FIG. 33 is a diagrammatic sectional view showing the COC type semiconductor device according to another form.

FIG. 34 is a diagrammatic sectional view showing a semiconductor device of another embodiment and a structural body using the same.

FIG. 35 is an illustration of a circuit of the semiconductor device according to another invention.

FIG. 36 is a graph showing the relationship between the output current and the conversion efficiency in the structural body according to another embodiment.

FIG. 37 is a diagrammatic sectional view showing the semiconductor device according to another embodiment.

FIG. 38 is a graph showing the transition of thermal resistance in the heat cycle test of the semiconductor device of another embodiment.

FIG. 39 is a graph showing the transition of thermal resistance in the power cycle test on the semiconductor device of another embodiment.

FIG. 40 is a plan and a sectional view showing the full-wave rectification device.

FIG. 41 is a circuit diagram showing the full-wave rectifier of the structural body according to another embodiment.

FIG. 42 is a diagrammatic sectional view showing the full-wave rectification device in another form.

FIG. 43 is a diagrammatic sectional view showing the semiconductor device according to another embodiment and the structural body using the same.

FIG. 44 is a plane view and a diagrammatic sectional view showing the power module device in another form.

FIG. 45 is a view showing the form of the solders of the present invention.

### BEST MODE FOR CARRYING OUT THE INVENTION

(Embodiment 1)

Semiconductor device 11 is explained in this embodiment.

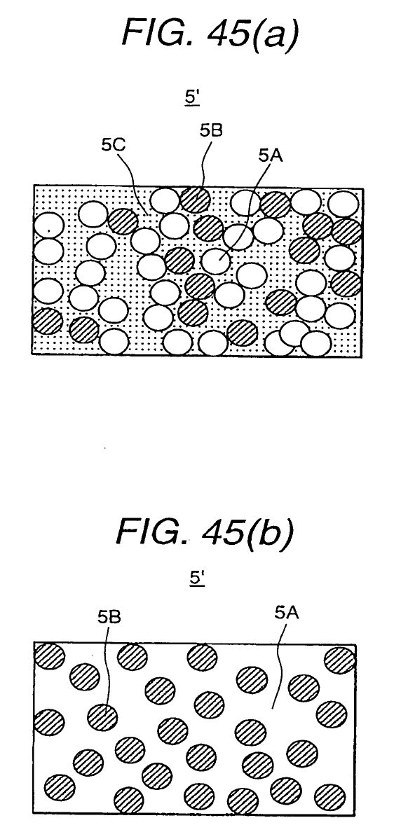

FIG. 45 shows a diagrammatic illustration explaining the form of the solders of the present invention.

FIG. 45(a) shows pasty solders 5′ according to a first form. The pasty solders 5′ is the composition made by mixing metal powder (particle size: 15-60. m) 5A for matrix metal comprised of Sn-5 wt % Sb alloy (melting point: 230-240° C.) which becomes the matrix metal after heat-treating of soldering, metal powder (particle size: 15-50 μm and melting point: 779° C.) 5B for dispersion which contains Ag-28 wt % Cu as principal ingredient, and flux material 5C which contains organic substance [weight ratio: WW rosin (100)-adipic acid (1)-tori ethanol amine (1)-aniline hydrochloride (2)]. The amount of addition of the flux material 5C to solders 5′ is about 11 wt %.

Moreover, the amount of addition is adjusted so that metal powder 5B for dispersion may occupy 50 vol % after heat-treating of soldering. The amount of addition is adjusted so that metal powder 5A for matrix metal may also occupy 50 vol % after heat-treating of soldering. Paste solders 5′ explained above is supplied to the desired connection part by the print method, the dispense method, etc. The soldering processing is done in the foaming gas where hydrogen is added to nitrogen, in nitrogen, or in air.

(b) shows sheet-like or ribbon-like solders 5′ according to a second form.

Sheet-like solders 5′ comprises matrix metal 5A comprised of Sn-5 wt % Sb alloy (melting point: 230 to 240° C.) beforehand, and metal powder 5B (particle size: 15 to 50 μm and melting point: 779° C.) for dispersion that contains Ag-28 wt % Cu distributed in matrix metal 5A as the principal ingredient.

The amount of addition is adjusted so that matrix metal 5A may occupy 50 vol % after heat-treating of soldering, and similarly, the amount of addition is adjusted so that metal powder 5B for dispersion may occupy 50 vol % after heat-treating of soldering. Sheet-like solders 5′ explained above is supplied to insert between the members to be connected part. The soldering processing is done in the foaming gas where hydrogen is added to nitrogen, in nitrogen, or in air. The operation, the effect, and the advantage not obtained by the conventional solders can be brought according to the above-mentioned solders 5′ as described later in connection with the semiconductor device of the present invention.

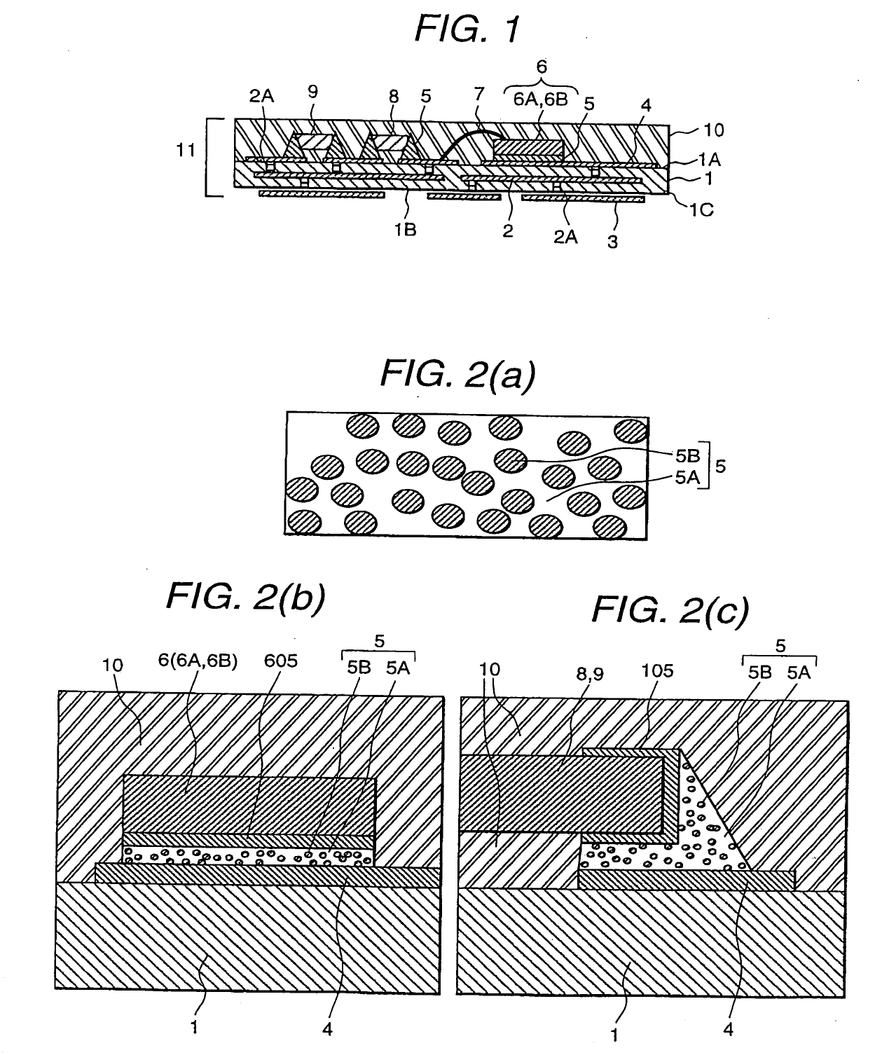

FIG. 1 is a diagrammatic sectional view showing the semiconductor device of this embodiment. Semiconductor device 11 comprises as follows. Substrate 1 which becomes a wiring member is a multi-layer glass ceramics substrate (low temperature baking substrate). Internal layer wiring layer (Ag-1 wt % Pt) 2 and wiring (Ag-1 wt % Pt) of a through hole 2A is provided in substrate 1. Wiring pattern (Ag-1 wt % Pt) 4 is provided on the first main respect 1A of substrate 1. The chip parts comprised of semiconductor device base body (Si, 3.5 ppm/° C.) 6 which contains the integrated circuit element base body 6A (not shown) and FET element base body 6B, chip resistor (about 7 ppm/° C. 8, and capacitor 9 (about 11.5 ppm/° C.) are bonded electrically on this wiring pattern 4 with solder layer 5 (the first mounting soldering). Solder layer 5 comprises the compound body where W powder 5B (particle size: 1 μm) is distributed to matrix metal 5A comprised of Sn-5 wt % Sb alloy as shown in FIG. 2. Moreover, the amount of addition of W powder 5B is adjusted to 50 vol %. Moreover, thin metallic wire 7 comprised of Au is bonded between predetermined parts of semiconductor device base body 6 and wiring pattern 4 (integrated circuit element base body 6A: diameter 27 μm and FET element base body 6B: diameter 50 μm). Chip parts, thin metallic wires 7, and the first main respect 1A are is completely sealed so as to be intercepted from ambient air by resin layer 10 (physical properties after hardening: coefficient of thermal expansion; 9.0 ppm/° C. and Young's modulus: 24.5 GPa and glass transition point: 150° C. and amount of addition of filler: 85 wt %) whose principal ingredient is epoxy material. External electrode layer (Ag-1 wt % Pt) 3 is provided to the first main respect 1A of multi-layer ceramics substrate 1 and the second main respect 1B on the other side. External electrode layer 3 is connected electrically to wiring pattern 4 through internal layer wiring layer 2 and through hole wiring 2A provided inside of multi-layer ceramics substrate 1. The chip parts comprised of semiconductor device base body 6 which contains the integrated circuit element base body 6A and FET element base body 6B, chip resistor 8, and capacitor 9 are bonded electrically on wiring pattern 4 with solder layer 5. Therefore, external electrode layer 3 is connected electrically to these chip parts. Here, internal layer wiring layer 2 and the through hole wiring 2A are laid to an internal area of multi-layer ceramics substrate 1. Moreover, the Ni plating layer and the Au plating layer are provided to the surfaces of wiring pattern 4 and external electrode layer 3 in order though they are not shown in figure. Moreover, the Ni plating layer and Sn plating layer are provided to the electrode of chip resistance 8 and capacitor 9 in order. Each chip part is completely enclosed with substrate 1, wiring pattern 4, and resin layer 10 as explained above. Solder layer 5 bonding these chip parts is completely enclosed with chip parts 6, 8, 9, wiring pattern 4, and resin layer 10.

Next, solder layer 5 is explained. FIG. 2A and FIG. 2B show diagrammatic sectional views of the solder layer applied to the semiconductor device of this embodiment. FIG. 2A is a diagrammatic illustration of solder layer 5. The solder layer has the composition where metal powder 5B composed of W (mean diameter: about 1 μm) is distributed to matrix metal 5A comprised of Sn-5 wt % Sb alloy (melting point: 230 to 240° C.). The amount of addition of W metal powder 5B is 50 vol %, and the matrix metal occupies 50 vol % of the remainder.

FIG. 2B is an enlarged diagrammatic sectional view of the part equipped with semiconductor device base body 6 (6A and 6B). Semiconductor device base body 6 is bonded electrically to wiring pattern 4 on substrate 1 with solder layer 5 having the composition shown in FIG. 2A. Substrate 1, wiring pattern 4, semiconductor device base body 6 (6A, 6B), and solder layer 5 are sealed by resin layer 10. The Ni plating layer (5 μm, not shown) and the Au plating layer (1 μm, not shown) are provided to the surface of wiring pattern 4 in order. Here, Ti(0.15 μm)-Ni (0.6 μm)-Au(0.2 μm) accumulating metal layer 605 is formed on the side to be bonded of semiconductor device base body 6 (6A, 6B) by the deposition.

FIG. 2C is an enlarged diagrammatic sectional view in the part equipped with chip resistance 8 and capacitor 9. Chip resistance 8 and capacitor 9 are also bonded electrically to wiring pattern 4 on substrate 1 with solder layer 5 having the composition of (a). Here, electrode 105 comprised of Ag thickness film is provided to chip resistance 8 and capacitor 9. Ni plating layer (5 μm) and Sn plating layer (1 μm) are provided in order on the surface of the Ag thickness film though they are not shown in figure. However, Au plating layer on wiring pattern 4, Au layer on accumulating metal layer 605 and Sn plating layer on electrode 105 fuses in solder layer 5 after chip parts 6, 8, and 9 are bonded (the first mounting soldering). Substrate 1, wiring pattern 4, chip resistance 8, capacitor 9, and solder layer 5 are sealed with resin layers 10.

A special feature point of the present invention is in that surroundings of solder layer 5 are completely enclosed with other solid materials, and metal powder 5B is distributed to matrix metal 5A. Solders 5 does not flow substantially even when semiconductor device 11 is heated to the temperature at which the matrix 5A melts in the following process (the second mounting soldering) because of such configuration of solder layer 5, and the liquidity of the solders is prevented and the short circuit, the displacement of the chip parts and the deterioration of the chip parts due to heat radiation is evaded. These are important points in the present invention. Moreover, metal powder 5B comprises a material (Ag—Cu alloy) easy to be wetted by matrix metal 5A. The advantage not obtained easily by combining metal powders such as Cu and Ni and the matrix metal whose principal ingredient is Sn is brought by this.

This point is explained by an example of pasty solders 5′ shown in FIG. 45(a). The surface cleaning of metal powder 5B (especially, removal of surface oxide film) by the flux material 5C progresses at the same time as the melting and uniting of the matrix metal powder 5A reached the melting point by rising temperature. That is, the uniting of matrix metal 5A and metal powder 5B (melted matrix metal 5A gets wet on the surface of metal powder 5B) is completed instantaneously. As a result, metal powder 5B comes to stay easily in melted matrix metal and the filling rate of metal powder 5B is increase, because the liquidity and the removal to the outside the system by the flux material 5C of metal powder 5B is controlled. The filling rate of metal powder 5B being increased in the present invention solders 5′ originates the fact that metal powder 5B is easy to be wetted by matrix metal. The surface of the matrix metal powder 5A and metal powder 5B is cleaned almost at the same time at the stage where the chemical revitalization degree of the flux material 5C increases, and the surface oxide film removal progresses almost at the same time, too. As a result, the wet reaction to the surface of metal powder 5B by matrix metal 5A progresses instantaneously at the same time as the melting and the uniting of the matrix metal powder 5A, too. At this time, accumulating metal layer 605, electrode 105, and wiring pattern 4 in the part to be connected are cleaned by the flux material 5C, and the bonding with melted matrix metal 5A is performed excellently. On the other hand, when the pasty solders where metal powders such as Cu and Ni is added, low molecular element in the flux material 5C volatilizes by rising temperature and the organic constituent with large molecular weight remains. The melt of the matrix metal powder that reaches the melting point and the uniting between powders advances at the same time. At this time, the chemical revitalization degree of the flux material 5C increases, too and the surface of the matrix metal powder is cleaned (especially, removal of surface oxide film). However, the surface cleaning does not progress easily for the metal powder comprised of single metal such as Cu and Ni. The oxide film on the surface of the powders of Cu and Ni is not removed completely at the stage where the melting and the uniting of the matrix metal powder are concluded. As a result, because the Cu and Ni powders flow with the flux material 5C, and are removed to the outside the system, they come not to stay easily in the melted matrix metal. This phenomenon becomes more remarkable as the amount of the filling of the Cu and Ni powders increase.

Even when metal powders 5B other than Sn-5 wt % Sb alloy are added, the same effect as the solders of the present invention can be obtained. For instance, the following alloy powder can be used. Alloy powder 5B of Sn-40 wt % Sb-10 wt % Ag-8 wt % Cu, Ag-20.4 wt % Cu-13.6 wt % Zr, Ag-44 wt % Cu, or (25-66 wt %)Sn-(22-70 wt %)Sb-(4.5-31 wt %)Ag-(2.3-18 wt %)Cu, and alloy powder 5B which contains one kind of metal or more selected from a group of Sn, Au, Fe, Ge, Mn, Ni, Sb, Si, Zn, Pd, Pt, P, Pb, and Al with Cu as well as Ag and/or Cu as the principal ingredient, as shown in Table 3 described later.

Next, the problem when solder layer 5 comprises only the matrix metal is explained.

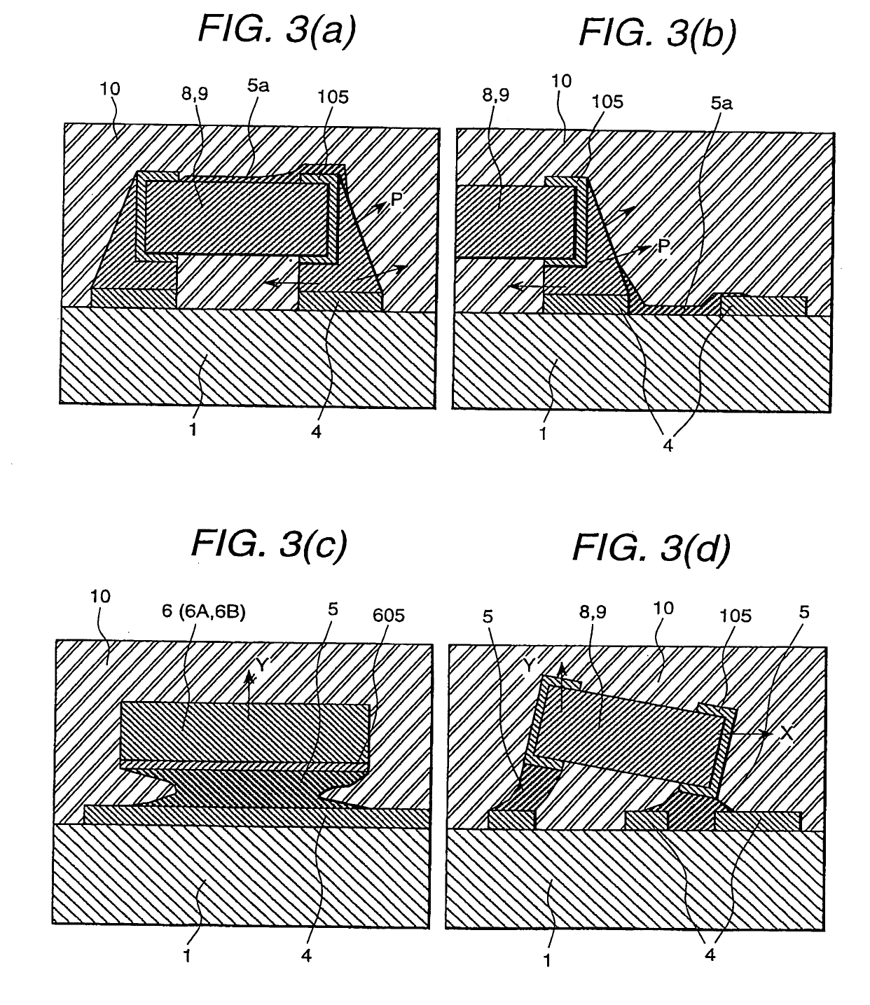

FIG. 3 is a diagrammatic sectional view illustrating the problem when the solder layer comprises of only the matrix metal. Here, (a) and (b) show the problem caused easily when sealed mainly by resin 10 (for instance, epoxy resin) with high Young's modulus. Moreover, (c) and (d) show the problem caused easily when sealed by resin 10 (for instance, gel resin) where the Young's modulus is low and the coefficient of thermal expansion is high.

(a) is a diagrammatic sectional views illustrating the state where the short circuit is occurred between electrodes of the chip parts due to the liquidity of the melted solder. Resin 10 in the neighborhood of chip parts 8 and 9 flakes off by the rising-up of internal pressure P (825 MPa) due to the re-melting of solder layer 5 (between the sealing resin and the chip parts). As a result, melted solders 5a flows out along the gap made. When this outflow advances, the short circuit is occurred between electrodes 105.

(b) is a diagrammatic sectional view illustrating the state when the short circuit is occurred between peripheral wiring patterns due to the liquidity of the melted solder. Resin 10 in the neighborhood of chip parts 8 and 9 flakes off by the rising-up of internal pressure P due to the re-melting of solder layer 5 (between the sealing resin and the substrate). As a result, melted solders 5a flows out along the gap made. When this outflow advances, the short circuit is occurred between wiring patterns 4.

(c) is a diagrammatic sectional view illustrating the state where the chip parts is lifted due to the liquidity of the melted solder and the thermal deformation of the sealing resin. This is a phenomenon caused easily when chip parts are semiconductor device base body 6 (6A, 6B). Semiconductor device base body 6 is lifted in the Y direction due to the external force based on the thermal deformation of resin 10, and, therefore, the fringing part in solder layer 5 is narrowed. As a result, solder layer 5 enters the state that the heat conduction is obstructed over the greater part of the area. Especially, the calorific value of FET element base body 6B is large, and the phenomenon of (c) becomes a trouble in the normal, electric operation.

(d) shows a phenomenon caused easily when chip parts are passive components 8 and 9. Parts 8 and 9 is lifted in the Y direction due to the external force based on the thermal deformation of resin 10, or moves in the X direction (displacement). Especially, when the displacement increases, the short circuit is occurred between wiring patterns 4 with the melted solders 5. Moreover, the solder layer 5 is cut out due to the increase of the displacement, and the cut-off is occurred between electrode 105 and wiring pattern 4 though not shown in figure.

Now, returning to FIG. 2 and keeping the explanation.

The volume expands by about 16% in the process that changes from the state of the solid phase into the state of the liquid phase when the matrix 5A melts again in the second mounting soldering process. On the other hand, because the melting point of metal powder 5B is higher than the matrix metal 5 and the state of the solid phase of metal powder 5B is maintained even if matrix metal 5A melts, the cubical expansion given by metal powder 5B is negligible. Because the volume rate which metal powder 5B occupies to solder layer 5 is 50 vol %, a substantial expansion of solder layer 5 is suppressed to about 8%. This value is one half of the case where the solder layer comprises only the matrix metal. The internal pressure caused in solder layer 5 by the cubical expansion of ½ is 413 Mpa (42 kgf/mm²), and it is decreased more greatly than 825 MPa (84.1 kgf/mm²) when the solder layer comprises only the matrix metal. As a result, because flaking off on the joint boundary face of the sealing resin is controlled, the outflow of the melted solders along the flaking off gap, and the short circuit (see FIG. 2(a) and (b)) of 105 and that of wiring pattern 4 are prevented. Moreover, even when the joint boundary face of the sealing resin flakes off and the flow of solder layer 5 starts, metal powder 5B piles up in a minute flaking off gap and has the role (clogging phenomena) to control the flow of melted matrix 5a.

The substantial cubical expansion becomes small even if solder layer 5 melts again by the existence of metal powder 5B which maintains the state of the solid phase as explained above in this embodiment, and the excessive rise of the internal pressure, the flaking off of the sealing resin, the outflow of melted solders and the short circuits are controlled. Further, the outflow of melted solders and the short circuit are controlled by the clogging phenomena of metal powder 5B.

In the present invention, sealing resin 10 which seals the chip parts installed in substrate 1 is not limited to the epoxy with high Young's modulus. For instance, when the chip parts are sealed by resin 10 where Young's modulus is low and the coefficient of thermal expansion is high like the silicone resin (Young's modulus: 11 GPa and coefficient of thermal expansion: 30 ppm/° C. and gel resin (Young's modulus: 0.98 Mpa, coefficient of thermal expansion: 950 ppm/° C. and penetration number: 55 to 90 (1/10 mm)), “floatage” or “displacement” of the installed chip parts are caused by the remelting of the first mounting solder member if the first mounting solder member comprises only the matrix metal. The floatage appears as a mode at which the chip parts are lifted from a predetermined position (lifting in the vertical direction with respect to the substrate; refer to FIG. 2(c)). The displacement appears as a mode where the chip parts comes off from a predetermined position and horizontally shifts to the substrate (refer to FIG. 2(d)). Such a floatage and displacement leads to the circuit function disappearance of the semiconductor device and are undesirable. According to the test of the present inventors, this originates the fact that the chip parts released from the state of uniting by the re-melting of the first mounting solders are moved to the horizontal direction or the vertical direction with respect to the substrate by the application of the external force due to the thermal expansion and the thermal deformation of the resin. Because the solders comprised of only the matrix has the high internal pressure by the re-melting, the flow deformation is accelerated by the environment's surrounding collapsing (the deformation of the resin and the flaking off of the sealing resin). Metal powder 5B has the action to decrease the substantial liquidity of solder layer 5 when matrix metal 5A melts again (the viscosity is improved in other words) in this embodiment.

Here, metal powder 5B has the following roles.
(1) Role of resistive material to interrupt the flow of melted matrix 5A.
(2) Role (torn off control of melted matrix 5A) to increase contact area between the solid phase (metal powder 5B) and the liquid phase (melted matrix metal 5A) and to improve the joint power between the two.

Substantial liquidity of solder layer 5 decreases by the action of the above-mentioned (1) and (2), and the floatage and the displacement are controlled. Thus, the viscosity of re-melting layer 5 is substantially improved by applying the solder layer according to this embodiment, the movement of the chip parts due to the application of the external force is controlled, and the disconnection, the floatage, and displacement etc. can be controlled.

In the semiconductor device of the present invention, matrix metal 5A that composes solder layer 5 is preferably the metal or the alloy, which mainly contains Sn from the viewpoint of the environmental protection. The metal comprised of Sn or the alloy comprised of two kinds or more selected from a group of Sn, Sb, Zn, Cu, Ni, Au, Ag, P, Bi, In, Mn, Mg, Si, Ge, Ti, Zr, V, Hf, and Pd can be selected as matrix metal 5A suitable for such an object. For instance, Sn—Ag system alloy represented by Sn-3.5 wt % Ag and Sn-3 wt % Ag-0.8 wt % Cu, Sn—Sb system alloy represented by Sn-5 wt % Sb, Sn-10 wt % Sb, and Sn-5 wt % Sb-0.6 wt % Ni-0.05 wt % P, Sn—Bi system alloy represented by Sn-58 wt % Bi, Sn—Cu system alloy represented by Sn-0.7 wt % Cu, Sn—In system alloy represented by Sn-52 wt % In, Sn—Zn system alloy represented by Sn-9 wt % Zn, In—Ag system alloy represented by In-10 wt % Ag, and the Au—Sn system alloy represented by Au-20 wt % Sn. Moreover, it is also possible to apply the alloy material which arbitrarily combines the above-mentioned Sn system, Sn—Ag system, Sn—Sb system, Sn—Bi system, Sn—Cu system, Sn—In system, Sn—Zn system, the In—Ag system, and the Au—Sn system solders like Sn-8.5 wt % Zn-1.5 wt % In and Sn-4 wt % Ag-2 wt % Zn-2 wt % Bi, etc. Sn-3 wt % Ag-0.8 wt % Cu, Sn-10 wt % Sb, Sn-0.7 wt % Cu, and Sn-9 wt % Zn can be enumerated as a more suitable material in the above-mentioned alloy.

However, because a large amount of Sn is overwhelmingly contained in these metals or alloys, these melting points are approximately 200° C. and are not very high. Moreover, the metal which composes the uniting part of chip parts 6, 8, and 9, and the metal provided on the surface of wiring pattern 4 is fused to solder layer 5 after the first mounting of semiconductor device.

Solder layer 5 after the first mounting of semiconductor device comes to have a lower melting temperature by this uniting (as described later). Therefore, solder layer 5 which contains Sn voluminously causes easily problems of the re-melting due to the second mounting soldering, the outflow of the melted solders, the short circuits, the disconnections, the floatages, and the displacement etc., the role of the present invention which provides the countermeasures becomes more important.

On the other hand, it is possible to apply for the first mounting of chip parts 6 even if it is solders 5 which contains Pb 8, and 9 though it retreats by one step in the point of making Pb free. For instance, the Pb—Sn system alloy represented by the Pb-12 wt % Sn-8 wt % Sb-1 wt % Ag alloy, Pb-5 wt % Sn, Pb-3.5 wt % Sn-1.5 wt % Ag, Sn-60 wt % Sn, and Sn-50 wt % Sn can be used. Some of these alloys has a melting point higher than the Pb free solders that contains Sn voluminously. However, the circumstances that solder layer 5 after the first mounting of the semiconductor device is fused to the surface metal of wiring pattern 4 and the metal on the surface of the uniting part of chip parts 6, 8, and 9, and solder layer 5 after the first mounting of the semiconductor device come to have low melting temperatures are similar to the above-mentioned example (as described later). Therefore, the role of the present invention which provides the prevention plan of the re-melting due to the second mounting soldering, the outflow of the melted solders, the short circuits, the disconnections, floatages, and displacements is important also for solder layer 5 which contains Pb.

Next, the mechanism is explained for the melting point decrease when the solders and the Pb—Sn system solders that mainly contains Sn is fused with the material in the surrounding.

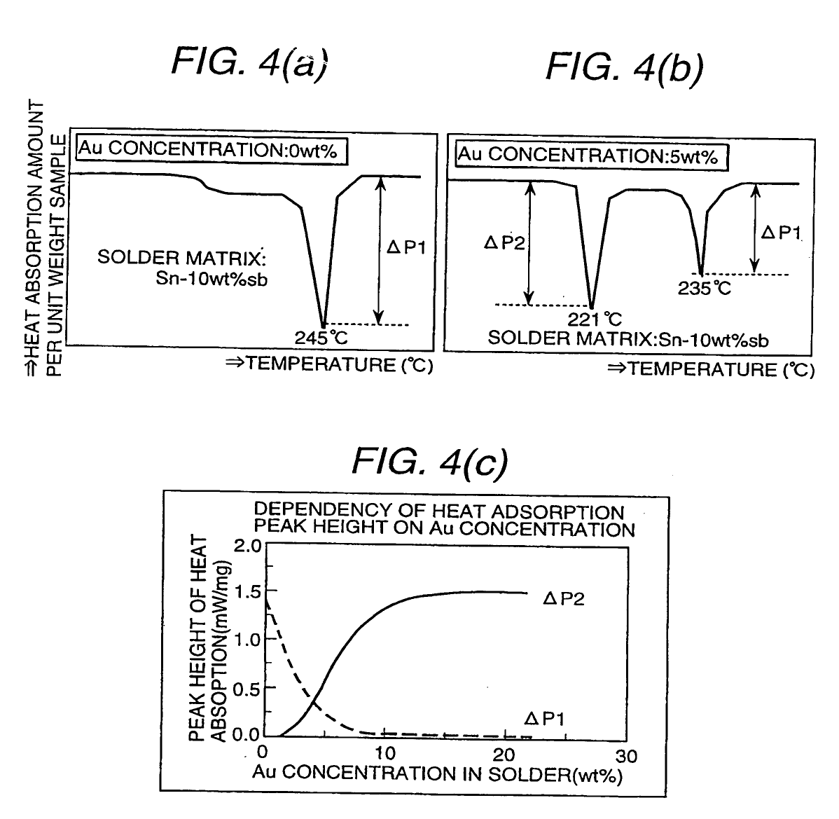

FIG. 4 is a graph illustrating the case where the melting point decrease when Au is fused with Sn-10 wt % Sb solders.

(a) is a diagrammatic view showing the characteristic of the heat absorption when Au is not fused with the solder. (b) is a diagrammatic view showing the heat absorption characteristic when Au is fused with the solder. (c) is a view showing the dependency to Au density of the heat absorption peak height.

Here, Au is derived from Au provided to the surface of accumulating metal layer 605 in semiconductor device base body 6 or Au of wiring pattern 4 or an introduction source. When the solders is not fused with Au, the heat absorption reaction with the peak caused about 245° C. in temperature rising process is occurred as for (a). The solders changes from the solid phase into the liquid phase and enters the melted state by this reaction. Heat absorption peak (ΔP1) corresponding to this peak shows a big value.

In (b), when Au fuses, the peak of 245° C. in (a) shifts to the low temperature side, and becomes 235° C., and deep peak (ΔP2) of about 221° C. is caused in the area of the lower temperature. In this case, heat absorption peak (ΔP1) of the high temperature side becomes shallower than peak ΔP 1 for (a). When the above-mentioned tendency is summed up, (c) is obtained. Peak (ΔP2) of the low temperature side rises as the Au density increases while peak (ΔP1) of the high temperature side lowers as the Au density in solder increase. The reaction of low temperature side peak (ΔP2) becomes predominant as the amount of uniting of Au increases and making to a low melting point is promoted from this tendency, although the solders with a little amount of uniting of Au is changed from the solid phase into the liquid phase by the reaction which corresponds to the high temperature side peak (ΔP1).

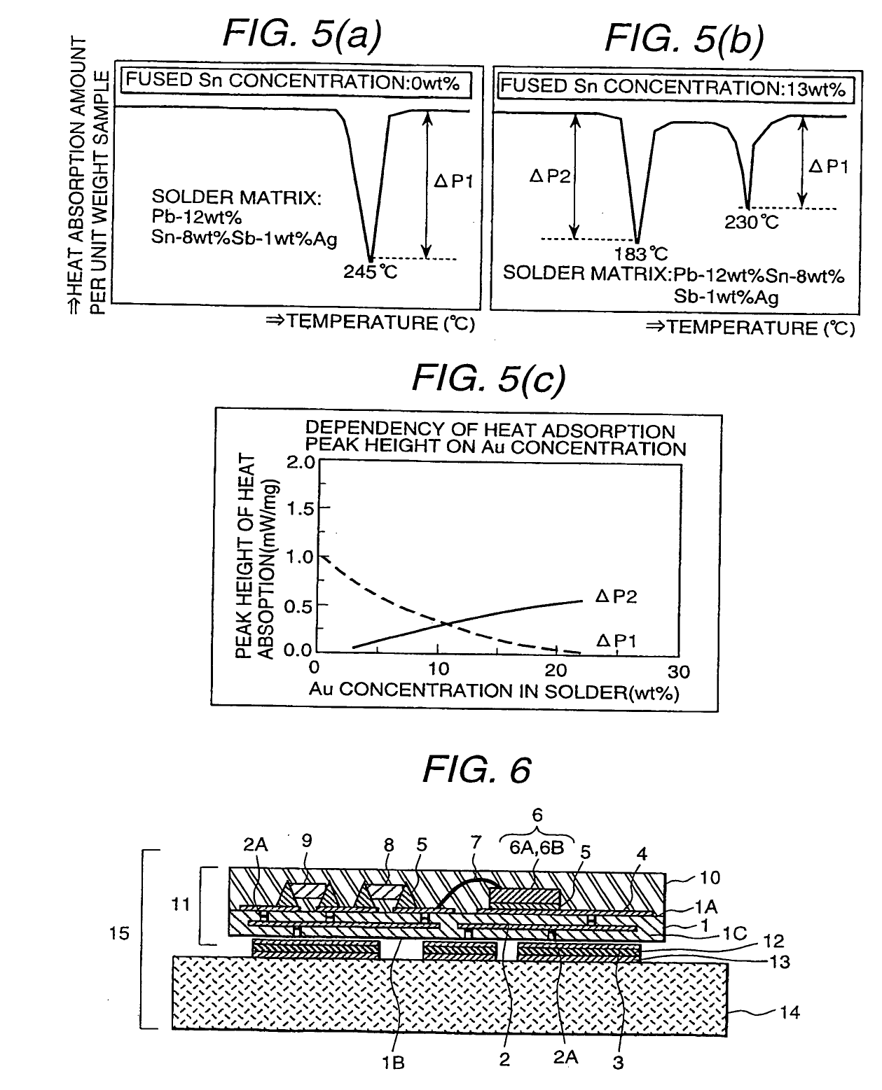

FIG. 5 is a graph illustrating the drop of the melting point when Sn is fused with Pb-12 wt % Sn-8 wt % Sb-1 wt % Ag solders. Here, Sn is derived from Sn plating provided on the surface of electrode 105 of chip parts 8 and 9.
(a) is a diagrammatic view illustrating the heat absorption characteristic when plating Sn is not fused with solders.
(b) is a diagrammatic view illustrating the heat absorption characteristic when plating Sn is fused with solders.
(c) is a view showing the dependency of the heat absorption peak height to Sn density.

When plating Sn is not fused with the solders (a), the heat absorption reaction with the peak caused at about 245° C. in temperature rising process. The solders changes from the solid phase into the liquid phase and enters melted state by this reaction. Heat absorption peak (ΔP1) corresponding to this peak shows a big value.

When plating Sn is fused with the solders (b), the peak of 245° C. in (a) shifts to the low temperature side and becomes 230° C., and deep peak (. P2) of about 183° C. is caused in the area of the lower temperature. In this case, heat absorption peak (. P1) of the high temperature side becomes shallower than peak ΔP1 for (a). When the above-mentioned tendency is summed up, (c) is obtained. Peak (ΔP2) of the low temperature side rises as the Sn density of plating increases while peak (ΔP1) of the high temperature side lowers as the Sn density of plating in solder increases.

The reaction of low temperature side peak (ΔP2) becomes predominant as the amount of uniting of plating Sn increases and making to a low melting point is promoted from this tendency, although the solders with a little amount of uniting of plating Sn is changed from the solid phase into the liquid phase by the reaction which corresponds to the high temperature side peak (ΔP1).

As mentioned above, the problem is common to either of cases where solders 5 contains Sn or Pb voluminously, which comes to take the material in the surrounding at the first mounting soldering, to make to a low melting point, and to melt easily again when the second mounting soldering is performed.

Solder layer 5 of this embodiment becomes effective also in the point to control the fusion of the material in the surrounding. The amount of dissolution of the material in the surrounding to melted solders 5 in the first mounting soldering is determined by the following factor.
(a) Substantial contact area between matrix metal 5A in solders 5 and material in surrounding.
(b) Liquidity of melted solders on contact boundary face.

The more contact area is large and the higher liquidity is, oppositely, the contact area is small, and lower liquidity is, the fewer the amount of merging of the material in the surrounding is, in other words.

As for solder layer 5, W powder 5B is distributed into Sn-5 wt % Sb alloy matrix metal 5A in semiconductor device 11 of this embodiment as explained in FIG. 2, and the volumes which W powder 5B and matrix metal 5A respectively occupy is 50 vol %. A substantial contact area with the material in the surrounding decreases because melted matrix metal 5A in the neighborhood of the contact boundary face is interrupted by W powder 5B. Moreover, the liquidity of melted matrix metal 5A has decreased as mentioned above (the viscosity is improved).

Melted matrix metal 5A fresh that does not contain the material in the surrounding is not supplied easily to the contact boundary face due to the liquidity decrease, and further dissolution of the material in the surrounding is controlled. As a result, the amount of uniting of Au and Sn can be decreased, and making to a low melting point by the reaction of low temperature side peak (ΔP2) can be controlled. This respect is one of important actions in the present invention. Therefore, making to a low melting point and the dissolution of the material in the surrounding can be controlled by lowering the liquidity, and decreasing the substantial contact area of melted solders 5 to the material in the surrounding by applying the solders of this embodiment.

Next, the method of manufacturing semiconductor device 11 of this embodiment is explained.

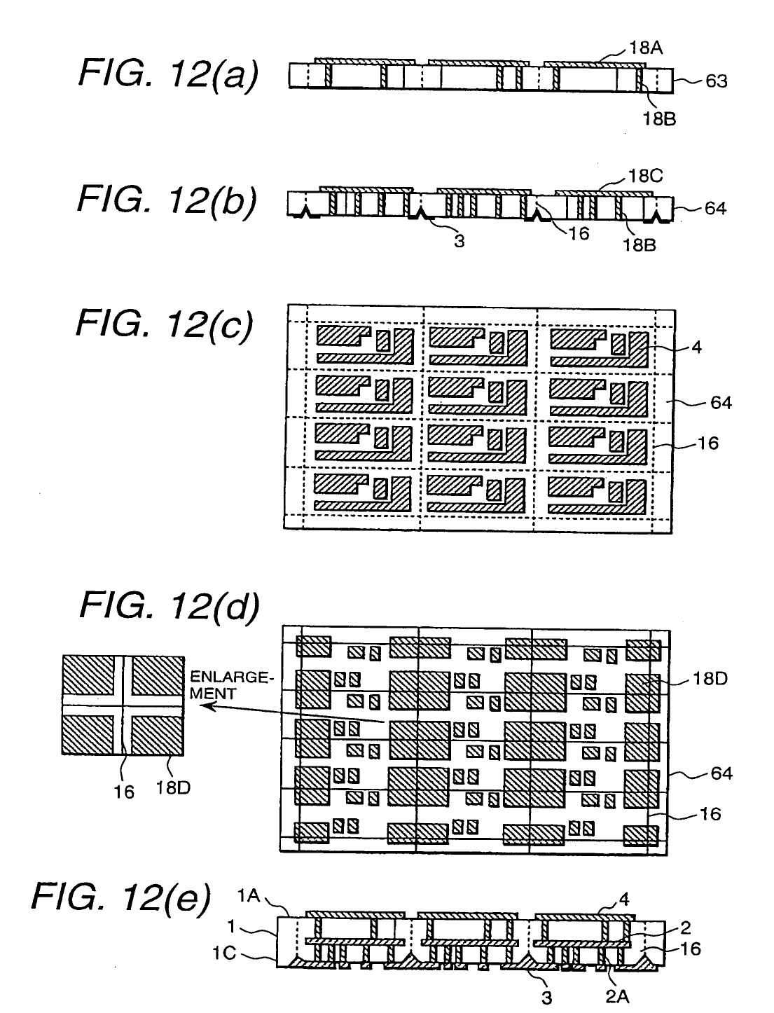

FIG. 12 is a view showing the multi-layer glass ceramics substrate applied to the semiconductor device of this embodiment.

As shown in the sectional view of (a), the through hole is formed in the predetermined part of the first greensheet 63 (the area after baking is adjusted for the thickness 78.8 mm×75 mm and the thickness after baking is adjusted to become 0.25 mm) comprised of the compound of the material of the glass ceramics material 1C and the organism. Paste 18B adjusted for the composition after baking to become Ag-1 wt % Pt is filled to this through hole, and paste layer 18A to form wiring pattern 4 is formed by the screen printing method. Moreover, the through hole is formed also in the predetermined part of the same second greensheet 64 as the above-mentioned greensheet as shown in (b), similar paste 18B is filled to this through hole, and the paste layer 18C to form internal layer wiring layer 2 is formed by the screen printing method.

Break line 16 (ditch) is provided beforehand on the back of the second greensheet 64. This break line 16 divides multi-layer glass ceramic substrate 1 in the subsequent process, and defines the size (or division) of semiconductor device 11. As for this division, 102 pieces of effective areas are obtained. Next, first and second greensheets 63, 64 are accumulated, and baked at 1,000° C. The material of the glass ceramics material 1C, the paste 18A, 18B, 18C are sintered at the same time. Greensheets 63 and 64 in this process are connected mutually, and become sintered compact with a high rigidity.

As shown in the plan view of (c), wiring pattern 4 is formed on the surface side (correspond to the first main respect 1A of multi-layer glass ceramics substrate 1) of the greensheet 63 after sintering. Wiring pattern 4 is patterned to be installed in the division formed by break line 16 provided on the other side (correspond to the second main respect 1B of multi-layer glass ceramics substrate 1). Next, as shown in the plan view of (d), the composition after baking on the other side (the second main respect 1B) is adjusted to become Ag-1 wt % Pt, and paste 18D which should become external electrode layer 3 after baking is formed by the screen printing method and is baked at 850° C. in air. Multi-layer glass ceramics substrate 1 is obtained through this process. Ni plating layer (not shown, thickness: 0.5 to 4 μm) and Au plating layers (not shown, thickness: 0.1 to 2 μm) are accumulated in order in wiring pattern 4 on this multi-layer glass ceramics substrate 1 and external electrode layer 3. The Ni plating layer acts as a barrier which prevents wiring pattern 4 and external electrode layer 3 being eroded with solders 12 for solders 5 and the external wiring connection layer in the first and the second mounting soldering. The Au plating layer has the role to give the wire bonding of thin metallic wire 7 at the same time as giving the wettability to solders 5 and solders 12 for the external wiring connection layer. As shown in the sectional view of (e), wiring pattern 4 provided on the first main respect 1A, internal layer wiring layer 2, through hole wiring 2A, and external electrode layer 3 are provided in plural divisions of multi-layer glass ceramics substrate 1, and the predetermined parts of these components are electrically connected. Moreover, multi-layer glass ceramics substrate 1 after baking is adjusted to have the area of 78.8 mm×75 mm and the thickness of 0.5 mm. Multi-layer glass ceramics substrate 1 obtained in the above-mentioned process has the performance: coefficient of thermal expansion: 6.2 ppm/° C., thermal conductivity: 2.5 W/m·K, bend strength: 2.5 Gpa, Young's modulus: 110 GPa and permittivity: 5.6 (1 MHz).

Multi-layer glass ceramics substrate 1 can be substituted by multi-layer glass ceramics substrate (coefficient of thermal expansion: 12.2 ppm/° C., thermal conductivity: 2.0 W/m-K, bend strength: 2.0 Gpa, Young's modulus: 110 GPa and permittivity: 5.4 (1 MHz)) of different performance, or multi-layer ceramics substrate (coefficient of thermal expansion: 12.2 ppm/° C., thermal conductivity: 2.0 W/m·K, bend strength: 2.0 Gpa, Young's modulus: 110 GPa and permittivity: 5.4 (1 MHz)) whose matrix material is alumina. In any case of the multi-layer glass ceramics substrate and the multi-layer alumina ceramics substrate, internal layer wiring layer 2, through hole wiring 2A, external electrode layer 3 and wiring pattern 4 can be substituted by the conductor material comprised of Ag, the conductor material comprised of Cu, and the conductor material comprised of Cu where metal powders such as W and Mo.

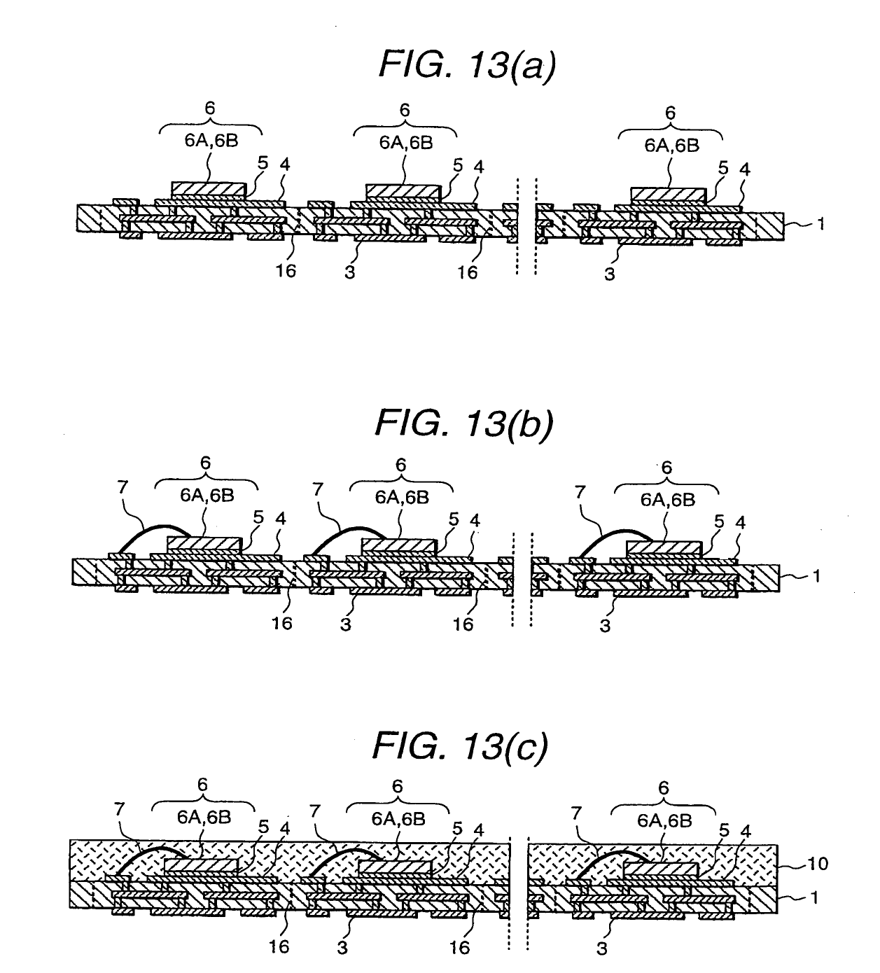

FIG. 13 is a sectional view showing the manufacture process of the following semiconductor devices. The chip parts comprised of semiconductor device base body 6 which contains the integrated circuit element base body 6A and FET element base body 6B, chip resistance 8, and capacitor 9 (not shown) are bonded electrically on wiring pattern 4 of multi-layer glass ceramics substrate 1 by solder layer 5 where W powder 5B (particle size: 1 μm and the amount of addition: 50 vol %) is distributed to matrix metal 5A comprised of Sn-5 wt % Sb. In this process, the paste (paste where the powder of matrix metal 5A and metal powder 5B is mixed beforehand with the flux material) adjusted for the composition after soldering to become the above-mentioned composition is printed on the predetermined part of wiring pattern 4, chip parts 6, 8, and 9 are set on the paste, and they are heated at 265 *C in air. Chip parts 6, 8, and 9 are bonded electrically on multi-layer glass ceramics substrate 1 as shown in (a) through this process.

Here, solder layer 5 has the configuration shown in FIG. 2. Because this respect has already described in detail, only the role of W powder 5B will be described, and other explanations will be omitted. The role of W powder 5B is demonstrated in the process where semiconductor device 11 is installed on wiring substrate 14 by the second mounting soldering which describes later.

The following role is played at the second mounting soldering.
(1) The substantial cubical expansion is reduced by the existence of W powder 5B by which the state of the solid phase is maintained even if solder layer 5 melts again, the excessive rise of the internal pressure, flaking off, the outflow of melted solders and the short circuits are controlled, and the outflow of melted solders and the short circuit are controlled by the clogging phenomena of W powder 5B.
(2) The dissolution of the material in the surrounding and making to a low melting point are controlled by reducing the contact area of melted solders 5 and the material in the surrounding and lowering the liquidity substantially.

Even if the metal comprised of Sn or the alloy comprised of two kinds or more selected from a group of Sn, Sb, Zn, Cu, Ni, Au, Ag, P, Bi, In, Mn, Mg, Si, Ge, Ti, Zr, V, Hf, and Pd is selected as matrix metal 5A, and single metal listed in Table 2, or the alloy comprised of two kinds or more selected from a group of Al, Co, Cr, Cu, Fe, Ge, Mn, Mo, Ni, Sb, Si, W, Zn, Ti, Pd, Ta, Pt, Ag, C, and P is selected as metal powder 5B, metal powder 5B causes desirable actions of the above-mentioned (1) and (2) in the state that solder layer 5 is sealed up.

Next, thin metallic wire 7 (integrated circuit element base body 6A: diameter 27. m and FET element base body 6B: diameter 50. m) comprised of Au is bonded in thermocompression at 200° C. between predetermined parts of semiconductor device base body 6 and wiring pattern 4 as shown in (b). Resin layer 10 material (physical properties after hardening are coefficient of thermal expansions: 9.0 ppm/° C., Young's modulus: 24.5 Gpa, glass transition point: 150° C. and amount of the filler addition: 85 wt %) whose principal ingredient is epoxy is printed on the chip part installing side of multi-layer glass ceramics substrate 1 given in the process so far so that chip parts 6, 8, 9, thin metallic wire 7, and the first main respect 1A can be completely coated. The heating processing of 110° C.×1.5 h and 150° C.×1.5 h is given in air in order and the epoxy material is hardened. Chip parts 6, 8, 9, thin metallic wire 7, and the first main respect 1A are sealed by resin layer 10 so that they are completely intercepted from air as shown in the section structure of (c) by the above-mentioned processing.

Next, multi-layer glass ceramics substrate 1 molded with the resin is divided along break line 16 by applying external force by the bending moment. At this time, multi-layer glass ceramics substrate 1 and resin layer 10 are broken so that each fracture surface may belong substantially to the same plane. Moreover, the fracture surface of external electrode layer 3 becomes the same plane as multi-layer glass ceramics substrate 1 and resin layer 10 by this breaking.

Semiconductor device 11 shown in FIG. 1 is obtained by the process so far. The chip element placement, the wire bonding, and the resin molding can be performed on one piece taken from the multi-layer glass ceramics substrate in the above-mentioned process to the individualization division. Therefore, the mass production of semiconductor device 11 is improved, and economical merit is increased. In the above-mentioned individualization division process, external force is applied to multi-layer glass ceramics substrate 1, resins layer 10, and external electrode layers 3 by the bending moment. The individualization of this semiconductor device 11 can be performed also by cutting which uses the rotation braid for instance. Even if the re-melting of solder layer 5 is caused in the second mounting soldering process described later, the outflow of matrix metal 5A and the short circuit due to th e outflow can be prevented according to semiconductor device 11 explained above.

The following materials can be used besides the material used by this embodiment for semiconductor device 11 of the present invention. The material of the thickness film can be replaced with materials other than the Ag-Pt system, for example, the material comprised of at least one kind of metal selected from a group of Ag (162′-cm, 962° C.), Pt (1060 Ω·cm, 1772° C.), Cu (172 Ω·cm, 1084° C.), Pd (1080 Ω·cm, 1554° C.), and Au (240 Ω·cm, 1064° C.). For instance, the thickness film material like Cu (about 100 wt %) material and the Ag-15 wt % Pd material, etc. is suitable for the wiring member.

For this case, It is desirable to form the Ni layer and the Au layer by the plating method etc. on the surface of the thickness film material comprised of at least one kind of metal selected from a group of Ag, Pt, Cu, Pd, and Au formed for instance as a wiring layer like external electrode layer 3 and wiring pattern 4, etc., in order to Secure the quality of the surface of the thickness film material, to secure the wire bonding, to secure the wetting of the solders, to prevent the erosion by the solders, and to prevent to generate intermetallic compound on the boundary surface of the soldering. As the glass ceramics material 1 C, the following material can be used, for instance.
(1) Al₂O₃-2MgO—SiO2-(B2O3-SiO2) system [composition: A120 3 (35 wt %) and 2MgO—SiO2(25 wt %), B2O3-SiO2 glass (40 wt %)]
(2) Al₂O₃-(CaO—Al2O3-SiO2-B2O3) system [composition: Al₂O₃ (40 wt %), CaO—Al2O3-SiO2-B2O3 glass (60 wt %)]
(3) Al₂O₃-(PbO—SiO2-B2O3) system [composition: Al₂O₃(55 wt %), PbO—SiO2-B2O3 glass (45 wt %)]
(4) BaO—Al₂O₃-SiO2-CaO—B2O3 system [composition: BaAl2, SiO6 are extracted in glass phase.]
(5) Al₂O₃-(B2O3-SiO2) system [composition: Al2O3(50 wt %), B2O3-SiO2 glass (50 wt %)].

For instance, multi-layer ceramics substrate 1 obtained by using the glass ceramics material 1C has the following characteristics.
(a) Coefficient of thermal expansion in which Cu wiring is given: 5.9 ppm/° C. and modulus: 110 GPa and wiring resistance (sheet resistance): 3 m Ω/□
(b) Coefficient of thermal expansion in which Cu wiring is given: 6.2 ppm/° C. and thermal conductivity: 1.3 W/m K and bend strength: 0.2 GPa and Young's modulus:100 GPa and wiring resistance (sheet resistance): 3 m Ω/□
(c) Coefficient of thermal expansion in which Cu wiring is given: 12.2 ppm/° C. and thermal conductivity: 2.0 W/m K and bend strength: 0.2 GPa and Young's modulus: 75 GPa and wiring resistance (sheet resistance): 3 m Ω/□
(d) Coefficient of thermal expansion in which Ag or Ag-Pt wiring is given: 6.3 ppm/° C. and thermal conductivity: 2.5 W/m·K and bend strength: 0.25 GPa and Young's modulus: 75 GPa and wiring resistance (sheet resistance): 3 mΩ/□
(e) Coefficient of thermal expansion in which Ag or Ag-Pt wiring is given: 10.4 ppm/° C. and thermal conductivity: 4.7 W/m·K and bend strength: 0.21 GPa and Young's modulus: 75 GPa and wiring resistance (sheet resistance): 3 m Ω/□.

The matrix of substrate 1 is not limited to the glass ceramics material, and can use the alumina substrate (coefficient of thermal expansion: 7.0 ppm/° C. and thermal conductivity: 15.2 W/m·K and bend strength: 0.4 GPa and Young's modulus: 300 GPa and wiring resistance (sheet resistance): 4 m Ω/□) which has wiring where W is distributed to Cu as one example. Moreover, the glass ceramics material which is the matrix of substrate 1 can be replaced with the nitride aluminum, the nitride silicon, the glass, and beryllia. In substrate 1 of any one of glass ceramics, alumina, the nitride aluminum, the nitride silicon, the glass, and beryllia, it is not assumed to be indispensable to have internal layer wiring layer 2 and the through hole wiring 2A.

Internal layer wiring layer 2, through hole wiring 2A, the matrix of external electrode layer 3 and wiring pattern 4 is selected in consideration of the point where the wiring resistance is low, the point where baking or manufacture is easy, and the point that the erosion with the solders can be endured, etc. Internal layer wiring layer 2, through hole wiring 2A, the matrix of external electrode layer 3 and wiring pattern 4 may be composed of at least one kind of metal selected from a group of Cu, Ag, Pt, Pd, and Au from this viewpoint. In this case, it is possible to form them by a thickness film baking method or a physical vapor deposition method. The wiring resistance (sheet resistance) of Ag-0.2-1.5 wt % Pt material is about 3 m Ω/□, that is, low resistance, and it is possible to bake simultaneously with glass ceramics material at about 1000° C. Moreover, even if the chip parts are bonded with the melted solders which contains a large amount of Sn for instance like Sn-3.5 wt % Ag material (melting point: 221° C.), the Ag-0.2-1.5 wt % Pt material is hardly eroded by the melted solders. If solders where the amount of addition of Sn is fewer is used, the problem by erosion can almost be evaded. Therefore, when external electrode layer 3 and wiring pattern 4 comprise the Ag-0.2-1.5 wt % Pt material, it is not required to plate the Ni layer and the Au layer on the surface in the present invention. In addition, internal layer wiring layer 2 and through hole wiring 2A need not provide if there is no necessity according to the required performance in semiconductor device 11.

Resin layer 10 can be replaced by various epoxy resins which have physical properties after hardening of the coefficient of thermal expansion: 5 to 220 ppm/° C., Young's modulus: 1 to 50 GPa and glass transition point: 75 to 160° C. Moreover, it can be replaced by various RTV (Room Temperature Vulcanizing) rubber resins which have physical properties after hardening of coefficient of thermal expansions: 90 to 900 ppm/° C. and the Young's modulus: 0.8 to 6.4 Mpa. In addition, it is possible to substitute resin layer 10 with the resin obtained by mixing said various epoxy resins and said various RTV rubber resins.

The epoxy material as resin layer 10 can be substituted with not only the one of the epoxy resins which have physical properties after hardening of coefficient of thermal expansions: 9.0 ppmPC, Young's modulus: 24.5 Gpa, glass transition point: 150° C. and amount of the filler addition: 85, but also epoxy resins which have the following properties, for instance, physical properties after hardening of Young's modulus: 1 to 50 GPa and coefficient of thermal expansion: 5 to 220 ppm/° C. such as coefficient of thermal expansions: 14 ppm/° C., Young's modulus: 8.8 Gpa, glass transition point: 136° C. and amount of the filler addition: 74 wt %.

Moreover, if it is possible to protect the installed parts mechanically or to seal them airtight, the resin composition which contains thermosetting property or thermoplastic resins and the filler, etc. other than the epoxy resin composition can be used as resin layer 10. As thermosetting resin, epoxy resin can be desirable, and, in this case, both liquid and the solid be used.

The liquid epoxy resin can do the formation processing by a well-known method such as the transfer molding. Poly phenylene sulfide (PPS) and polybutylene terephthalate (PBT), etc. as thermoplastic resin can do the formation processing by the injection molding process. The following resin can be used as epoxy resin: bisphenol A type epoxy resin, tetrabromobisphenol A type epoxy resin, bisphenol F type epoxy resin, bisphenol A/F type epoxy resin, bisphenol AD type epoxy resin, phenol novolak type epoxy resin, cresol novolak type epoxy resin, and biphenyl type epoxy resin, etc. In addition, the resin cyclic epoxy resin alone is used or can be used together for the heat resistance improvement. For instance, the following resin exists as resin cyclic epoxy resin: 3,4-epoxycyclohexyl methyl (3,4-epoxy) 4-cyclohexane carboxylate, 4-(1, 2-epoxypropyl)-1,2-epoxycyclohexane, 2-(3,4-epoxy) cyclohexyl-5, and 5-spiro (3,4-epoxy) cyclohexane-m-dioxane, etc. Moreover, amine system hardener, acid anhydride system hardener, and phenol resin, etc. can be used as hardener of epoxy resin.

Diethylene triamine, bis (aminomethyl) cyclohexane, diaminodiphenyl methane, and diaminodiphenylsulfon, etc. can be enumerated as the amine system hardener. Methylic tetrahydro phthalic anhydride, methy hymic acid anhydride, nagic acid anhydride etc. can be enumerated as acid anhydride system hardener. The phenol novolac resin and the phenol alkyl resin, etc. can be enumerated as phenol resin. Moreover, the epoxy material as resin layer 10 can be substituted even with the resin where Young's modulus is small and the coefficient of thermal expansion is high. For instance, It is possible to replace the resin layer with the epoxy resin which has physical properties after hardening of coefficient of thermal expansions within the range of 5 to 22 ppm/° C. like physical properties after hardening of coefficient of thermal expansions: 14 ppm/° C., Young's modulus: 8.8 Gpa, glass transition point: 136° C. and amount of the filler addition: 74 wt %.

Fused silica, crystal silica, alumina, magnesium oxide, magnesium carbonate, calcium carbide, dolomite, aluminium hydroxide, magnesium hydroxide, calcium fluoride, magnesium fluoride, aluminum fluoride, talc, clay, and mica, etc. can be used as a filler. Moreover, the crushing shape, the spheroidal shape or the fibrous shape can be used. As for the mean diameter of these filler, the range of 0.1 to 30 μm is desirable. This reason depends on the filling to the narrowness part becoming difficult when particle size are larger than 30 μm, and the rising of the viscosity and the impairing work when particle size is smaller than 0.1 μm.

Moreover, the expansion coefficient after resin layer 10 hardens can be adjusted within the desired range by adjusting the amount of addition of the filler. That is, the coefficient of thermal expansion can be reduced by increasing the amount of the filler addition, and it can be enlarged by decreasing the amount of the filler addition. Making-flexibility agent, the flame retarder, coloring agent, and the surface treatment agent, etc. can be added if necessary.

In the present invention, the matrix of substrate 1 can be substituted even with materials other than the ceramics material. For instance, it can be replaced by compound resin made by soaking epoxy into glass fabric base [glass epoxy and physical properties: coefficient of thermal expansion: 14 ppm/° C., Young's modulus: 170 Gpa]. Moreover, it is also possible to use paper phenol material which uses paper as the base, and uses phenol resin as impregnation resin; composite material which uses the glass fabric, the glass nonwoven cloth, and paper as the base, and uses epoxy resin, the polyimide, and the bismaradetriazine as impregnation resin; and glass polyimide material which uses the glass fabric as the base, and uses the polyimide as impregnation resin. Furthermore, a flexible printed board which forms the wiring pattern to the films such as polyester, the polyimide, and the polyimide amid can be used. The wiring provided to these substrates 1 is made of Cu. Ni, a single-layer or a multi-layer.

It is possible to replace the Si material as semiconductor device base body 6 with compound semiconductor which contains at least on e selected from a group of Ga, As, Al, P, In, Sb as main ingredient, typically the compound semiconductor material such as GaAs materials (6.0 ppm/° C. and SiC (3.7 ppm/° C.), or Ge material (6.0 ppm/° C.). Moreover, SiGe obtained by combining materials which contain the Si material can be used, for instance. Thin metallic wire 7 comprised of Au can be replaced with Al or Al material to which Si and Ni are added. These alternate material including the Au material can be 10 to 100. m in diameter according to need.

An electric connection to the external circuit is generally achieved by soldering with the circuit board of making the material which has a coefficient of thermal expansion different from that of semiconductor device as the matrix (for instance, glass epoxy substrate). It is desired to substitute the Pb—Sn system alloy material which has been applied to equip with electronic parts so far with Pb free alloy from the viewpoint of the environmental protection in recent years.

The Pb free solders of possible practical use is an alloy which contains an overwhelming large amount of Sn, and the melting point is 240° C. or less. For instance, when the above-mentioned semiconductor device where the semiconductor elements are bonded (the first mounting soldering) by using Sn-5 wt % Sb solders (melting point: 230-240° C.) is soldered (the second mounting soldering) to the circuit board by using the Sn-3 wt % Ag-0.5 wt % Cu solders (melting point: 221° C.), it is necessary to heat them at the temperature higher by about 40 degree than the melting point to secure the second mounting soldering. In such heat-treating, not only the solders for the second mounting but also the solders for the first mounting will be melt. According to the study by the inventors, The cubical expansion of about 16% is caused in the Pb free solders during the process which changes from the state of the solid phase into the state of the liquid phase. Because surroundings of the solders for the first mounting are enclosed with the resin, and a big internal pressure of 825 Mpa (84.1 kgf/mm²) according to this cubical expansion is occurred. As a result, the joint boundary face of the sealing resin (between the ceramics board and the resin) flakes off, the melted solders for the first mounting flows out through the caused gap, and thereby, the short circuit is occurred between wiring patterns. For instance, when chip parts such as capacitors and resistors are mounted first, the short circuit is occurred between electrodes of the chip parts by the similar cause. Such a short circuit spoils not only the semiconductor device but also the circuit function of the electronic equipment using the same. In addition, when the substrate equipped with the chip parts is a substrate whose matrix is made of the resin, the solders with a high melting point cannot be used for the solders for the first mounting. This reason is that heat resistance of the resin substrate is not high like the ceramics material. For instance, the quality deterioration in changing in quality of the substrate (discoloration), degeneration (insulation deterioration), and the deformation, etc. occurs when the first mounting soldering for the glass epoxy substrate is done at a temperature of 250° C. or more. It is necessary to use the material which can be processed at the temperature which does not exceed 250° C. as a solders for the first mounting to avoid this. The outflow of the first mounting solders in the subsequent second mounting soldering, and the short circuits, the disconnections and the displacement of the chip parts due to this outflow are accelerated further for the semiconductor device mounted firstly by the solders of such a low melting point.

A semiconductor device with high reliability by which The outflow of the first mounting solders, and the short circuits, the disconnections and the displacement of the chip parts due to this outflow can be prevented when the semiconductor device where the chip parts as the circuit element installed on the substrate are sealed in resins is installed in the external wiring substrate can be provided according to this embodiment by which the problem like the above-mentioned can be solved.

(Embodiment 2)

Semiconductor device 11 obtained by embodiment 1 is applied to structural body 15 according to this embodiment, which is installed on wiring substrate 14, and shown in FIG. 6. Structural body 15 is obtained by bonding electrically external electrode layers 3 of semiconductor device 11 and external wiring 13 comprised of the Cu material of 25. m in thickness, provided on one respect of wiring substrate 14 through external wiring connection layer 12. In this case, Sn-3 wt % Ag-0.5 wtCu solders (melting point: 221° C.) is used as external wiring connection layer 12 (work temperature: 260° C.).

The coefficient of thermal expansion of matrix material of wiring substrate 14 is different from that of multi-layer ceramics substrate 1 in semiconductor device 1, for example, glass epoxy material (composite material where the epoxy resin is soaked into glass fiber cloth, coeffeicient of thermal expansion: 9.0 ppm/° C., Young's modulus: 35 GPa). Moreover, the size of wiring substrate 14 is 30 mm×7 mm×0.6 mm. On such structural body 15, internal layer wiring layer 2 and through hole wiring 2A are arranged to be laid to an internal area of multi-layer ceramics substrate 1.

Here, chip parts 6 (6A,6B) housed in semiconductor device 11, 8, and 9 are bonded electrically on wiring pattern 4 provided to substrate 1 with solder layer 5 (the first mounting soldering). Solder layer 5 comprises the compound body where W powder 5B (particle size: 1. m) is distributed to matrix metal 5A comprised of Sn-5 wt % Sb alloy as described in embodiment 1. Here, the amount of addition of W powder 5B is adjusted to 50 vol %. Each of chip parts 6 and 8 and 9 is completely enclosed by substrate 1, wiring pattern 4, and resin layer 10. Moreover, solder layer 5 by which these chip parts are bonded is completely enclosed by chip parts 6, 8 and 9, wiring pattern 4, and resin layer 10.

In such structural body 15, it is an important point that surroundings of solder layer 5 are completely enclosed by other solid materials, and that metal powder 5B is distributed to matrix metal 5A. W powder 5B does not melt and the state of the solid phase can be maintained even if matrix metal (Sn-5 wt % S b) 5A of solder layer 5 melts when semiconductor device 11 is mounted (heating temperature: 260° C.) secondly by using external wiring connection layer 12 (Sn-3 wt % Ag-0.5 wt % Cu solders) because solder layer 5 has such configuration.

The advantage or the effect explained in embodiment 1 can be obtained immediately by the process of the second mounting to obtain structural body 15. Because the details has been described before, only the key points are explained here to avoid overlapping.
(1) The substantial cubical expansion is reduced by the existence of W powder 5B by which the state of the solid phase is maintained even if solder layer 5 melts again, the excessive rise of the internal pressure, flaking off, the outflow of melted solders and the short circuits are controlled, and the outflow of melted solders and the short circuit are controlled by the clogging phenomena of W powder 5B.
(2) A substantial viscosity of re-melted solder layer 5 is improved by the existence of metal powder 5B which maintains the state of the solid phase, the movement of the chip parts according to application of the external force is controlled, and the floatage and displacement are controlled.
(3) The dissolution of the material in the surrounding and making to a low melting point according to it are controlled by lowering liquidity, and reducing the substantial contact area of the melted solders 5 and the material in the surrounding.

In this structural body 15, because the re-melting of solder layer 5 is permitted in the heat-treating of the second mounting, Sn-3 wt % Ag-0.5 wt % Cu solders as external wiring connection layer 12 can be substituted with other metals or alloy materials. For instance, Pb—Sn system alloy represented by Pb-12 wt % Sn-8 wt % Sb-1 wt % Ag, Pb-5 wt % Sn, Pb-3.5 wt % Sn-1.5 wt % Ag, Pb-40 wt % Sn, Pb-60 wt % Sn, and Pb-85 wt % Sn. The alloy material made by adding at least one selected from a group of Bi, Ag, Sb, In, Au, Zn, Cu, Pd, Mn, Mg, and P by the Pb—Sn system can be used. Moreover, The metal comprised of Sn or the alloy comprised of two kinds or more selected from a group of Sn, Sb, Zn, Cu, Ni, Au, Ag, P, Bi, In, Mn, Mg, Si, Ge, Ti, Zr, V, Hf, and Pd can be selected from the viewpoint of the environmental protection.

For instance, it is possible to replace it with the following alloy. Sn—Ag system alloy represented by Sn-3.5 wt % Ag and Sn-3 wt % Ag-0.8 wt % Cu, Sn—Sb system alloy represented by Sn-5 wt % Sb, Sn-10 wt % Sb, and Sn-5 wt % Sb-0.6 wt % Ni-0.05 wt % P, Sn—Bi system alloy represented by Sn-58 wt % Bi, Sn—Cu system alloy represented by Sn-0.7 wt % Cu, Sn—In system alloy represented by Sn-52 wt % In, Sn—Zn system alloy represented by Sn-9 wt % Zn, In—Ag system alloy represented by In-10 wt % Ag, and the Au—Sn system alloy represented by Au-20 wt % Sn. Moreover, it is also possible to apply the alloy material which arbitrarily combines the above-mentioned Sn system, Sn—Ag system, Sn—Sb system, Sn—Bi system, Sn—Cu system, Sn—In system, Sn—Zn system, the In—Ag system, and the Au—Sn system solders like Sn-8.5 wt % Zn-1.5 wt % In and Sn-4 wt % Ag-2 wt % Zn-2 wt % Bi, etc. Sn-3 wt % Ag-0.8 wt % Cu, Sn-10 wt % Sb, Sn-0.7 wt % Cu, and Sn-9 wt % Zn can be enumerated as a more suitable material in the above-mentioned alloy.

It is possible to replace wiring substrate 14 with the glass epoxy with physical properties: for instance, coefficient of thermal expansions: 14 ppm/° C. and Young's modulus: 170 Gpa. Moreover, it is also possible to use paper phenol material which uses paper as the base, and uses phenol resin as impregnation resin; composite material which uses the glass fabric, the glass nonwoven cloth, and paper as the base, and uses epoxy resin as impregnation resin; and glass polyimide material which uses the glass fabric as the base, and uses the polyimide as impregnation resin. Furthermore, a flexible printed board which forms the wiring pattern to the films such as polyester, the polyimide, and the polyimide amid can be used. Single-layer or the substrate in the form that the wiring pattern is formed on the aluminium substrate to which organic insulating layers are provided can be used as wiring substrate 14.

It is desirable to provide the wiring pattern to connect with the external circuit on the back of the above-mentioned various substrates to install semiconductor device 11. In this case, the wiring pattern to install semiconductor device 11 and wiring pattern on the back are electrically connected. External wiring 13 is provided to other respect of wiring substrate 14. This external wiring 1 can be communicated electrically to opposite main side via the through hole wiring. Moreover, when more high density wiring is given, it is also possible to provide the internal layer wiring layer more than one layer in wiring substrate 14.

Table 1 is a table explaining the defective generation rate of the present invention structural body. Solder layer 5 in semiconductor device 11 is obtained by distributing W powder 5B into Sn-5 wt % Sb alloy matrix metal 5A by 50 vol %. Moreover, Sn-5 wt % Sb alloys to which the metal powder is not added are compared with the structural body obtained by using the semiconductor device having the same structure to which the metal powder is added. The defective generation rate of the present invention structural body 15 is 0.00015%, and it is 1/23000 compared with 3.45% of the structural body for the comparison. A defective mode shows the disappearance of the circuit function by the short circuit in both structural bodies, and the effect of the outflow prevention of solders 5 obtained by the addition of W powder 5B appears clearly in the present invention structural body 15.

TABLE 1

| | DEFECTIVE | |
|---|---|---|
| | GENERATION | |
| SAMPLE | RATE | DEFECTIVE MODE |
| INVENTION | 0.00015 | DISAPPEAR OF CIRCUIT |
| BODY | | FUNCTION DUE TO SHORT |
| | | CIRCUIT |
| COMPARED | 3.45 | DISAPPEAR OF CIRCUIT |
| BODY | | FUNCTION DUE TO SHORT |
| | | CIRCUIT |

STRUCTUAL BODY OF THE PRESENT INVENTION: Application of W powder addition Sn-5 wt % Sb solder (Number of Sample: 100,000 pieces)
STRUCTUAL BODY FOR COMPARATION: Application of Sn-5 wt % Sb solder (Number of Sample: 100,000 pieces)

Table 1 shows the defective generation rate based on the circuit function disappearance of the structural body where the chip parts are installed by using the solders of various metal powder addition. The circuit function disappearance mentioned here is occurred by the short circuit based on the re-melting and the outflow of solders 5. Even if any metal powders 5B are added, a circuit function defective disappearance by the short circuit is 0.013% or less, and this value is far lower than 3.45% in the structural body for the comparison (Table 1). Moreover, a clear correlation (dependency of the defective rate to the density of the metal powder) between the defective generation rate and the density is not seen although the density of metal powder 5B has changed from 2.33 g/cm3 of Si to 21.45 g/cm3 of Pt. All the metals listed in Table 2 as metal powder 5B for solders 5 can be applied from this respect. Cu, Fe, Ni, Sb, Zn, Ag, and Pt are more desirable from the viewpoint of the cost, the easiness of powder production, and the bondability with matrix metal 5A in above-mentioned metal powder 5B.

TABLE 2

| | | SHORT CIRCUIT DEFECTIVE |
|---|---|---|
| METAL | DENSITY (g/cm³) | GENERATION RATE (%) |
| Al | 2.699 | 0.003 |
| Co | 8.85 | 0 |
| Cr | 7.19 | 0.003 |
| Cu | 8.96 | 0 |
| Fe | 7.87 | 0 |
| Ge | 5.36 | 0.008 |
| Mn | 7.42 | 0.003 |
| Mo | 10.2 | 0 |
| Ni | 8.902 | 0 |
| Sb | 6.62 | 0.011 |
| Si | 2.33 | 0.003 |
| W | 19.3 | 0.00015 |
| Zn | 7.133 | 0.012 |
| Ti | 4.507 | 0.003 |
| Pd | 12.02 | 0 |
| Ta | 16.6 | 0.003 |
| Pt | 21.45 | 0 |
| Ag | 10.49 | 0.013 |

Matrix metal: Sn-5 wt % Sb
Number of sample: 1,000 pieces per each (W addition: 100,000 pieces)
Second mounting soldering: 260° C.

Moreover, Table 3 shows the defective generation rate based on the circuit function disappearance of the structural body to which various alternative powders are applied. Even if any powders 5B are used, the defective generation rate is excellent with 0.018% or less. Even if the re-melting of matrix metal 5A is caused at the second mounting stage, alternative powder 5B is selected from the viewpoint that solders 5 does not flows out and the short circuit is not occurred. When the powder 5B is selected, the following matter is also considered. In the first mounting stage, at the same time as the melting and bonding of metal powder 5A which reached melting point, the surface cleaning of metal powder 5B by flux agent 5C (especially, removal of surface oxide film) progresses, and the uniting of matrix metal 5A and metal powder 5B (matrix metal 5A melted on the surface of metal powder 5B gets wet) is completed instantaneously. Moreover, metal powder 5B is not limited to the alloy powders listed in Table 2 in the present invention. Further, it is possible to apply the alloy material which contains one kind of metal or more selected from a group of Sn, Au, Fe, Ge, Mn, Ni, Sb, Si, Zn, Pd, Pt, P, Pb, and Al as well as Ag and/or Cu as the principal ingredient

TABLE 3

| | SHORT |
|---|---|
| | CIRCUIT |
| | DEFECTIVE |
| | GENERATION |
| COMPOSITION (wt %) | RATE (%) |
| Cu-(8-10)Sn-(2-4)Zn | 0.003 |
| Cu-(10-13)Sn-(0.1-1)Zn | 0.008 |
| Cu-(20-30)Ni-(0.5-5)(Sn or Sb) | 0.003 |
| Cu-(1.5-4)Si-(0-3)Zn-(0-1)Mn-0.2Fe | 0.002 |
| Cu-(10-20) Ni-(10-20)Zn-(2-4)Sn-(0-7)Pb-(0-0.5)Mn | 0.008 |
| Cu-(9-11)Al-(0-5)Ni-(0-5)Fe-(0-1)Mn | 0.003 |
| Ag-12Cu-6Sn | 0.018 |
| Ag-20Cu | 0.011 |
| Ag-20Zn-3Sn-2Ni | 0.011 |
| Ag-20Zn-5Mn-2Ni | 0.003 |
| Ag-31.2Cu-6.2Zn | 0.005 |
| Ag-80Cu-5P | 0.012 |
| Ag-58Cu-28Zn | 0.013 |
| Au-25Ag-16Cu-1.6Zn | 0.007 |
| (33.3˜66)Cu-(34˜66.7)Zn | 0.003 |
| Cu-4.4Sn-0.07P-0.1Zn | 0.012 |
| Cu-(8˜25)Ge-(10˜20)Zn-(2˜4)Pd-(0˜0.5)Pt | 0.013 |

Matrix metal: Sn-5 wt % Sb
Second mounting soldering: 260° C.

In the present invention, metal powder 5B which can be added to solders 5 is not limited to the single metal powder listed in Table 2. It is possible to apply as long as it is a powder even if it is an alloy material comprised of two kinds of materials or more selected from a group of Al, Co, Cr, Cu, Fe, Ge, Mn, Mo, Ni, Sb, Si, W, Zn, Ti, Pd, Ta, Pt, Ag, C, and P. For instance, the following is especially desirable materials for metal powder 5B. Fe-50 wt % Ni, Fe-42 wt % Ni, Fe-29 wt % Ni-17 wt % Co, Fe-30 wt % Ni-13 wt % Co-0.3 wt % Si-0.8 wt % Mn-0.02 wt % C-0.3 wt % Be, and Fe-0.3 wt % C-0.5 wt % Mn-0.2 wt % Si-0.87 wt % Cr-0.2 wt % Mo, Fe-0.53 wt % C-0.3 wt % Mn-1.0 wt % Cr-0.17 wt % V, Fe-18 wt % Ni-8 wt % Cr, Cu-67 wt % Al, Ag-28 wt % Cu, Al-1.5 wt % Be, Al-7.6 wt % Ca, Al-10 wt % Ce, Al-10 wt % Co, Al-10 wt % Cr, Al-1.8 wt % Fe, Al-53 wt % Ge, Al-15 wt % Mn, Al-3 wt % Mo, Al-5.7 wt % Ni, Al-22 wt % Pd, Al-30 wt % Sb, Al-11.7 wt % Si, Al-3 wt % Te, Al-2.5 wt % Ti, Al-3.3 wt % V, Al-3 wt % W, Al-5 wt % Zr, Fe-3.8 wt % B, Ni-4 wt % B, Fe-1.2 wt % C, Cu-3 wt % Co, Ge-27 wt % Co, Co-10 wt % Mn, Co-8 wt % Mo, Ni-30 wt % Co, Zn-5 wt % Co, Fe-50 wt % Cu, Cu-40 wt % Ge, Cu-50 wt % Ni, Cu-31 wt % Sb, Cu-15 wt % Si, Cu-30 wt % Sn, Cu-8 wt % Ti, Cu-31 wt % Zn, Cu-11 wt % Zr, Fe-35 wt % Ge, Fe-11 wt % Mn, Fe-15 wt % Mo, Fe-6 wt % P, Fe-20 wt % Sb, Fe-19 wt % Si, Fe-alloy material such as 18 wt % Ta, Fe-8 wt % Ti, Ni-25 wt % Ga, Mn-3 wt % Mo, Ni-10 wt % Mn, Ni-25 wt % Mo, Si-13 wt % Mo, Mo-5 wt % Ti, Mo-10 wt % W, Ni-11 wt % P, Ni-17 wt % Pd, Ni-36 wt % Sb, Ni-11.5 wt % Si, Ni-32.5 wt % Sn, Ni-22 wt % Zn, and Sb-9.8 wt % Pd

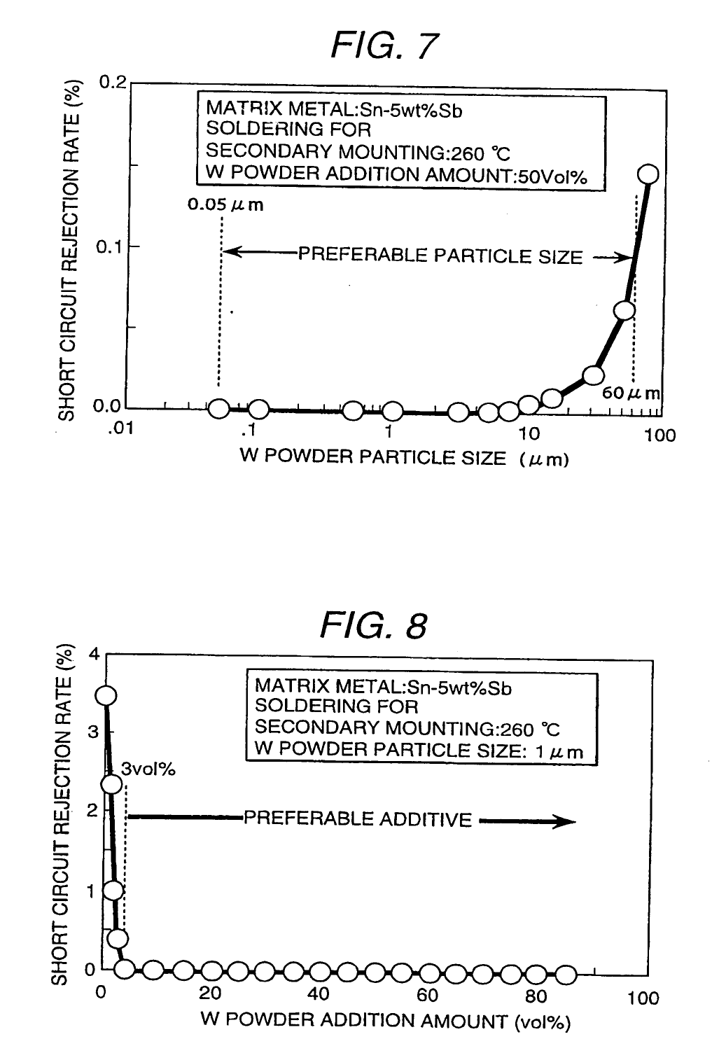

FIG. 7 is a graph showing the effect of W powder particle size on the short circuit rejection rate after the second mounting of the semiconductor device.

When the particle size of W powder 5B is near the range of 0.05 to 10 μm, the short circuit rejection rate is 0% or extremely close to 0%. Therefore, it is more desirable to select the range of 0.05 to 10 μm as a particle size. Moreover, a semiconductor device and a structural body of the present invention are handled with the electronic equipment described later as mass production goods. In this case, it is preferable that a defective rate of each product is 0.1% (level of about −3 σ) from the viewpoint by which products are stably produced. Therefore, the short circuit rejection rate up to 0.1% is the permitted range in the present invention. The particle size of W powder 5B selected as a desirable range is 0.05 to 60 μm from such a viewpoints. Even if metal powder 5B comprises the single metal listed in TABLE 2 or the alloy material comprised of two kinds of materials or more selected from a group of Al, Co, Cr, Cu, Fe, Ge, Mn, Mo, Ni, Sb, Si, W, Zn, Ti, Pd, Ta, Pt, Ag, C, and P, the preferable particle size is in the range of 0.05 to 60 μm, and the more preferable particle size is in the range of 0.05 to 10 μm. From the viewpoint by which the filling rate of metal powder 5B in solders 5 is raised, It is preferable to combine and add metal powder 5B of various particle sizes in the range of 0.05 to 60. m.

FIG. 8 is a graph showing the effect of W powder particle size on the short circuit rejection rate after the second mounting of the semiconductor device.

When W powder is not added, the short circuit rejection rate is 3.5% and high, and defective rates has exceeded the admissible range (0.1%, level of about −3 σ). Moreover, even when the amount of W powder addition is less than 3 vol %, it shows high short circuit rejection rate. This depends on that the amount of W powder 5B is fewer and the following points are not satisfied.
(1) To suppress efficiently the cubical expansion by the remelting of matrix metal 5A.
(2) To improve the substantial viscosity of re-melted solders 5 enough.
(3) To reduce the substantial contact area of melted solders 5 and the material in the surrounding enough.

On the other hand, when the amount of W powder addition rate is in the range of 3 vol % or more, the rejection rate is 0% and under the admissible rejection rate. This is based upon the addition of the amount of W powder 5B enough to satisfy the above-mentioned points (1)-(3). Thus, the range of 3 to 85 vol % is selected as the amount of W powder addition from the viewpoint by which the short circuit failure is prevented. All of matrix metal 5A and metal power 5B described before show the above tendency in common. However, it is necessary to consider the amount of addition of W powder 5B from the viewpoint of the reliability of semiconductor device 11 and structural body 15.

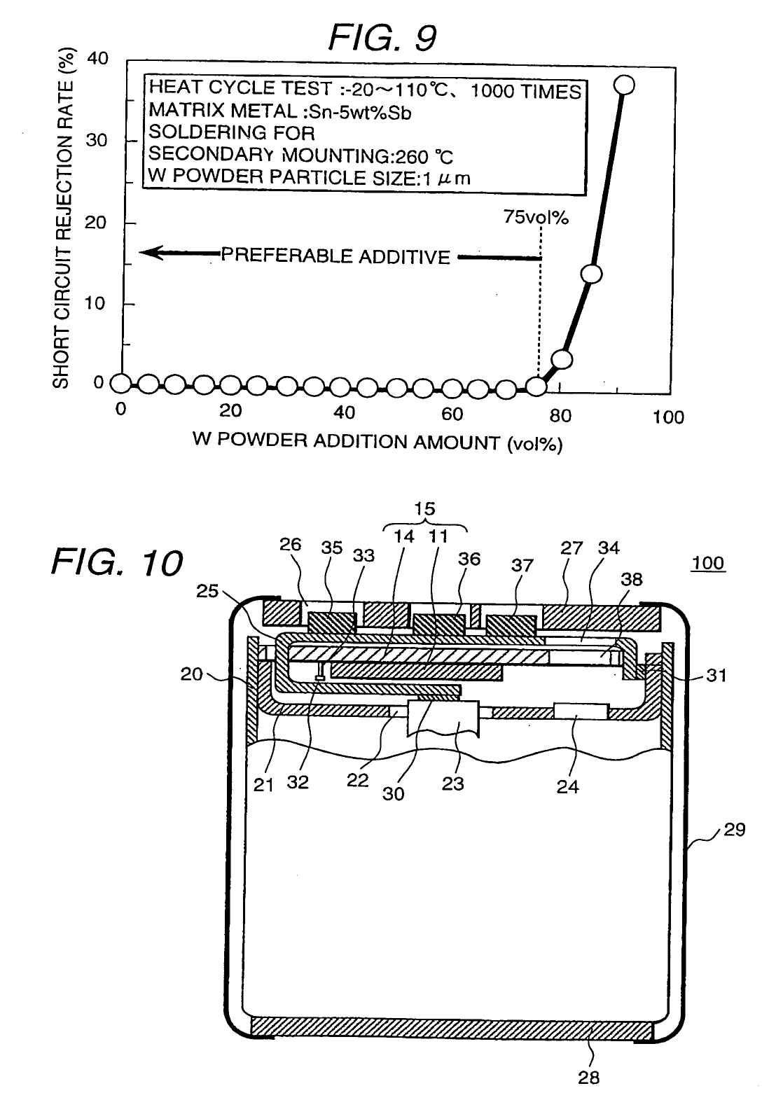

FIG. 9 is a graph showing the effect of W powder particle size on the disconnection rejection rate of the present invention structural body.

The defective disconnection mentioned here is the disconnection by the crack destruction in solder layer 5, and the heat cycle test is executed 1,000 times at −20 to 110° C. As for the disconnection defect rate, when the amount of addition of W powder 5B is in the range of 0 to 75 vol %, the defect rate is 0% or extremely close to 0%, and the excellent result is obtained. However, when it is exceeds 75 vol %, a defective rate is increased. The crack breakdown occurs because an excessive distortion based on the temperature change concentrates on matrix metal 5A in solder layer 5 as the amount of addition of W powder 5B increases. Because the area of matrix metal 5A where the distortion is allotted extends in the range where the amount of addition of W powder 5B is appropriate, the density of the overstress is avoided, and the crack destruction in solder layer 5 is controlled. Thus, the amount of W powder addition is selected to enter in the range of 0 to 75 vol % from the viewpoint by which the disconnection by the crack destruction is prevented.

The above tendency can be applied commonly to all of matrix metal 5A and metal powder 5B mentioned above. A proper amount of addition of W powder 5B is selected to be 3 to 75 vol % from the viewpoint by which the short circuit and the disconnection are prevented as explained above. This proper amount of addition is applied commonly to the case that matrix metal 5A comprises the metal comprised of Sn or the alloy comprised of two kinds or more selected from a group of Pb, Sn, Sb, Zn, Cu, Ni, Au, Ag, P, Bi, In, Mn, Mg, Si, Ge, Ti, Zr, V, Hf, and Pd, and metal powder 5B comprises the single metal listed in Table 2 or the alloy material comprised of two kinds of materials or more selected from a group of Al, Co, Cr, Cu, Fe, Ge, Mn, Mo, Ni, Sb, Si, W, Zn, Ti, Pd, Ta, Pt, Ag, C, and P. It is desirable for matrix metal 5A and metal powder 5B to be in the state of the paste before the chip parts are installed. It is desirable that the amount of addition of metal powder 5B is 5 to 30 vol % from the viewpoint by which the paste to which metal powder 5B is uniformly distributed is made. Metal powders 5B and matrix metal 5A are in the state that both are bonded in metallurgies after the element placement. More preferably, an amount of addition of metal powder 5B is selected to be in the range of 5 to 20 vol % from this viewpoint.

In structural body 15 of this embodiment, semiconductor device 11 is installed (second mounting soldering) on wiring substrate 14 at a work temperature of 260° C. as described above. The defective generation rate of semiconductor device 11 by this heat-treating is 0.00015%, and it is 1/23000 compared with 3.45% of the structural body for the comparison (Sn-5 wt % Sb alloy is applied as a solder layer and the metal powder is not added). A defective mode shows the disappearance of the circuit function by the short circuit in both structural bodies, and the effect of the outflow prevention of solders 5 obtained by the addition of W powder 5B appears clearly in the present invention structural body 15. The prevention of the circuit function from disappearing (the outflow of solders 5) depends on that the cubical expansion of re-melted solders 5 is suppressed to be low by W powder 5B by which the state of the solid phase is maintained even when the second mounting heat-treating is performed, the excessive rise of the internal pressure, flaking off, the outflow of melted solders and the short circuits are controlled, and the outflow of melted solders and the short circuit are controlled by the clogging phenomena of W powder 5B. Moreover, there is the fact that the substantial viscosity of re-melted solders 5 is improved by W powder 5B by which the state of the solid phase is maintained, and the outflow and the short circuit are controlled. In addition, contribution is also given from the fact that W powder 5B narrows the contact area between melted solders 5 (melted matrix metal 5A especially), the Au plating layer on and wiring pattern 4, the Sn plating layer on electrode 105 of chip parts 8 and 9, and Au layer on accumulating metal layer 605 of semiconductor chip 6 at the first mounting soldering, and the uniting of Au and Sn to solder layer is suppressed, too. Although the particle size of W powder 5B used in this embodiment is 1. m, an object of the present invention is achieved even if different particle sizes are used.

When the particle size of W powder 5B is near the range of 0.05 to 60 μm as shown in FIG. 7, the short circuit rejection rate is 0% or extremely close to 0%. Moreover, one with small particle size is not accompanied by displacement and it is possible to install the chip parts for smaller chip parts. Therefore, it is more desirable to select the range of 0.05 to 10 μm as a particle size from such a viewpoint. Moreover, semiconductor device 11 and structural body 15 are handled with the electronic equipment described later as mass production goods. In this case, it is preferable that a defective rate of each product is 0.1% (level of about −3 σ) from the viewpoint by which products are stably produced. Therefore, the short circuit rejection rate up to 0.1% is the permitted range in the present invention. The particle size of W powder 5B selected as a desirable range is 0.05 to 60 μm from such a viewpoints. Even if metal powder 5B comprises the single metal listed in TABLE 2 or the alloy material comprised of two kinds of materials or more selected from a group of Al, Co, Cr; Cu, Fe, Ge, Mn, Mo, Ni, Sb, Si, W, Zn, Ti, Pd, Ta, Pt, Ag, C, and P, the preferable particle size is in the range of 0.05 to 60 μm, and the more preferable particle size is in the range of 0.05 to 10 μm. From the viewpoint by which the filling rate of metal powder 5B in solders 5 is raised, It is preferable to combine and add metal powder 5B of various particle sizes in the range of 0.05 to 60 Am.

It is possible to select true spherical, irregular type spherical, a square, or a cylinder shape as the shape of metal powder 5B.

Although the amount of addition of W powder 5B used by this embodiment is 50 vol %, an object of the present invention is achieved even if a different amount of addition is used.

The short circuit rejection rate is high in the area where the amount of addition of W powder is a little as shown in FIG. 8, and exceeds the admissible range (0.1%, level of about −3 cs). This depends on that the amount of W powder 5B is fewer and the following points are not satisfied.
(1) To suppress efficiently the cubical expansion by the remelting of matrix metal 5A.
(2) To improve the substantial viscosity of re-melted solders 5 enough.
(3) To reduce the substantial contact area of melted solders 5 and the material in the surrounding enough.

On the other hand, when the amount of W powder addition rate is in the range of 3 vol % or more, the rejection rate is 0% and under the admissible rejection rate. This is based upon the addition of the amount of W powder 5B enough to satisfy the above-mentioned points (1)-(3). Thus, the range of 15 to 85 vol % is selected as the amount of W powder addition from the viewpoint by which the short circuit failure is prevented. All of matrix metal 5A and metal power 5B described before show the above tendency in common. However, it is necessary to consider the amount of addition of W powder 5B from the viewpoint of the reliability of semiconductor device 11 and structural body 15.

when the amount of addition of W powder 5B is in the range of 0 to 75 vol %, the disconnection rejection rate of the structural body (the disconnection by the crack destruction in solder layer 5, the heat cycle test: 1,000 times at −20 to 110° C.) is 0% or extremely close to 0%, and the excellent result is obtained. However, when it is exceeds 75 vol %, a defective rate is increased. The crack breakdown occurs because an excessive distortion based on the temperature change concentrates on matrix metal 5A in solder layer 5 as the amount of addition of W powder 5B increases. Because the area of matrix metal 5A where the distortion is allotted extends in the range where the amount of addition of W powder 5B is appropriate, the density of the overstress is avoided, and the crack destruction in solder layer 5 is controlled. Thus, the amount of W powder addition is selected to enter in the range of 0 to 75 vol % from the viewpoint by which the disconnection by the crack destruction is prevented.

The above tendency can be applied commonly to all of matrix metal 5A and metal powder 5B mentioned above. A proper amount of addition of W powder 5B is selected to be 3 to 75 vol % from the viewpoint by which the short circuit and the disconnection are prevented as explained above. This proper amount of addition is applied commonly to the case that matrix metal 5A comprises the metal comprised of Sn or the alloy comprised of two kinds or more selected from a group of Pb, Sn, Sb, Zn, Cu, Ni, Au, Ag, P, Bi, In, Mn, Mg, Si, Ge, Ti, Zr, V, Hf, and Pd, and metal powder BB comprises the single metal listed in Table 2 or the alloy material comprised of two kinds of materials or more selected from a group of Al, Co, Cr, Cu, Fe, Ge, Mn, Mo, Ni, Sb, Si, W, Zn, Ti, Pd, Ta, Pt, Ag, C, and P.

FIG. 14 is a graph showing the short circuit rejection rate of the structural body obtained by using the semiconductor device exposed to the high temperature high humidity atmosphere. Here, sample A is structural body 15 obtained by second mounting soldering of 260° C. after exposing semiconductor device 11 to high temperature high humidity atmosphere for 50 hours, and sample B is structural body 15 obtained by second mounting without exposing semiconductor device 11 to high temperature high humidity atmosphere and both are structural bodies 15 according to this embodiment. Sample C is a comparison example structural body obtained by second mounting without exposing semiconductor device 11 mounted firstly by using the solders to which metal powder is not added to high temperature high humidity atmosphere. The short circuit rejection rate of sample A is 0.00037%, and almost equal to sample B (0.00015%). Sample provides yield ratio better than sample C (3.45%). When semiconductor device 11 is exposed to the high temperature high humidity atmosphere, moisture invades internally through resin layer 10. This moisture deteriorates the joint power on the contact boundary face in chip parts 6, 8, 9, wiring pattern 4, substrate 1, and resin layer 10, and comes to cause an interfacial flaking off easily by the re-melting of solders 5 according to the second mounting soldering and the cubical expansion. However, neither the outflow nor the short circuit of solders 5 are caused in the result of sample A even under the state to cause such an interfacial flaking off easily. This is due to the effect of the addition of W powder 5B.

This embodiment structural body 15 is brought to the heat cycle test of −20 to 110° C. with a comparison example structural body. Here, the circuit function disappearance of semiconductor device 11 based on the crack destruction in solder layer 5 is paid to attention. In the test up to 2000 times, structural body 15 of this embodiment did not show something wrong due to the disappearance of the circuit function of semiconductor device 11. On the other hand, the comparison example structural body did not disappear the circuit function by the test up to 2000 times either.

This results suggest that the connection reliability of solder layer 5 is deteriorated compared with the case not to add the metal powder even if metal powder 5B is added to solder layer 5.

(Embodiment 3)

Structural body 15 obtained by embodiment 2 is applied to the lithium ion accumulator as electronic equipment 100 shown in FIG. 10. Electronic equipment 100 (an accumulator and externals size: 60 mm×30 mm×8 mm) has the following configuration. The accumulator elements such as the positive electrode active material, the negative electrode active material, the positive electrode collector, the negative electrode collector, separators, and the organic electrolyte liquids are housed in metallic case 20 (size: 55 mm×29 mm×7 mm) of having base angle pole type by made of the stainless steel. In this battery, LICoO₂ is used as the positive electrode active material and the carbon which has a graphitized structure is used as the negative electrode active material. The positive electrode active material is maintained in the positive electrode collector comprised of Al, and the negative electrode active material is maintained in the negative electrode collector comprised of Cu. The separator is arranged between the positive electrode active material and the negative electrode active material, and the organic electrolyte liquids is inserted. Metallic lid 21 whose section is concave is fixed to the opening of metallic case 20 which becomes the negative electrode of the accumulator. Positive electrode 23 is provided to the center part of metallic lid 21 through insulating layer 22 made of the glass material. Moreover, safety valve 24 is installed in the hole in the predetermined part of metallic lid 21. Flexible printed board 25 which consists of the polyimide, to which the Cu wiring (not shown) is given, and structural body 15 where semiconductor device 11 is installed on wiring substrate 14 is installed in the space formed by metallic lid 21 and metallic case 20. Semiconductor device 11 has the protection network to prevent the battery accumulator element from overheating by preventing the overelectrical discharge, the overcharge, and the overcurrent as described later to comprises.

The reason why the overcharge and the overelectrical discharge of the accumulator is controlled as follows.

For instance, the decomposition of the positive electrode active material, the decomposition of the organic electrolyte liquids and the extraction of the lithium metal on the negative electrode, etc. are caused if the lithium ion accumulator is overdischarged more than the predetermined voltage of the battery, and they cause the short circuit of the positive and negative pole and the deterioration of cell characteristics, etc. Therefore, it is necessary to avoid the overcharge of the accumulator. Oppositely, the ionization of the metal of the negative electrode collector and the solve-out of the organic electrolyte liquid are caused if the lithium-ion battery is overdischarged below the predetermined voltage of the battery. As a result, the deterioration of collection electric function and the dropout of the negative electrode active material is caused, and the capacity is decreased. This is the reason why the overelectrical discharge must be controlled.

Positive electrode outside terminal 35, negative electrode outside terminal 36, and earth terminal 37 are provided on flexible printed board 25. Positive electrode outside terminal 35 is connected to metallic case 20 through the wiring (not shown) on connection part 30, 31, structural body 15, and flexible printed board 25. Hole 34 and 38 are formed at the positions corresponding to safety valve 24 of wiring substrates 14 of flexible printed board 25 and structural body 15, respectively. Insulation board 27 where holes 26 are provided at the positions corresponding to external terminal 35, 36, and 37 is arranged on flexible printed board 25. Moreover, insulation board 28 is arranged in the bottom side of metallic case 20. An outside face of insulation board 27, metallic case 20, and insulation board 28 is covered with heat contraction tube 29. A charger or an electronic equipment (for instance, feed power to the cellular phone and the personal computer, etc.) is connected between positive electrode outside terminal 35 and negative electrode outside terminal 36 and is supplied to practical use. When electronic equipment 100 of this embodiment is obtained, an important point is that the outflow of re-melted solders 5 and the short circuit due to the outflow are evaded, and structural body 15 obtained as a result is installed when semiconductor device 11 is installed in wiring substrate 14 by the second mounting soldering.

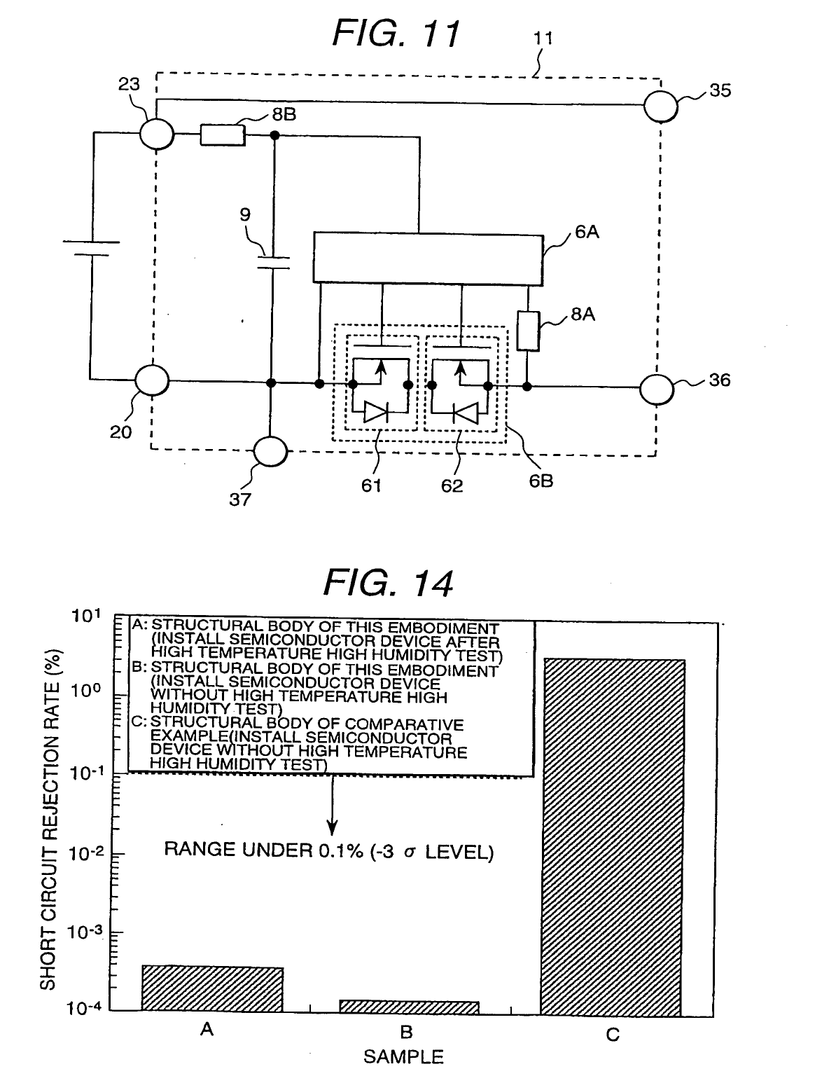

The circuit of semiconductor device 11 shown in FIG. 11 is built into this embodiment electronic equipment 100 of the above-mentioned configuration (lithium ion accumulator). The integrated circuit element 6A, FET element 6B, the chip resistance 8A, and BB and chip capacitor 9 are installed in semiconductor device 11. FET element 6B comprised of FET element 62 for the overvoltage prevention and FET element 61 for the overelectrical discharge prevention is connected between metallic case 20 (the negative electrode is held concurrently) to house the accumulator element and negative electrode outside terminal 36. When the overvoltage is applied between positive electrode 23 and metallic case 20, the integrated circuit element 6A turns off FET element 62. As a result, the overcharge is prevented. Moreover, when the voltage between positive electrode 23 and metallic case 20 drops less than the predetermined voltage by the overelectrical discharge, the integrated circuit element 6A turns off FET element 61. As a result, the overcurrent is prevented.

There is the limit in making of the protection network compact because the element of a discrete type had been used for the element of the second lithium ion protection network installed in the accumulator so far. The lithium ion battery accumulator which is one example of the electronic equipment of the present invention use the semiconductor device where the chip parts as the circuit element is installed on the wiring substrate as a protection network, and the installed chip parts are sealed with the resin. Therefore, in the second lithium ion, the size of metallic case 20 of this embodiment becomes 55 mm×29 mm×7 mm while the size of conventional metallic case 20 is 50 mm×29 mm×7 mm. Therefore, the occupation capacity of the protection network in the accumulator become small, and the occupation capacity of the battery element is able to be increased. As a result, making the accumulator high capacity is achieved, and time that the lithium ion accumulator is able to be operated is increased by a factor of 1.1.

Electronic equipment 100 has semiconductor device 11 suitable for the small size, lightness, the thin type, mass production, and the surface mounting, in which chip parts 6, 8, and 9 as the circuit elements are installed on multi-layer ceramics substrate 1 and the chip parts is sealed with resin layer 10, and structural body 15 in which the outflow of the solders and the short circuit are prevented when semiconductor device 11 is mounted secondly on external wiring substrate 14. As a result, making highly reliable, making efficient, making to high volume efficiency and making to a high density mounting of electronic equipment 100 become possible.

The lithium ion accumulator as this embodiment electronic equipment 100 is suitable for the battery packing for the cellular phone because the highly accurate voltage detector and delay circuit are built into micro package, and there are not external parts either. This feature or the advantage is as follows.
(1) Built-in highly accurate voltage detector
   Overcharge detecting voltage:3.9-4.4 V±25 mV
   Overcharge release voltage:3.8-4.4 V±50 mV
   Overelectrical discharge detecting voltage:2.0-3.0 V±80 mV
   Overelectrical discharge release voltage:2.0-3.4 V±100 mV
   Overcurrent A detecting voltage:0.05-0.3 V±30 mV
   Overcurrent B detecting voltage:0.5 V±100 mV
(2) The application of the high voltage device to the charger connection terminal. (26V in maximum rating voltage)
(3) Various detection delay time
   Overcharge: 1 s
   Overelectrical discharge: 125 ms
   Overcurrent A: 8 ms
   Overcurrent B: 2 ms
   The above-mentioned detection function is given by a built-in circuit. (an external capacitor is unnecessary)
   Small and making to measurement by parts count reduction
(4) Three stage built-in overcurrent detector
   Overcurrent A, overcurrent B, and load short circuit
   Improvement of the safety against short software of the load.
(5) The charge function existence to 0V battery can be selected.
(6) The charger connection detection function and the abnormal charging current detection function are built into.
   Safety to the impression of voltage (24V) of an excessive charger is secured.
(7) Low consumption electric current
   At operation: 3.0 μm.
   When power is downed: 0.1 μm.
(8) The width of the operating temperature is wide.
   −40˜85° C.

Mobile telephone machine portable radio telephone equipment, a portable personal computer, and a portable video camera, etc. are enumerated as examples of the electronic equipment The effects such as miniaturizing, making highly reliable, and making to high performance are achieved in electronic equipment 100 where semiconductor device 11 or structural body 15 of the present invention is installed in these electronic equipment.

(Embodiment 4)

Semiconductor device 11 of which multi-layer ceramics substrate 1 is made of the alumina substrate including internal layer wiring layer 2 where W is distributed to Cu, through hole wiring 2A, external electrode layer 3 and wiring pattern wiring 4 is used in this embodiment. That is, the alumina substrate has the characteristics of a coefficient of thermal expansion: 7.0 ppm/° C., thermal conductivity: 15.2 W/m-K, bend strength: 0.4 Gpa, Young's modulus: 300 GPa and wiring resistance (sheet resistance): 4 mΩ/□. In this case, the composite material where metal powder 5B (particle size: 0.5 to 10 μm and the amount of addition: 30 vol %) comprised of the Ag-28 wt % Cu alloy is distributed to matrix metal 5A comprised of the Pb-50 wt % Sn alloy is used as solders 5 to mount firstly chip parts 6, 8, and 9 by soldering (240° C.). The manufacture process which includes the member configuration and the second mounting soldering other than multi-layer ceramics substrate 1 and solders 5 is similar to embodiment 1. The same performance, advantage, and effect as embodiment 1 are given in the semiconductor device which has the above-mentioned configuration. This semiconductor device 11 is done the second mounting soldering on wiring substrate 14 and is housed in structural body 15, and this structural body 15 is applied to the lithium ion accumulator as electronic equipment 100. In addition, the material configuration other than multi-layer ceramics substrate 1 and solders 5 are similar to embodiments 2 and 3. As a result, the performance excellent as well as said embodiment 2 and 3 is obtained. Especially, the excellent yield is obtained in the short circuit rejection rate of structural body 15 low with 0.00022% as electronic parts for the mass production product. This depends on the effective in the control of the cubical expansion and the outflow of matrix metal 5A by Ag-28 wt % Cu alloy powder 5B added to solders 5. Moreover, structural body 15 did not give something wrong because of the circuit function disappearance of semiconductor device 11 in the test up to 2500 times since structural body 15 of this embodiment is turned on to the heat cycle test of −20 to 110° C. Because Ag-28 wt % Cu alloy powder 5B added to solders 5 is excellent in the wettability to matrix metal 5A, the joint of Ag-28 wt % Cu alloy powder 5B and matrix metal 5A are excellently performed. This is a principal cause to give the excellent connection reliability.

Moreover, the occupation capacity of the protection network housed in lithium ion accumulator 100 has been decreased as well as embodiment 3. As a result, the size of metallic case 20 in this embodiment is able to be increased to 55 mm×29 mm×7 mm while the size of conventional metallic case 20 is 50 mm×29 mm×7 mm. Making the accumulator high capacity is achieved by the occupation capacity of the battery element having been improved, and time that the lithium ion accumulator is able to be operated is increased by a factor of 1.1.

(Embodiment 5)

Semiconductor device 11 obtained by embodiment 4 is installed directly in flexible printed board 25 and the lithium ion accumulator as electronic equipment 100 is obtained. Also in this case, the material configuration same as embodiment 4 is possessed except not using external wiring substrate 14. As a result, the size of metallic case 20 in this embodiment is able to be increased to 55 mm×29 mm×7 mm while the size of conventional metallic case 20 is 50 mm×29 mm×7 mm. Making the accumulator high capacity is achieved by the occupation capacity of the battery element having been improved, and time that the lithium ion accumulator is able to be operated is increased by a factor of 1.1.

(Embodiment 6)

In this embodiment, semiconductor device 11 which composes an electric power multiplication circuit is obtained.

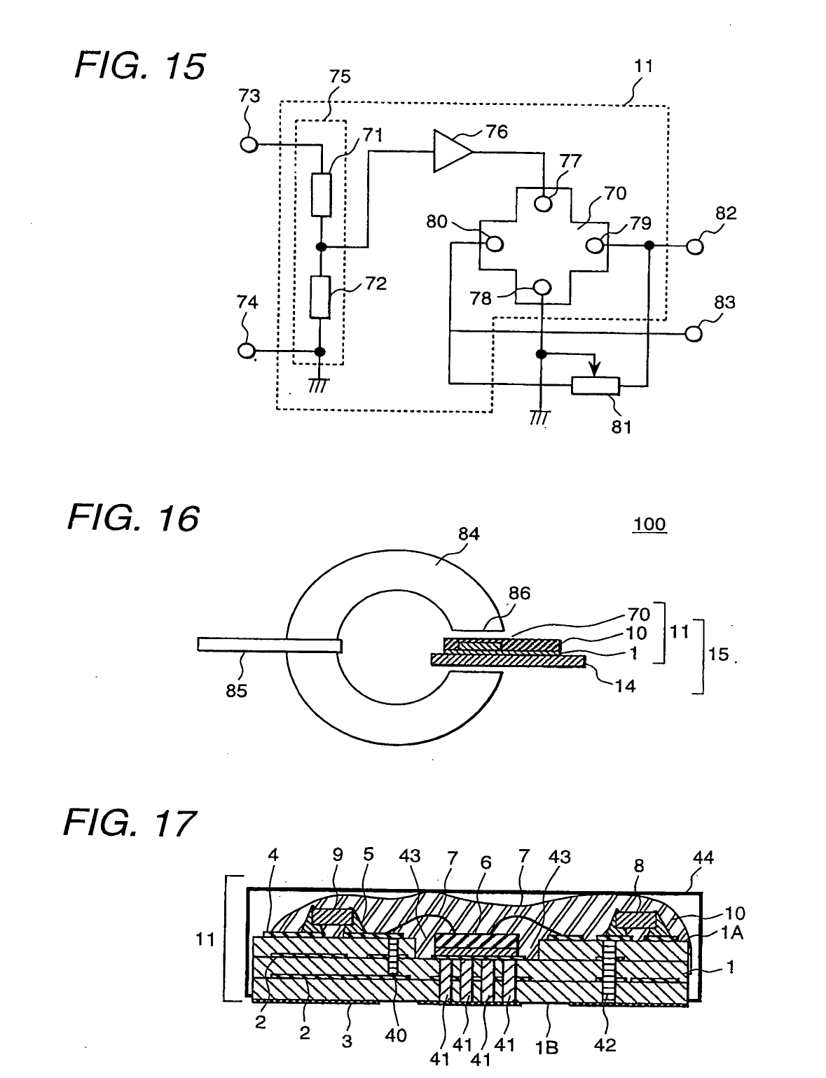

FIG. 15 shows a circuit block diagram of the electric power multiplication circuit arrangement as the semiconductor device of this embodiment. Semiconductor device 11 comprises hall-effect device 70, voltage converting circuit 75, and voltage-electric current converting circuit 76. Chip parts which compose these circuits are bonded firstly on multi-layer ceramics substrate 1 having wiring where W is distributed to Cu and comprised of alumina the coefficient of thermal expansion: 7.0 ppm/° C., thermal conductivity: 15.2 W/m·K, bend strength: 0.4 Gpa, Young's modulus: 300 GPa and wiring resistance (sheet resistance): 4 mΩ/□ as well as embodiment 1. Solders 5 where alloy powder 5B (particle size: 0.5 to 55 μm and amount of addition: 40 vol %) comprised of the Fe-36 wt % Ni alloy is distributed into matrix metal 5A comprised of the Sn-3 wt % Ag-0.5 wt % Cu alloy is used in this soldering. Hereafter, the same wire bonding, resin molding, and individualization division as embodiment 1 is performed.

The size of semiconductor device 11 is miniaturized to 15 mm×10 mm×1.2 mm. The above-mentioned semiconductor devices 11 are bonded comprised (second mounting soldering: 260° C.) on polyimide seat 14 where Cu wiring layer 13 is provided by external wiring connection layer 12 comprised of Sn-3 wt % Ag-0.5 wt % Cu alloy. After structural body 15 obtained thus is exposed to the high temperature high humidity atmosphere (85° C., 85% RH) for 500 hours, it is mounted by second soldering. The short circuit rejection rate of this structural body 15 is 0.00044%, and the excellent yield is given. This result suggests that the interface is not flaked off by the cubical expansion and the re-melting of solders 5 according to the second mounting soldering without decreasing the joint power on the contact boundary face between chip parts, wiring patterns 4, substrates 1, and resin layers 10 even in case of being in the state that moisture invades internally through resin layer 10. This is an effect of the addition of Fe-36 wt % Ni alloy powder 5B.

Structural body 15 of this embodiment is turned on to the heat cycle test of −40-125° C. Here, the circuit function disappearance of semiconductor device 11 based on the crack destruction in solder layer 5 is paid to attention. In the test up to 2000 times, structural body 15 of this embodiment did not show something wrong due to the disappearance of the circuit function of semiconductor device 11. These test results suggests that the excellent connection reliability is maintained even when Fe-36 wt % Ni alloy powder 5B is added to solder layer 5.

FIG. 16 shows a block diagram of the magnetic field generation part. The magnetic field generation part comprises electric current coil 85 wounded around core 84, magnetic field gap 86, semiconductor device 11 where hall-effect device 70 is housed in magnetic field gap 86, and structural body 15 where semiconductor devices 11 is mounted by second soldering on wiring substrate 14.

Hereafter, the function of semiconductor device 11 is explained by using FIG. 15 and FIG. 16.

The power supply voltage in the system to be measured input to the input terminal 73 and 74 is input to voltage—current converting circuit 76 through voltage converting circuit 75 comprised of resistor 71 and 72. Voltage-current converting circuit 76 outputs the electric current proportional to the input voltage to control current terminal 77 of hall-effect device 70. On the other hand, an electric current of the system to be measured is input to current coil 85, and the magnetic field proportional to the input electric current is generated in gap 86.

As a result, the hall electromotive power is generated in voltage output terminals 79, 80 of hall-effect device 70 put to in perpendicular to the direction of the flow of the controlling current of hall-effect device 70 and the magnetic field of gap 86. Variable resistor 81 operate to compensate the offset voltage generated by the asymmetry of the characteristic of hall-effect device 70, and is connected between voltage output terminal 79 and 80. Movable terminal 78 is grounded to the ground. The output is output from output terminal 82 and 83 to the outside. The magnetic field generation part having the above-mentioned configuration is applied for a wattmeter and a watt-hour meter as an electric power multiplication circuit. These wattmeter and watt-hour meter are miniaturized and lightened, and the structure is simplified.

(Embodiment 7)

In this embodiment, semiconductor device 11 as the high-frequency power amplifying device (high frequency power module) used for the transmission part such as cellular telephones, structural body 15 using semiconductor device 11, and cellular phone 100 using structural body 15 are obtained.

FIG. 17 is a diagrammatic sectional view showing the high frequency power module or the semiconductor device of this embodiment. Semiconductor device 11 (8 mm×12.3 mm×2.7 mm) of this embodiment comprises the following configuration. Multi-layer glass ceramics substrate 1 has the characteristics of a coefficient of thermal expansion: 6.2 ppm/° C., thermal conductivity: 2.5 W/m·K, bend strength: 0.25 Gpa, Young's modulus: 110 GPa and permittivity: 5.6 (1 MHz). Internal layer wiring layer 2 (Ag-1 wt % Pt) comprised of two layers, window shade type pier (Ag-1 wt % Pt and diameter:0.14 mm), thermal pier 41 (Ag -1 wt % Pt and diameter: 0.14 mm), and penetration type pier 42 (Ag-1 wt % Pt and diameter: 0.14 mm) are provided in substrate 1. Wiring pattern 4 (Ag-1 wt % Pt and thickness: 0.015 mm) is provided on the first main respect 1A of substrate 1. The chip parts of chip resistance 8 (about 7 ppm/° C.) and chip capacitor 9 (about 11.5 ppm/° C.) are bonded electrically to this wiring pattern 4 with solder layer 5 (first mounting soldering). Cavity 43 is provided on the first main respect 1A, and semiconductor device base body 6 (Si,3.5 ppm/° C. including integrated circuit element base body 6A (not shown) and FET element base body 6B (not shown) are bonded electrically on wiring pattern 4 provided to the bottom with solder layer 5. Here, solder layer 5 comprises the compound body where Ni powder 5B (particle size: 0.05 to 18 μm) is distributed into matrix metal 5A comprised of Pb-12 wt % Sn-8 wt % Sb-1 wt % Ag alloy (melting point: 238° C.), and the amount of addition of Ni powder 5B is adjusted to 40 vol %. Moreover, thin metallic wire 7 made of Au is bonded (integrated circuit element base body 6A: 27. m in diameter and FET element base body 6B: 50. m in diameter) between predetermined parts of semiconductor device base body 6 and wiring pattern 4. These chip parts, thin metallic wires 7, and first main respect 1A are completely sealed from air with the gel resin layer (physical properties after hardening are coefficient of thermal expansions: 210 ppm/° C., Young's modulus: 0.62 MPa and glass transition point: −42° C.). Moreover, surroundings of installed chip parts 6, 8, 9 and resin layer 10 are enclosed with substrate 1 and metallic cap 44 (thickness: 0.15 mm) set in substrate 1. Metallic cap 4 is for preventing an electromagnetic noise. External electrode layer 3 (Ag-1 wt % Pt and thickness:0.015 mm) is provided to the second main respect 1B of substrate 1. Gel resin layer 10 is replaced with various gel resins which have physical properties after hardening of coefficient of thermal expansion: 200 to 9600 ppm/° C., Young's modulus: 90 Pa-11 GPa and penetration number: 55 to 90 (1/10 mm).

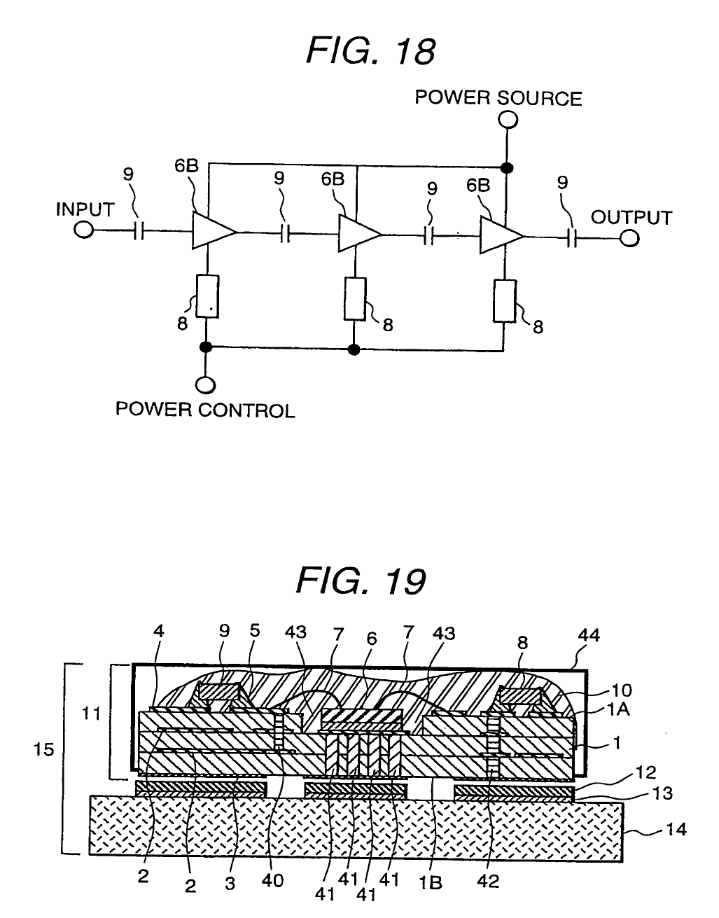

FIG. 18 is a circuit diagram of the semiconductor device of this embodiment. The input signal is amplified to three steps and is output.

In this embodiment, the semiconductor device for the comparison in which chip parts 6, 8, and 9 are installed is made by using the alloy comprised of the Pb-12 wt % Sn-8 wt % Sb-1 wt % Ag alloy as solder layer 5. Here, all the members is the same as this embodiment semiconductor device 11 excluding solder layer 5.

FIG. 19 is a diagrammatic sectional view showing a structural body for the cellular phone.

In structural body 15, the above-mentioned semiconductor device 11 is the one that the second mounting soldering is done on external wiring substrate 14 (glass epoxy, 15 mm×20 mm×1.2 mm, and coefficient of thermal expansion: 14.0 ppm/° C. and Young's modulus: 170 GPa). External wiring 13 comprised of the Cu layer of 25. m in thickness is provided on external wiring substrate 14, and external electrode layer 3 of semiconductor device 11 is bonded to external wiring 13 by the second mounting soldering (work temperature: 260° C.) using Sn-3.5 wt % Ag (melting point: 221° C.) as external wiring connection layer 12. Here, the above-mentioned semiconductor device for comparison is obtained in the same way.

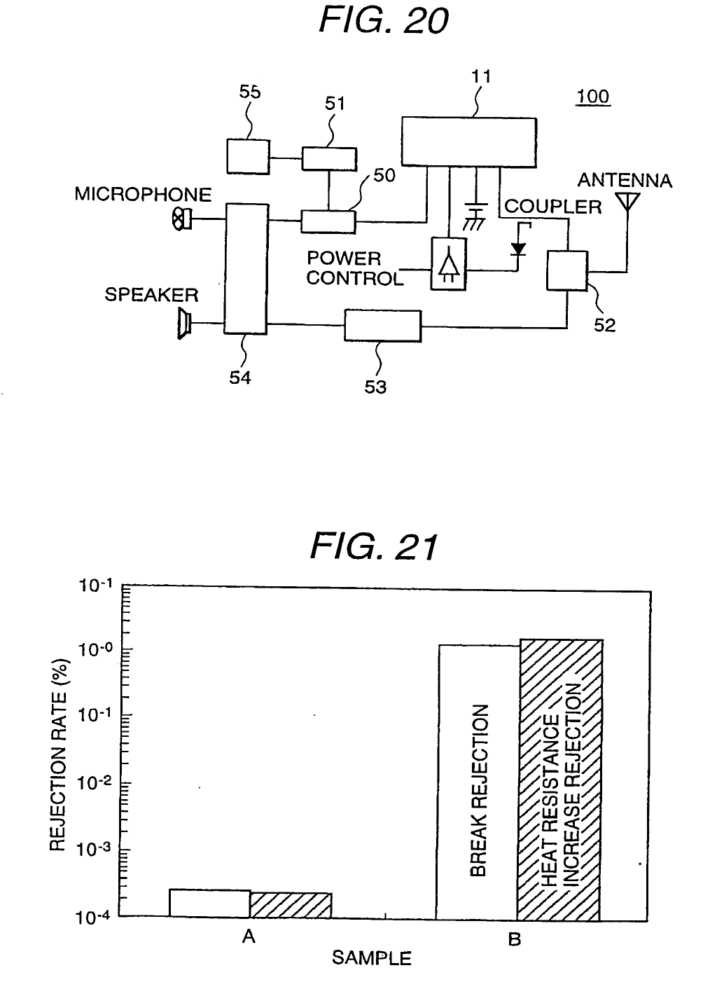

FIG. 20 is a circuit block diagram of the cellular phone where the structural body of this embodiment is applied.

The input aural signal is converted into the high frequency signal from transmitter 51 by mixer 50, and transmitted from the antenna as an electric wave through this embodiment structural body 15 or power amplifier and antenna common machine 52. The transmission electric power is monitored by the coupler, and kept constant by the control signal to this embodiment structural body 15 which is the power amplifier. Here, antenna common machine 52 and the antenna are loads in the present invention. The cellular phone is miniaturized and lightened, and the structure is simplified by using the above-mentioned configuration.

FIG. 21 is a graph showing the disconnection defect rate and the thermal resistance increase defect rate of the structural body of this embodiment.

Here, sample A is structural body 15 of the present invention where semiconductor device 11 is applied, and sample B is structural body 15 obtained by mounting secondly semiconductor device for the comparison. The defective disconnection mentioned here means the state that solder layer 5 is cut by chip parts 8 and 9 coming to the surface in the direction of Y or moving in the direction of X (displacement) due to the thermal deformation of resin layer 10 as explained by FIG. 3(d), and is intercepted electrically between electrode 105 and wiring pattern 4. Moreover, a thermal resistance defective increase means the state that semiconductor device base body 6 (6A, 6B) comes to the surface in the direction of Y by the thermal deformation of resin 10 as explained by FIG. 3(c), the fringing part of solder layer 5 is narrowed, and, therefore, to enter the state that the heat radiation of semiconductor device base body 6 is obstructed as the result (the state that the thermal resistance after second mounting soldering reaches twice thermal resistance after the first second mounting soldering). The disconnection defect rate and the thermal resistance increase defect rate of sample A are 0.00023% and 0.00022%, respectively, and the disconnection defect rate of sample A is far more excellent than that (the disconnection defect rate:1.38% and the thermal resistance increase defect rates:1.93%) of sample B. Ni powder 5B is added to solder layer 5 of sample A, and the viscosity of re-melted solders 5 (Matrix metal 5A more accurately) is improved substantially by this existence of powder 5B. As a result, chip parts 8 and 9 are prevented from coming to the surface and the displacement even if the thermal deformation of resin 10 is caused, and to arrive at the state of the disconnection is evaded.

Moreover, the fringing part in solder layer 5 is never narrowed because semiconductor device base body 6 (6A, 6B) is prevented from coming to the surface and the heat radiation of semiconductor device base body 6 is maintained. The viscosity of re-melted solders decreases for sample B because the metal powder is not added to the solder layer. As a result, coming to the surface or displacement of chip parts 8 and 9 and coming to the surface of and semiconductor device base body 6 (6A, 6B) are caused, and the state of the disconnection and the state of the thermal resistance increase are occurred. The point that the defective generation rate of this embodiment structural body 15 is greatly decreased as explained above is an effect of the addition of Ni powder 5B to solder layer 5.

Structural body 15 of this embodiment is turned on to the heat cycle test of 40 to 125° C. with the structural body for the comparison. Here, the circuit function disappearance of semiconductor device 11 based on the crack destruction in solder layer 5 is paid to attention. In the test up to 2000 times, structural body 15 of this embodiment di d not show something wrong due to the disappearance of the circuit function of semiconductor device 11. On the other hand, the comparison example structural body did not show something wrong due to the circuit function disappearance in the test up to 2000 times.

This results suggest that the connection reliability of solder layer 5 is deteriorated compared with the case not to add the metal powder even if metal powder 5B is added to solder layer 5.

(Embodiment 8)

In this embodiment, semiconductor device 11 as a different type of high-frequency power amplifying device (high frequency power module) used for the transmission part such as cellular telephones, structural body 15 using semiconductor device 11, and cellular phone 100 using structural body 15 are obtained.

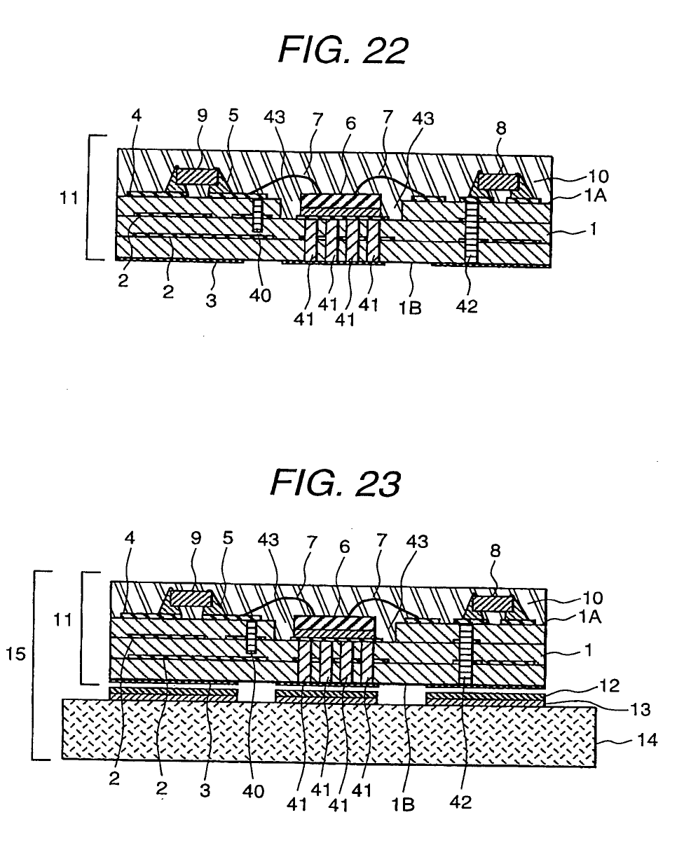

FIG. 22 is a diagrammatic sectional view showing the high frequency power module as this embodiment semiconductor device is explained.

In semiconductor device 11 (8 mm×12.3 mm×2.5 mm) of this embodiment, the resin layer whose principal ingredient is a epoxy (physical properties after hardening are coefficient of thermal expansion: 9.0 ppm/° C., Young's modulus: 24.5 Gpa, glass transition point:150° C. and amount of the filler addition: 85 wt %) is applied as resin layer 10. The member configuration other than resin layer 10 is similar to the semiconductor device made in embodiment 7, and the circuit shown in FIG. 19 is included.

In this embodiment, the alloy comprised of the Pb-12 wt % Sn-8 wt % Sb-1 wt % Ag alloy is used as solder layer 5. Further, the semiconductor device for the comparison where chip parts 6, 8, and 9 are installed is also made. Here, all the member configuration is the same as semiconductor device 11 of this embodiment excluding solder layer 5.

FIG. 23 is a diagrammatic sectional view showing the structural body for a cellular phone.

In structural body 15, the above-mentioned semiconductor device 11 is bonded secondly on external wiring substrate 14 (glass epoxy, 15 mm×20 mm×1.2 mm, and coefficient of thermal expansion: 14.0 ppm/° C. and Young's modulus: 170 GPa).

External wiring 13 comprised of the Cu layer of 25. m in thickness is provided on external wiring substrate 14, and external electrode layer 3 of semiconductor device 11 is bonded to external wiring 13 by the second mounting soldering (work temperature: 260° C.) using Sn-3.5 wt % Ag (melting point: 221° C.) as external wiring connection layer 12. Here, the above-mentioned semiconductor device for comparison is obtained in the same way. This embodiment structural body 15 comprised of the above-mentioned configuration has the circuit for the cellular phone shown in FIG. 21.

The cellular phone 100 is miniaturized and lightened, and the structure is simplified by using the above-mentioned configuration

The defect which occurs in the structure sealed with resin layer 10 where the Young's modulus is high like semiconductor device 11 and structural body 15, etc. according to this embodiment is the short circuit due to the outflow of re-melted solders 5.

The defect based on the thermal resistance increase by the displacement disconnection and coming to the surface seen in the structure sealed with the resin layer where the coefficient of thermal expansion is high and the Young's modulus is high like said embodiment 7, is not caused. Moreover, the short circuit rejection rate of structural body 15 of this embodiment is 0.00033% and low, and the defective rate is far better than 2.75% of the structural body for the comparison. This is based upon the same effect as said embodiment 2 obtained by Ni powder 5B added to solder layer 5.

(Embodiment 9)

Semiconductor device 11 which uses wiring substrate 1 where the resin is made a matrix is explained in this embodiment.

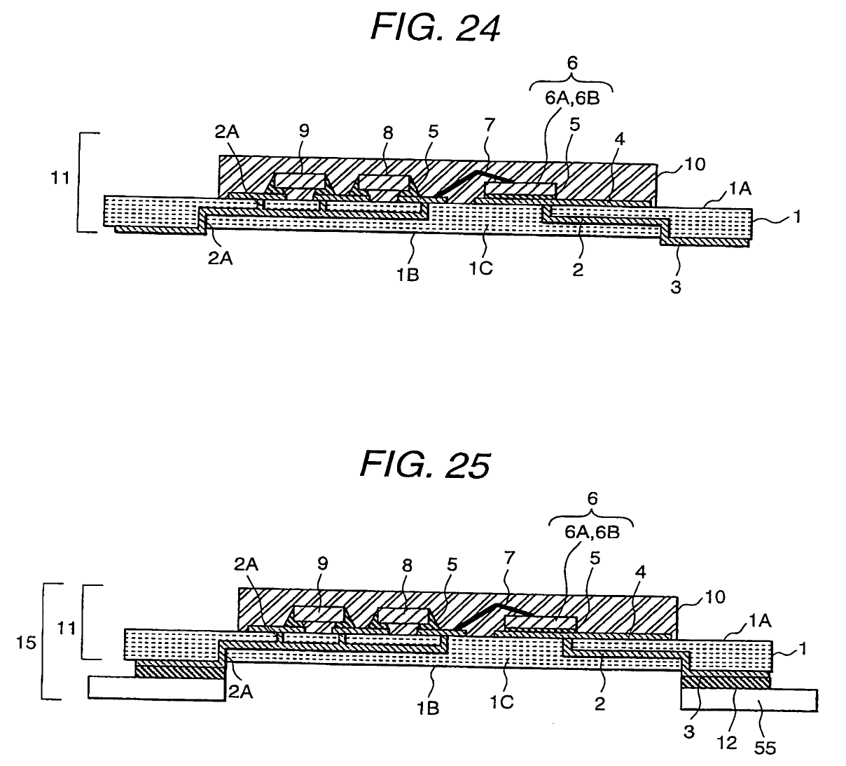

FIG. 24 is a diagrammatic sectional view showing the semiconductor device of this embodiment. Semiconductor device 11 comprises as follows. Internal layer wiring layer 2 (Cu and thickness:15 μm) and through hole wiring 2A (Cu and plating formation) are provided inside of multi-layer glass epoxy substrate 1 (30 mm×7 mm×0.4 mm). Wiring pattern 4 (Cu and thickness: 25 μm and Ni plating of 5 μm in thickness and the Au plating of 1 μm in thickness are formed in order) is provided to the first main respect 1A of substrate 1. The chip parts comprised of semiconductor device base body (Si, 3.5 ppm/° C.) 6 which contains the integrated circuit element base body 6A (not shown) and FET element base body 6B, chip resistance 8 (about 7 ppm/° C.), and capacitor 9 (about 11.5 ppm/° C.) are bonded electrically on wiring pattern 4 by solder layer 5 (first mounting soldering and work temperature: 270° C.). Solder layer 5 comprises the compound body where Fe-19 wt % Si powder 5B (particle size: 1. m) to matrix metal 5A comprised of Sn-5 wt % Sb alloy, and the amount of addition of Fe-19 wt % Si powder 5B is adjusted to 45 vol %. Moreover, thin metallic wire 7 made of Au is bonded (integrated circuit element base body 6A: 27 μm in diameter and FET element base body 6B: 50 μm in diameter) between the predetermined parts of semiconductor device base body 6 and wiring pattern 4. These chip parts, thin metallic wires 7, and the first main respect 1A are completely sealed so as to be intercepted from ambient air with resin layer 10 whose principal ingredient is epoxy material (physical properties after hardening are coefficient of thermal expansions: 9.0 ppm/° C., Young's modulus: 24.5 Gpa, glass transition point: 150° C. and amount of the filler addition: 85 wt %).

This resin layer 10 (size:10.5 mm×4 mm×0.8 mm) is formed by the potting method. External electrode layer 3 (Cu of 25 μm in thickness, Ni plating of 5 μm in thickness and the Au plating of 1 μm in thickness are formed in order) is provided on the second main respect 1B on the other side of the first main respect 1A of substrate 1. External electrode layer 3 is connected electrically to wiring pattern 4 via internal layer wiring layer 2 and through hole wiring 2A provided inside of substrate 1. Because chip parts 6, 8, and 9 are bonded electrically on wiring pattern 4 with solder layer 5, external electrode layer 3 is connected electrically to these chip parts. Each chip part is completely enclosed with substrate 1, wiring pattern 4, and resin layer 10 as explained above. Moreover, solder layer 5 where these chip parts are bonded is completely enclosed with chip parts 6, 8, 9, wiring pattern 4, and resin layer 10.

At the stage before semiconductor device 11 is made, multi-layer glass epoxy substrate 1 is like a frame (take of 8 pieces). After the mounting of chip parts 6, 8, and 9, the wire bonding, and the resin molding are ended, the individualization is carried out by cutting which uses the rotation braid. Moreover, external electrode layer 3 is not necessary to be formed on the second main respect 1B side, and can be formed on the first main respect 1A side if necessary.

Because solder layer 5 comprises the compound body where Fe-19 wt % Si powder (particle size: 1. m) is distributed into matrix metal 5A comprised of Sn-3.5 wt % Ag alloy in semiconductor device 11 explained above, it is possible to prevent the outflow of matrix metal 5A, and the short circuit and the disconnection due to the outflow even if the re-melt is caused when second mounting soldering described later is carried out.

(Embodiment 10)

In this embodiment, structural body 15 of the form where the metallic member is connected to semiconductor device 11 obtained in embodiment 9.

FIG. 25 is a diagrammatic sectional view showing the structural body of this embodiment.

Ni board 55 (10 mm×3 mm×0.4 mm) is bonded (second mounting soldering and work temperature: 260° C.) to external electrode layer 3 of semiconductor device 11 by using Sn-3 wt % Ag-0.5 wtCu solders (melting point: 221° C.) or external wiring connection layer 12. This Ni board 55 has the role of the wiring member to connect electrically semiconductor device 11, metallic case 20 (which doubles with negative electrode concurrently) where the battery accumulator element are housed and positive electrode 23. Even when the member connected to external electrode layer 3 of semiconductor device 11 is metal member 55 and the configuration does not provide the form of the wiring substrate, the member falls within the range of the definition of structural body 15 in the present invention. Structural body 15 of this embodiment is made by soldering secondly at a work temperature of 260° C. as described above.

The effect of the outflow prevention of solders 5 based on the addition of Fe-19 wt % Si powder 5B appears clearly because the short circuit rejection generation rate of semiconductor device 11 by this heat-treating is 0.00035% and low.

The prevention of the outflow of solders 5 depends on that the cubical expansion of re-melted solders 5 is suppressed to be low by W powder 5B by which the state of the solid phase is maintained even when the second mounting heat-treating is performed, the excessive rise of the internal pressure, flaking off, the outflow of melted solders and the short circuits are controlled, and the outflow of melted solders and the short circuit are controlled by the clogging phenomena of W powder 5B. Moreover, there is the fact that the substantial viscosity of re-melted solders 5 is improved by W powder 5B by which the state of the solid phase is maintained, and the outflow and the short circuit are controlled. In addition, contribution is also given from the fact that W powder 5B narrows the contact area between melted solders 5 (melted matrix metal 5A especially), the Au plating layer on and wiring pattern 4, the Sn plating layer on electrode 105 of chip parts 8 and 9, and Au layer on accumulating metal layer 605 of semiconductor chip 6 at the first mounting soldering, and the uniting of Au and Sn to solder layer is suppressed, too.

As for the metal which causes the same action as Fe-19 wt % Si powder 5B, the various metals listed in Table 2 can be applied even if the matrix of substrate 1 is made of the resin material in the present invention. Moreover, it is possible to apply as long as it is a powder even if it is the alloy material composed of two kinds of materials or more selected from a group of Al, Co, Cr, Cu, Fe, Ge, Mn, Mo, Ni, Sb, Si, W, Zn, Ti, Pd, Ta, Pt, Ag, C, and P. Although the particle size powder 5B used by this embodiment is 1. m, an object of the present invention is achieved even if the different particle size is used. The particle size of powder 5B is selected preferably within the range of 0.05 to 60 μm. Even if the metal powder is comprised of single metal listed in Table 2 or the alloy made of two kinds or more selected from a group of Al, Co, Cr, Cu, Fe, Ge, Mn, Mo, Ni, Sb, Si, W, Zn, Ti, Pd, Ta, Pt, Ag, C, and P, the desirable range of particle size is between 0.05 and 60 μm, and the more desirable range of particle size is between 0.05 and 10 μm. From the viewpoint by which the filling rate of metal powder 5B in solders 5 is raised, It is preferable to combine and add metal powder 5B of various particle sizes in the range of 0.05 to 60. m. It is possible to select true spherical, irregular type spherical, a square, or a cylinder shape as the shape of metal powder 5B. Although the amount of addition of W powder 5B used by this embodiment is 45 vol %, an object of the present invention is achieved even if a different amount of addition is used. 3 to 75 vol % is selected as a proper amount of addition of powder 5B, from the viewpoint by which the short circuit and the disconnection are prevented.

Even if the matrix metal 5A is the metal comprised of Sn or the alloy made of two kinds or more selected from a group of Sn or Pb, Sn, Sb, Zn, C u, Ni, Au, Ag, P, Bi, In, Mn, Mg, Si, Ge, Ti, Zr, V, Hf, or even if the metal powder 5B is comprised of single metal listed in Table 2 or the alloy made of two kinds or more selected from a group of Al, Co, Cr, Cu, Fe, Ge, Mn, Mo, Ni, Sb, Si, W, Zn, Ti, Pd, Ta, Pt, Ag, C, and P, the proper range of the diameter range and the proper amount of the addition mentioned above is the same.

Structural body 15 of this embodiment is turned on to the heat cycle test of −20 to 110° C. Here, the circuit function disappearance of semiconductor device 11 based on the crack destruction in solder layer 5 is paid to attention. In the test up to 2000 times, structural body 15 of this embodiment did not show something wrong due to the disappearance of the circuit function of semiconductor device 11.

(Embodiment 11)

Structural body 15 obtained in embodiment 10 is applied to the lithium ion accumulator as electronic equipment 100. Electronic equipment 100 (battery accumulator and externals size: 60 mm×30 mm×8 mm) composes the circuit shown in FIG. 11, and semiconductor device 11 or structural body 15 installed therein has the role as the protection network to prevent the overelectrical discharge, the overcharge, and the overcurrent, and to prevent the overheating of the accumulator element.

The same operation and effect as embodiment 3 are given in the second lithium ion cell 100 which has the above-mentioned configuration.

(Embodiment 12)

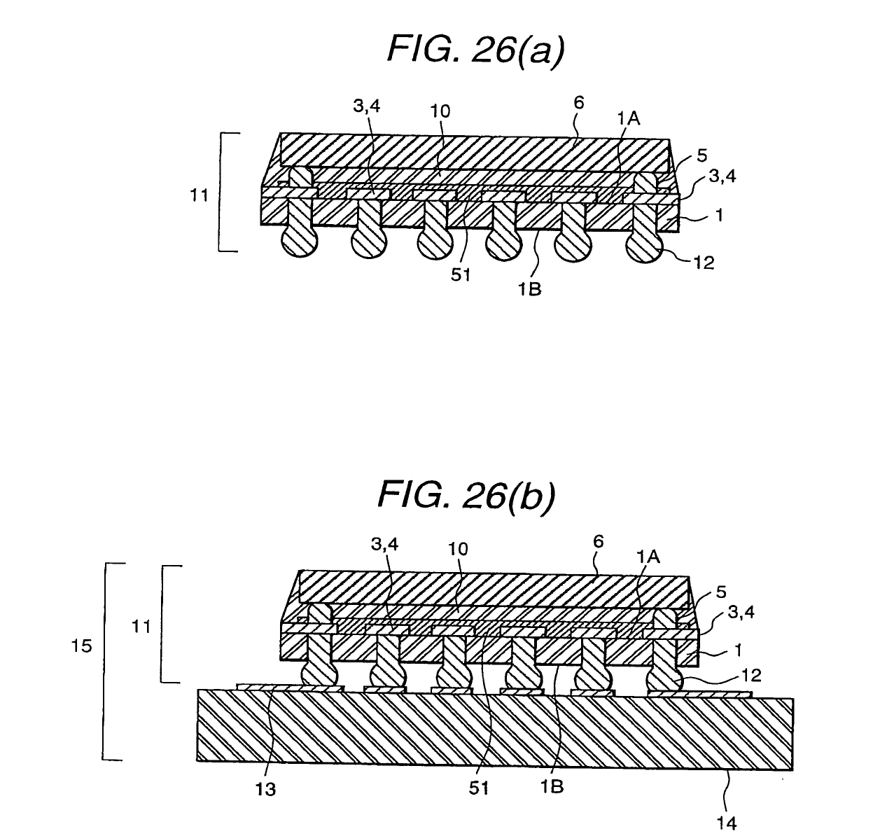

CSP(Chip Scale Package) type semiconductor device 11 and structural body 15 installing the same in the external wiring substrate is explained in this embodiment FIG. 26 is a diagrammatic sectional view showing a semiconductor device of this embodiment and a structural body using the same. Semiconductor device 11 is made as shown in (a). Wiring pattern 4 (Cu and thickness: 25 μm and Ni plating of 5. m in thickness and the Au plating of 1 μm in thickness are formed in order) is provided on the first main respect 1A of polyimide substrate 1 (11 mm×11 mm×0.3 mm). The chip parts comprised of integrated circuit element base body (10 mm×10 mm×0.3 mm) 6 are bonded (first mounting soldering and the work temperature: 270° C.) electrically on this wiring pattern 4 with solder layer 5 (pitch: 0.01 mm). Solder layer 5 comprises the compound body where Ni powder 5B (particle size: 0.05 to 0.5. m) is distributed into matrix metal 5A comprised of Sn-3.5 wt % Ag alloy, and the amount of addition of Ni powder 5B is adjusted to 45 vol %. Epoxy resin 10 is filled to the gap (about 50 μm) between the integrated circuit element base body 6 and polyimide substrate 1, and solder layer 5 is sealed so as to be intercepted completely from ambient air. Epoxy resin 10 comprises bisphenol A, methylic hexahydro phthalic anhydride as the anhydride system hardener, amine as the hardening accelerator, and organic acid. Here, solder resist film 51 is provided to the predetermined parts (parts other than the area where solder layer 5 is formed) of wiring pattern 4 provided on the first main respect 1A. Moreover, wiring pattern 4 doubles with external electrode layer 3 concurrently, and solder ball 12 (Sn-3 wt % Ag-0.7 wt % Cu and diameter: about 0.15 mm) for the external wiring connection is formed aiming at the second main respect 1B side of substrate 1. Although metal powder 5B is not added to solder ball 12 for the external wiring connection in this embodiment, adding is desirable if necessary.

Because solder layer 5 comprises the compound body where Ni powder 5B is distributed into matrix metal 5A comprised of Sn-3.5 wt % Ag alloy in semiconductor device 11 explained above, it is possible to prevent the outflow of matrix metal 5A, and the short circuit and the disconnection due to the outflow even if the re-melt is caused at second mounting soldering described later.

Next, structural body 15 using the above-mentioned semiconductor device 11 is made as shown in (b). Semiconductor devices 11 are bonded to external wiring 13 of wiring substrate 14 having the same as said embodiment 2 (Cu and thickness: 25 μm) with solder ball 12 for the external wiring connection. In this case, the second mounting soldering with solder ball 12 is executed at 260° C.

The defective (disappearance of the circuit function by the short circuit or the disconnection) generation rate of semiconductor device 11 on structural body 15 of this embodiment is 0.00039%, and this is an extremely low value. This is due to the effect of the outflow prevention of solders 5 by the addition of Ni powder 5B. This effect of the outflow prevention is based upon the control of the cubical expansion of re-melted solders 5, the control of liquidity, the clogging phenomena by Ni powder 5B, the decrease of the substantial contact area between melted matrix metal 5A and wiring pattern 4.

The heat cycle test of −30 to 125° C. is given to structural body 15 of this embodiment. Here, the circuit function disappearance of semiconductor device 11 based on the crack destruction in solder layer 5 is paid to attention. In the test up to 2000 times, structural body 15 of this embodiment did not show something wrong due to the disappearance of the circuit function of semiconductor device 11.

In this embodiment, semiconductor device 11 and structural body 15 using the same have been explained in this embodiment, in which integrated circuit element base body 6 is bonded to wiring pattern 4 on polyimide substrate 1 with layer 5 where the Ni powder is added, and epoxy resin 10 is filled into the gap between integrated circuit element base body 6 and polyimide substrate 1. In this embodiment, neither semiconductor device 11 nor structural body 15 are limited to the above-mentioned form.

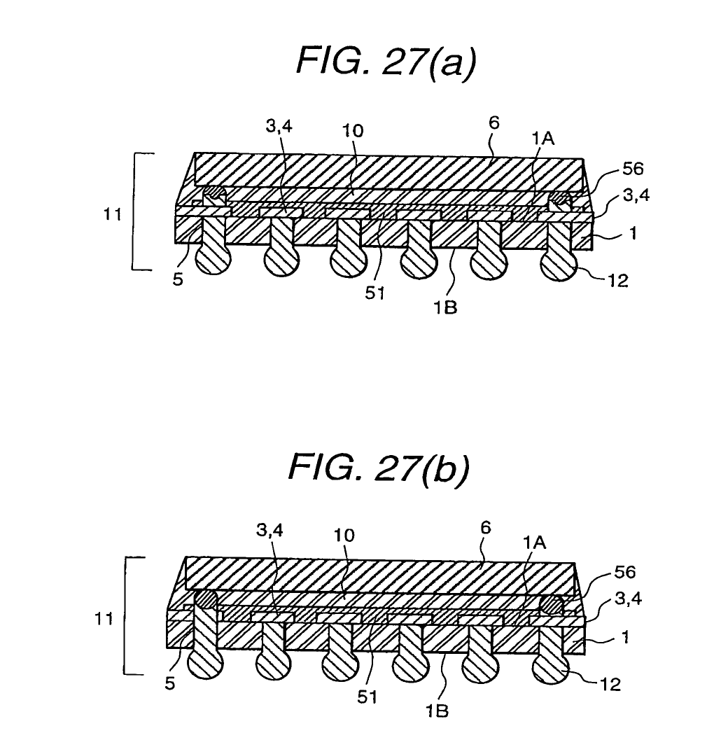

FIG. 27 is a diagrammatic sectional view showing a CSP type semiconductor device in another form.

Semiconductor devices 11 are bonded to wiring pattern 4 of substrate 1 with solder layer 5 comprised of metal powder 5B and matrix metal 5A through Au bump 56 provided to integrated circuit element base body 6 by the technique of the wire bonding as shown in (a). Au bump 56 can be formed also by the wire bonding of Cu and Al. Moreover, semiconductor devices 11 shown in (b) are bonded to wiring pattern 4 of substrate 1 with solder layer 5 comprised of metal powder 5B and matrix metal 5A through metallic ball 56 such as Cu, Ni, and Cu-Sn alloy. Even if it is semiconductor device 11 of the above-mentioned configuration, the same effect as this embodiment is achieved. Although structure body 15 is not shown in figure, the same effect as this embodiment is achieved for structural body 15 that the above semiconductor device 11 is installed in wiring substrate 14. Semiconductor device 11 and structural body 15 explained above can play the role of the package where making to multi pins, the miniaturization, and making to the thin type are required accord ing to the needs such as making of the integrated circuit, making to the large-scale, speeding up, and making to the multifunction. Such semiconductor device 11 and structural body 15 are suitable for mounting on personal digital assistant equipment and camera all-in-one design VTR.

(Embodiment 13)

In this embodiment, CSP type semiconductor device 11 in another form and structural body 15 that the device is installed on the external wiring substrate.

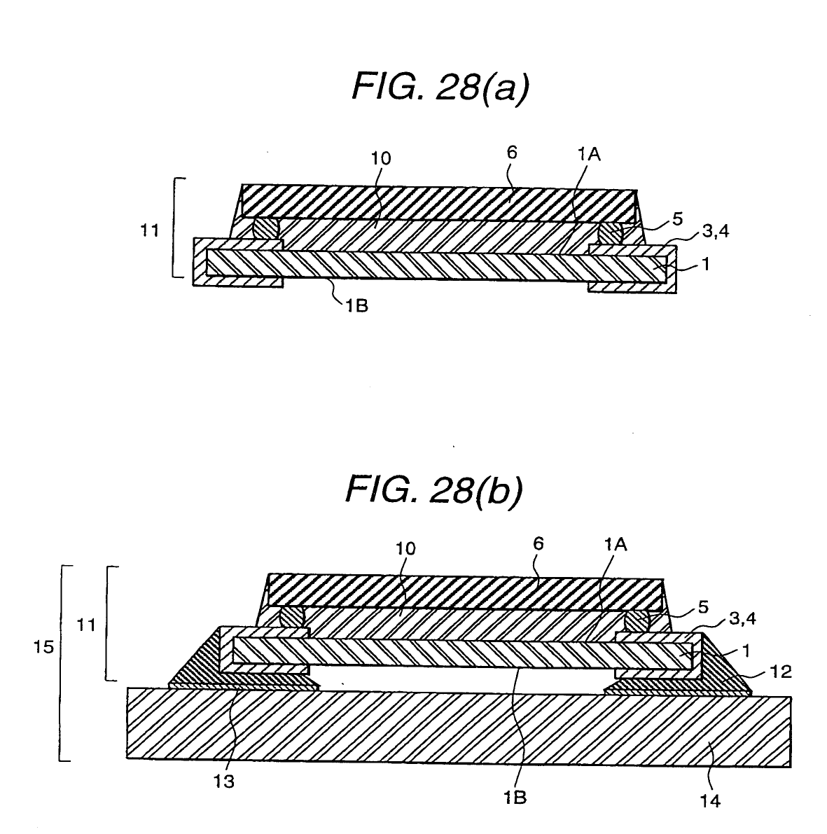

FIG. 28 is a diagrammatic sectional view showing the semiconductor device of this embodiment and the structural body using the same. Semiconductor device 11 is made as shown in (a). Nitride aluminium substrate, nitride silicon substrate, glass substrate, and beryllia substrate (12 mm×12 mm×0.3 mm) are used as wiring substrate 1. Wiring pattern 4 (Cu of 25 μm in thickness, Ni plating of 5 μm in thickness and the Au plating of 1 μm in thickness are formed in order) is provided to the first main respect 1A of substrate 1, and the chip parts comprised of integrated circuit element base body (10 mm×10 mm×0.3 mm) 6 are bonded (first mounting soldering and the work temperature: 270° C.) electrically on this wiring pattern 4 with solder layer 5 (pitch: 0.1 mm). Solder layer 5 comprises the compound body where Ni powder 5B (particle size: 0.05 to 0.5 μm) is distributed into matrix metal 5A comprised of Sn-3.5 wt % Ag alloy. In this embodiment, the amount of addition of Ni powder 5B is adjusted to 25 vol %. Epoxy resin 10 is filled to the gap (about 50 μm) between the integrated circuit element base body 6 and polyimide substrate 1, and solder layer 5 is sealed so as to be intercepted completely from ambient air. Epoxy resin 10 comprises bisphenol A, methylic hexahydro phthalic anhydride as the anhydride system hardener, amine as the hardening accelerator, and organic acid. Moreover, wiring pattern 4 doubles with external electrode layer 3 concurrently, and extends in a direction of the second main respect 1B from the first main respect 1A of substrate 1 via the side.

Because solder layer 5 comprises the compound body where Ni powder 5B is distributed into matrix metal 5A comprised of Sn-3.5 wt % Ag alloy in semiconductor device 11 explained above, it is possible to prevent the outflow of matrix metal 5A, and the short circuit and the disconnection due to the outflow even if the re-melt is caused when second mounting soldering described later is carried out.

Next, structural body 15 using the above-mentioned semiconductor device 11 is made as shown in (b). Semiconductor devices 11 are bonded to external wiring 13 (Cu and thickness: 25. m) of wiring substrate 14 made of the same material as embodiment 2 with solder layer 12 (Sn-3.5 wt % Ag alloy) for the external wiring connection. In this case, the second mounting soldering with solder layer 12 is executed at 260° C.

The defective (the disappearance of the circuit function by the short circuit and the disconnection) generation rate of semiconductor device 11 in structural body 15 of this embodiment is 0.00023 to 0.00063% in any case that wiring substrate 1 is made of the nitride aluminium substrate, the nitride silicon substrate, the glass substrate, and the beryllia substrate. This is an extremely low value. This is due to the effect of the outflow prevention of solders 5 by the addition of Ni powder 5B. This effect of the outflow prevention is based upon the control of the cubical expansion of re-melted solders 5 by Cu powder 5B, the control of liquidity, clogging phenomena, and the decrease of the substantial contact area between melted matrix metal 5A and wiring pattern 4.

The heat cycle test of −30 to 125° C. is given to structural body 15 of this embodiment. Here, the disappearance of the circuit function of semiconductor device 11 based on the crack destruction in solder layer 5 is paid to attention. In the test up to 2000 times, structural body 15 of this embodiment, which uses the nitride aluminium substrate, the nitride silicon substrate, the glass substrate, and the beryllia substrate as wiring substrate 1, did not show something wrong due to the disappearance of the circuit function of semiconductor device 11. Semiconductor device 11 and structural body 15 explained above can play the role of the package where making to multi pins, the miniaturization, and making to the thin type are required according to the needs such as making of the integrated circuit, making to the large-scale, speeding up, and making to the multifunction. Such semiconductor device 11 and structural body 15 are suitable for mounting on personal digital assistant equipment and camera all-in-one design VTR.

(Embodiment 14)

In this embodiment, CSP type semiconductor device 11 in a further form and structural body 15 where the device is installed on the external wiring substrate.

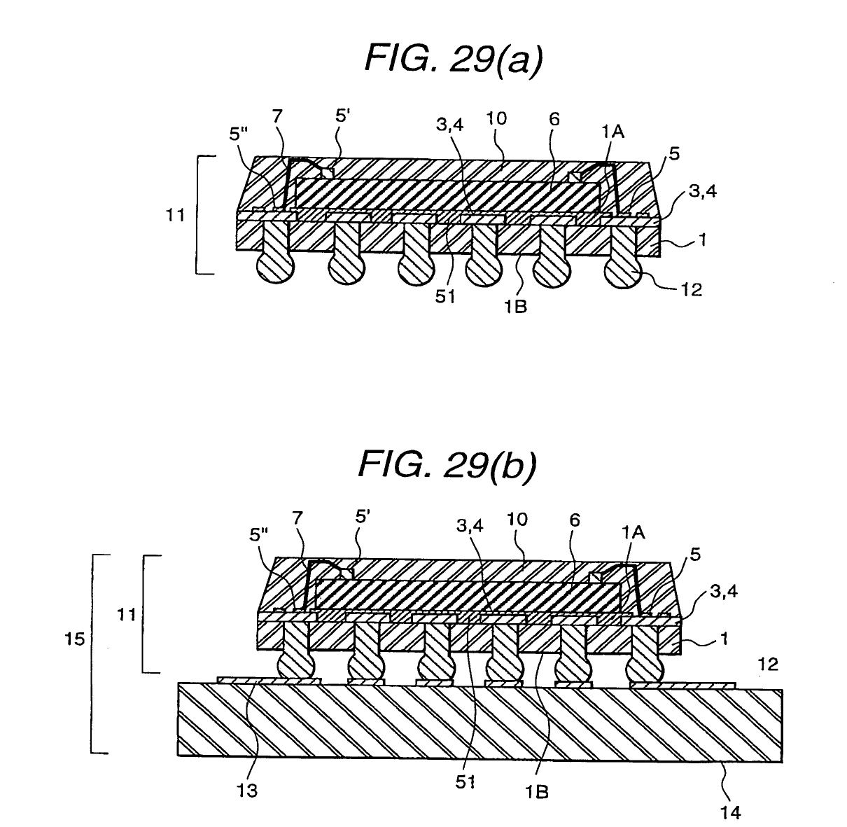

FIG. 29 is a diagrammatic sectional view showing the semiconductor device of this embodiment and the structural body using the same. Semiconductor device 11 is made as shown in (a). Wiring substrate 1 is the same polyimide substrate as embodiment 12, and the chip parts comprised of wiring pattern 4 and integrated circuit element base body (9 mm×9 mm×0.3 mm) 6 are bonded (first mounting soldering and work temperature: 270° C.) electrically by solder layers 5′ and 5″ (pitch: 0.1 mm) through TAB wiring 7 (the polyimide tape of 60. m in thickness and Cu wiring of 25. m in thickness are provided). Solder layer 5 comprises the compound body where Ni powder 5B (particle size: 0.05 to 0.1. m) is distributed into matrix metal 5A comprised of Sn-3.5 wt % Sb alloy, and the amount of addition of Ni powder 5B is adjusted to 35 vol %. Integrated circuit element base body 6 is bonded to substrate 1 by the adhesive (not shown) comprised of the epoxy resin where the Ag powder is added. Integrated circuit element base body 6, TAB wiring 7, solder layer 5′, 5″, and wiring pattern 4 are sealed by the same epoxy resin layer 10 as embodiment 1. Wiring pattern 4 doubles with external electrode layer 3 concurrently, and solder ball 12 (Sn-3 wt % Ag-0.7 wt % Cu and diameter: about 0.15 mm) for the external wiring connection is formed aiming at the second main respect 1B side of substrate 1.

Because solder layer 5 comprises the compound body where Ni powder 5B is distributed into matrix metal 5A comprised of Sn-3.5 wt % Ag alloy in semiconductor device 11 explained above, it is possible to prevent the outflow of matrix metal 5A, and the short circuit and the disconnection due to the outflow even if the re-melt is caused at second mounting soldering described later.

Next, structural body 15 using the above-mentioned semiconductor device 11 is made as shown in (b). Semiconductor devices 11 are bonded to external wiring 13 of wiring substrate 14 having the same as said embodiment 2 (Cu and thickness: 25. m) with solder ball 12 for the external wiring connection. In this case, the second mounting soldering with solder ball 12 is executed at 260° C.

The defective (disappearance of the circuit function by the short circuit or the disconnection) generation rate of semiconductor device 11 on structural body 15 of this embodiment is 0.00039%, and this is an extremely low value. This is due to the effect of the outflow prevention of solders 5 by the addition of Ni powder 5B. This effect of the outflow prevention is based upon the control of the cubical expansion of re-melted solders 5, the control of liquidity, the clogging phenomena by Ni powder 5B, the decrease of the substantial contact area between melted matrix metal 5A and wiring pattern 4.

The heat cycle test of −30 to 125° C. is given to structural body 15 of this embodiment. Here, the circuit function disappearance of semiconductor device 1t based on the crack destruction in solder layer 5 is paid to attention. In the test up to 2000 times, structural body 15 of this embodiment did not show something wrong due to the disappearance of the circuit function of semiconductor device 11.

(Embodiment 15)

In this embodiment, BGA (Ball Brid Array) type semiconductor device 11 and structural body 15 which the device is installed in the external wiring substrate is explained.

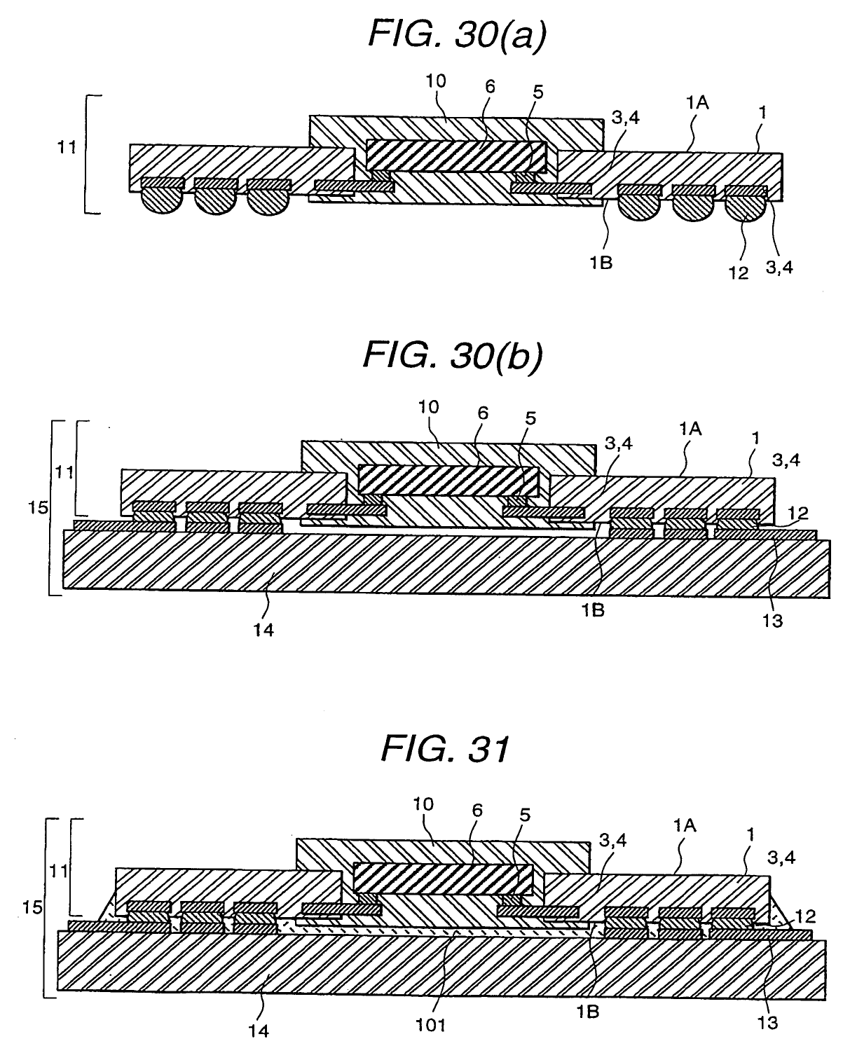

FIG. 30 is a diagrammatic sectional view illustrating the semiconductor device and the structural body which uses the semiconductor device. Semiconductor device 11 is configured as shown in FIG. 30(a).

A through hole is provided in the central portion of a polyimide substrate (15 mm×15 mm×0.4 mm), and integrated circuit element base body 6 is arranged in this portion. Wiring pattern 4 (Cu and thickness: 25 μm and: Ni plating of 5 μm in thickness and Au plating of 1. m in thickness are formed in order) is buried in substrate 1, and a part of wiring pattern 4 is projected to the through hole side. The chip parts comprised of projected wiring pattern 4 and integrated circuit element base body 6 (10 mm×10 mm×0.3 mm) are bonded electrically (the first mounting soldering and the work temperature: 270° C.) with solder layer 5 (pitch: 0.1 mm). Solder layer 5 is made of the compound body which Cu powder 5B (particle size: 0.05-0.1 μm) is distributed into matrix metal 5A comprised of Sn-3.5 wt % Sb alloy, and the amount of addition of Cu powder 5B is adjusted to 30 vol %. Integrated circuit element base body 6, polyimide substrate 1, wiring pattern 4, and solder layer 5 are molded with epoxy resin 10, and in particular, solder layer 5 is sealed completely so as to be intercepted from ambient air. Epoxy resin 10 is the same material as one of embodiment 1. Moreover, a part of wiring pattern 4 doubles with external electrode layer 3 concurrently, and solder ball 12 (Sn-3 wt % Ag-0.7 wt % Cu and diameter: about 0.25 mm) for the external wiring connection is formed aiming at the second main respect 1B side of substrate 1. Therefore, wiring pattern 4 arranged in the outer side of substrate 1, which doubles with external electrode layer 3, communicates electrically with projected wiring pattern 4 and integrated circuit element base body 6. Adding if necessary is desirable though metal-powder 5B is not added to solder ball 12 for the external wiring connection in this embodiment.

It is possible to prevent the outflow of matrix metal 5A and the short circuit according to this, and the disconnections even if the re-melt is caused at the soldering for the second mounting described later, because solder layer 5 comprises the compound body where Cu powder 5B is distributed into matrix metal 5A comprised of Sn-3.5 wt % Sb alloy according to semiconductor device 11 explained above.

Next, structural body 15 which uses the above-mentioned semiconductor device 11 is made as shown in (b). Semiconductor devices 11 are bonded to external wiring 13 (Cu and thickness: 25 μm) of wiring substrate 14 made of the same material as embodiment 2 with solder ball 12 for the external wiring connection. In this case, the second mounting soldering with solder ball 12 is executed at 260° C.

The defective (disappearance of the circuit function by the short circuit or the disconnection) generation rate of semiconductor device 11 on structural body 15 of this embodiment is 0.00039%, and this is an extremely low value. This is due to the effect of the outflow prevention of solders 5 by the addition of Cu powder 5B. This effect of the outflow prevention is based upon the control of the cubical expansion of re-melted solders 5 by Cu powder 5B, the control of liquidity, clogging phenomena, and the decrease of the substantial contact area between melted matrix metal 5A and wiring pattern 4.

The heat cycle test of 30 to 125° C. is given to structural body 15 of this embodiment. Here, the disappearance of the circuit function of semiconductor device 11 based on the crack destruction in solder layer 5 is paid to attention. In the test up to 2000 times, structural body 15 of this embodiment did not show something wrong due to the disappearance of the circuit function of semiconductor device 11.

In semiconductor device 11 and structural body 15 of this embodiment, integrated circuit element base body 6 is bonded to wiring pattern 4 on polyimide substrate 1. However, neither semiconductor device 11 nor structural body 15 are limited in the above-mentioned form. For instance, instead of polyimide substrate 1, it is possible to use one of which the matrix is comprised of glass epoxy material (the composite material where epoxy resin is soaked into glass fiber cloth and the coefficient of thermal expansion: 9.0 ppm/° C., Young's modulus: 35 Gpa). Even if it is a semiconductor device in such a form and a structural body using the semiconductor device, the same excellent performance and effects as the above-mentioned ones can be achieved. Semiconductor device 11 and structural body 15 explained above can play the role of the package where making to multi pins, the miniaturization, an d making to the thin type are required according to the needs such as making of the integrated circuit, making to the large-scale, speeding up, and making to the multifunction. Such semiconductor device 11 and structural body 15 are suitable for mounting on personal digital assistant equipment and camera all-in-one design VTR.

FIG. 31 is a diagrammatic sectional view showing the example of the modified structural body according to this embodiment. The following two points are different though this structural body 15 is basically similar to the structural body of FIG. 30. The first point is that silicone resin 101 is filled between semiconductor device 11 and wiring substrate 14, and thus solder ball 12 for the external wiring connection is sealed up completely. The second point is that solder ball 12 for the external wiring connection comprises matrix metal 12A which contains Sn-3 wt % Ag-0.7 wt % Cu and Fe powder 12B (particle size: about 0.25 mm and amount of addition: 40 vol %). Even if solder ball 12 for the external wiring connection melts again when structural body 15 is integrated or connected electrically to other members by heat-treating, the outflow of the matrix metal 12A and the short circuit according to this, and the disconnections can be prevented according to such configuration. Here, the aforementioned matrix metal 5A and metal powder 5B can be applied as matrix metal 12A and metal powder 12B. The proper particle size and the amount of addition of this metal powder 12B can use similar ones at the use of metal powder 5B.

(Embodiment 16)

In this embodiment, COC (Chip On Chip) type semiconductor device 11 and structural body 15 which installs this in the external wiring substrate are explained.

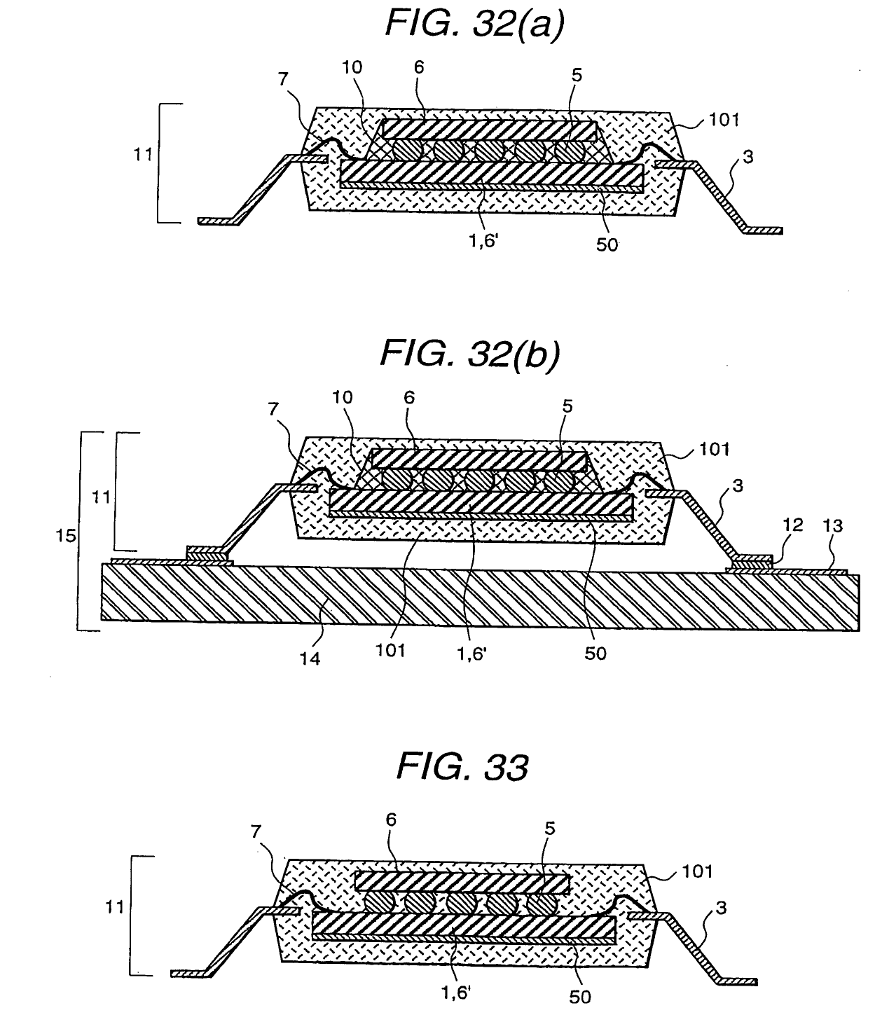

FIG. 32 is a diagrammatic sectional view showing a semiconductor device of this embodiment and a structural body which uses the same. Semiconductor device 11 is made as shown in (a). Substrate 1 is a Si substrate (15 mm×15 mm×0.3 mm), and it doubles with second integrated circuit element base body 6′. The chip parts comprised of first integrated circuit element base body (12 mm×12 mm×0.3 mm) 6 are bonded (first mounting soldering and the work temperature: 270° C.) electrically on the second integrated circuit element base body 6′ with solder layer 5 (pitch: 0.08 mm). Solder layer 5 comprises the compound body where Ni powder 5B (particle size: 0.05 to 0.1. m) is distributed into matrix metal 5A comprised of Sn-3.5 wt % Ag alloy, and the amount of addition of Ni powder 5B is adjusted to 3 vol %. The Al wiring (thickness: 1.75 μm) is provided on the first integrated circuit element base body 6, and Ti (0.18 μm)-Cu (1.75. m)-Ni (15 μm) accumulating metal layer is provided selectively to the area where solder layer 5 is formed on the Al wiring though they are not shown in figure. On the other hand, the same Al wiring and Ti-Cu-Ni accumulating metal layer as first integrated circuit element base body 6 are provided on second integrated circuit element base body 6′. The accumulating metal layer of second integrated circuit element base body 6′ doubles with wiring pattern 4 concurrently.

Epoxy resin 10 is filled to the gap (about 70 μm) formed by first integrated circuit element base body 6 and second integrated circuit element base body 6′, and solder layer 5 is sealed completely so as to be intercepted from ambient air. Epoxy resin 10 comprises bisphenol A, methylic hexahydro phthalic anhydride as the anhydride system hardener, amine as the hardening accelerator, and organic acid. Moreover, the second integrated circuit element base body 6′ is installed on plinth 50 with the silver paste adhesive (not shown). The Al wiring layer is provided in the surrounding area of the second integrated circuit element base body 6′ (not shown), and is connected electrically to external terminal 3 by the wire bonding of Au thin line 7 (diameter: 25 μm). Here, plinth 50 and external terminal 3 form the lead frame made of Fe-42 wt % Ni alloy (thickness: 0.1 mm and Sn plating). Each material explained above is sealed by epoxy resin 101 (coefficient of thermal expansion after hardening: 16 ppm/° C., modulus of elasticity: 15.7 GPa and glass transition point: 155° C.) provided by transfer molding method (180° C.,4.9 MPa,3 min, 180° C.×6 h) excluding a part of external terminal 3. It is possible to substitute epoxy resin 101 for such a transfer molding with the resin which has physical properties after hardening of a coefficient of thermal expansion of 5 to 220 ppm/° C., Young's modulus of 1 to 50 GPa and glass transition point of 120 to 160° C. Because solder layer 5 comprises the compound body where Ni powder 5B is distributed into matrix metal 5A comprised of Sn-3.5 wt % Ag alloy in semiconductor device 11 explained above, it is possible to prevent the outflow of matrix metal 5A, and the short circuit and the disconnection due to the outflow even if the re-melt is caused when second mounting soldering described later is carried out.

Moreover, semiconductor device 11 of this embodiment has the following features. That is, (1) the mounting area is reduced by facing joint, and (2) metal connection suitable for high-speed communication is obtained because loss of electrical signals is small although the first integrated circuit element base body 6 and the second integrated circuit element base body 6′ are different kinds of devices which play the electrically different roles. In semiconductor device 11 of this embodiment, connection resistance in the solder joint part between the first integrated circuit element base body 6 and the second integrated circuit element base body 6′ was examined by the high temperature shelf test of 150° C. and 1,000 hours. The initial value of the resistance was 11 m 0, and the resistance value after 1,000 hours was 12 mΩ. Excellent stability was shown. Moreover, (1) the high temperature and humidity blocking test of 85° C., 85% RH and 50V, (2) the high temperature shelf test of 150° C. and 500 hours, (3) the heat cycle test of −5 to 150° C. and 1,000 times were performed to semiconductor device 11. The defective number due to circuit function decrease was 0 in 15 input samples in each test. Excellent reliability was shown.

Next, structural body 15 which uses the above-mentioned semiconductor device 11 is made as shown in (b). External terminal 3 of semiconductor device 11 and external wiring 13 (Cu and thickness: 25 μm) of wiring substrate 14 comprised of the same material as embodiment 2 is bonded by solder (Sn-3 wt % Ag-0.7 wt % Cu) 12 for the external wiring connection. This second mounting soldering is executed at 260° C. The defective (disappearance of the circuit function by the short circuit or the disconnection) generation rate of semiconductor device 11 in structural body 15 of this embodiment was 0.00045%, and this was an extremely low value. This is due to the prevention effect of the outflow of solders 5 due to the addition of Ni powder 5B. This prevention effect of the outflow is based upon the control of the cubical expansion of re-melted solders 5 by Ni powder 5B, the control of liquidity, clogging phenomena, and the decrease of the substantial contact area between the metals being connected and melted matrix metal 5A. The heat cycle test of −30 to 125° C. is given to structural body 15 according to this embodiment. Structural body 15 of this embodiment did not show something wrong due to the disappearance of the circuit function of semiconductor device 11 in the test up to 2,000 times. Semiconductor device 11 and structural body 15 having the structure where epoxy resin 10 is filled to the gap between the first integrated circuit element base body 6 and the second integrated circuit element base body 6′, and having the structure sealed with epoxy resin 101 by the transfer molding method in this embodiment. However, neither semiconductor device 11 nor structural body 15 are limited in the above-mentioned form in this embodiment.

FIG. 33 is a diagrammatic sectional view showing the COC type semiconductor device according to another form.

In this semiconductor device 11, epoxy resin 101 is filled to the gap between the first integrated circuit element base body 6 and the second integrated circuit element base body 6′ by the transfer molding method. Even if semiconductor device 11 has such configuration, the same effect as this embodiment can be achieved. Moreover, although the detailed description is omitted, the same effect as this embodiment can be also achieved f or structural body 15 where semiconductor device 11 having such structure is installed on wiring substrate 14. Semiconductor device 11 and structural body 15 explained above can play the role of the package where making to multi pins, the miniaturization, and making to the thin type are required according to the needs such as making of the integrated circuit, making to the large-scale, speeding up, and making to the multifunction. Such semiconductor device 11 and structural body 15 are suitable for mounting on personal digital assistant equipment and camera all-in-one design VTR.

(Embodiment 17)

In this embodiment, semiconductor device 11 as a micro DC/DC converter for portable equipment and structural body 15 which installs the same on the external wiring substrate are explained.

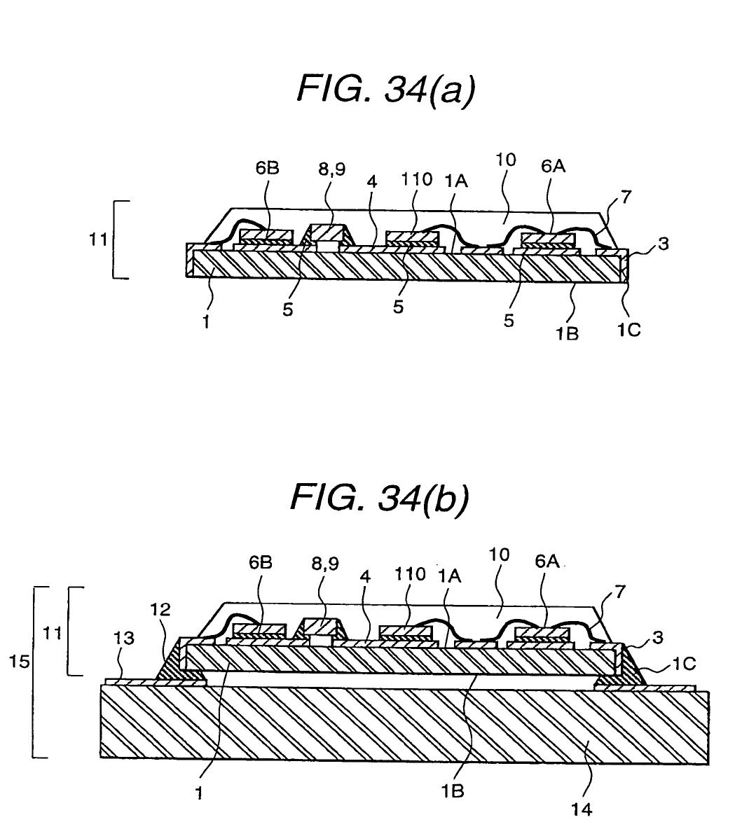

FIG. 34 is a diagrammatic sectional view showing a semiconductor device of this embodiment and a structural body using the same. Semiconductor device 11 is made as shown in (a). Internal wiring layer (Cu and thickness: 15. m, not shown) and the through hole wiring (Cu and plating forming, not shown) 2A are provided inside of multi-layer glass epoxy substrate (25 mm×10 mm×0.4 mm) 1. Wiring pattern 4 (Cu and thickness: 25 μm and Ni plating of 5 μm in thickness and the Au plating of 1 μm in thickness are formed in order) is provided on first main respect 1A of substrate 1. The chip parts of thin film inductor 110, PWM control integrated circuit base body 6A, MOSFET element base body 6B as the switching element, rectifier diode 6C (not shown), chip resistance 8 and capacitor 9 are bonded (first mounting soldering and work temperature: 270° C.) electrically on this wiring pattern 4 with solder layer 5. Solder layer 5 comprises the compound material where mixed powder 5B (particle size: 0.3. m) comprised of Ni powder and Al powder is distributed into matrix metal 5A comprised of Sn-5 wt % Sb alloy. The amount of addition of mixed powder 5B is adjusted to 30 vol %. Thin metallic wire 7 comprised of Au is bonded (40 μm in diameter) between predetermined parts of wiring pattern 4, and thin film inductor 110 and semiconductor device base bodies 6A, 6B. These chip parts, thin metallic wires 7, wiring patterns 4, and first-main respect 1A are completely sealed so as to be intercepted from ambient air by resin layer 10 whose principal ingredient is epoxy (physical properties after hardening are as follows. Coefficient of thermal expansions: 9.0 ppm/° C., Young's modulus: 24.5 Gpa, glass transition point: 150° C. and amount of filler addition: 85 wt %).

This resin layer 10 (size: 23 mm×9 mm×0.8 mm) is the one having formed with the potting method. External terminal layer 3 (Cu and thickness: 25 μm, Ni plating of 5 μm in thickness and Au plating of 1. m in thickness are formed in order) extends along from first main respect 1A of substrate 1 to side 1C. External terminal layer 3 is connected electrically to wiring pattern 4 through internal layer wiring layer 2 and through hole wiring 2A provided inside of substrate 1. Each chip part is completely enclosed by substrate 1, wiring pattern 4, and resin layer 10 as explained above, and solder layer 5 where these chip parts are bonded is also enclosed completely by chip parts, wiring patterns 4, and resin layer 10.

Because solder layer 5 comprises the compound body where mixed powder of Ni powder and Al powder is distributed into matrix metal 5A comprised of Sn-3.5 wt % Sb alloy in semiconductor device 11 explained above, it is possible to prevent the outflow of matrix metal 5A, and the short circuit and the disconnection due to the outflow even if the re-melt is caused when second mounting soldering described later is carried out.

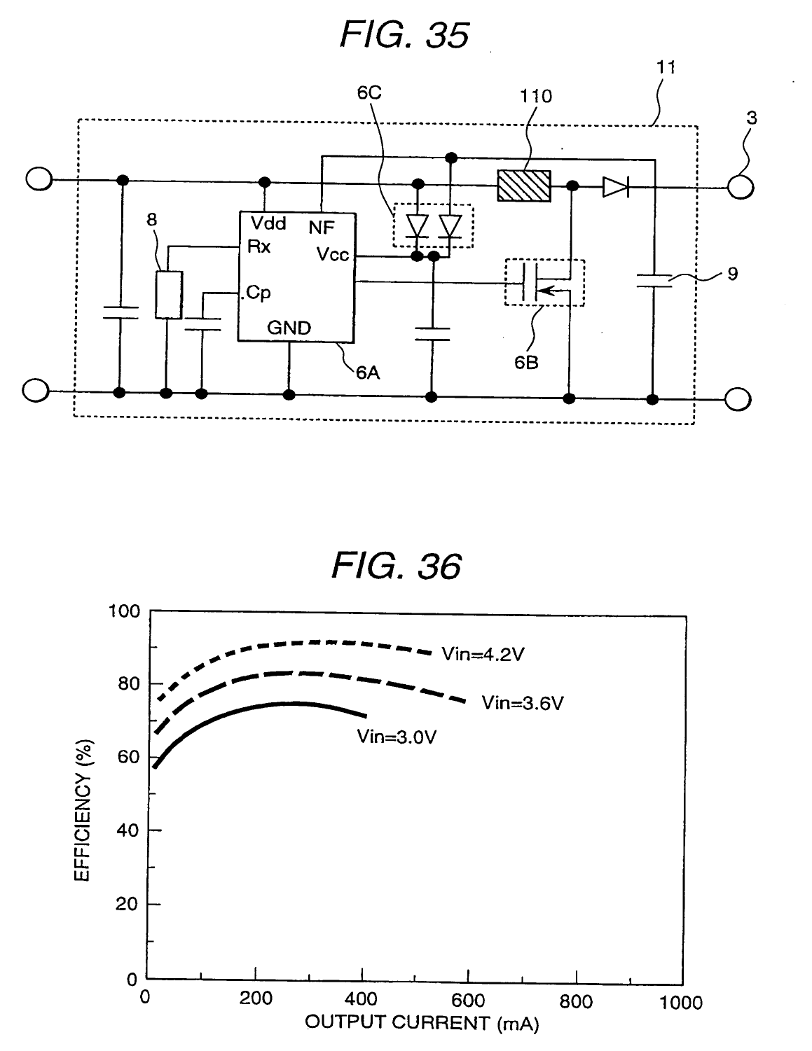

FIG. 35 is an illustration showing circuit of the semiconductor device according to this invention.

This semiconductor device 11 composes a DC/DC converter circuit for the switching of 5 MHz. The input side (Vi) is connected to the lithium ion accumulator (voltage: 3.0 to 4.2V and average voltage: 3.6 V), and the output side (Vo) is connected to two or more various loads. The maximum output voltage of 4.7 V and the maximum output electric current of 600 mA (maximum output: about 3 W) is supplied with stepping up or stepping down or reversing according to the voltage assumed to be necessary for various loads. This DC/DC converter circuit is suitable for a cellular phone and a book type personal computer, which needs the communication function, the display function, and the high-speed processing function of the image information.

Structural body 15 of this embodiment in which the above-mentioned semiconductor device 11 is built is made as shown in FIG. 34(b). Semiconductor device 11 is bonded on external wiring (Cu and thickness: 25 μm) 13 of wiring substrate 14 comprised of the same material as embodiment 2 by using solder (Sn-5 wt % Sb-0.6 wt % Ni-0.05 wt % P) 12. In this case, the second mounting soldering with solder 12 for the external wiring connection is carried out at 260° C.

The defective (disappearance of the circuit function by the short circuit or the disconnection) generation rate of semiconductor device 11 in structural body 15 of this embodiment was 0.00045%, and this was an extremely low value. This is due to the effect of the outflow prevention of solders 5 by the addition of Ni powder 5B. This effect of the outflow prevention is based upon the control of the cubical expansion of re-melted solders 5 by mixed powder 5B of Ni and Al, the control of liquidity, the clogging phenomena, the decrease of the substantial contact area between melted matrix metal 5A and wiring pattern 4.

The control characteristic as the DC/DC converter is examined by using structural body 15 of this embodiment. It has been confirmed that the output voltage has nothing but the change of ±3% or less for the input voltage change from 3 to 4.2V and structural body 15 has the excellent controllability.

Moreover, FIG. 36 is a graph showing the relationship between the output current and the conversion efficiency of this embodiment structural body. This graph shows the case that input voltage (Vin) is 3.0V, 3.6V, or 4.2V. High efficiency of 80% or more is obtained especially for the output current 300 mA in average voltage 3.6V of the lithium ion accumulator.

(Embodiment 18)

In this embodiment, semiconductor device 11 for the AC dynamo device of the automobile and structural body 15 using the same are explained.

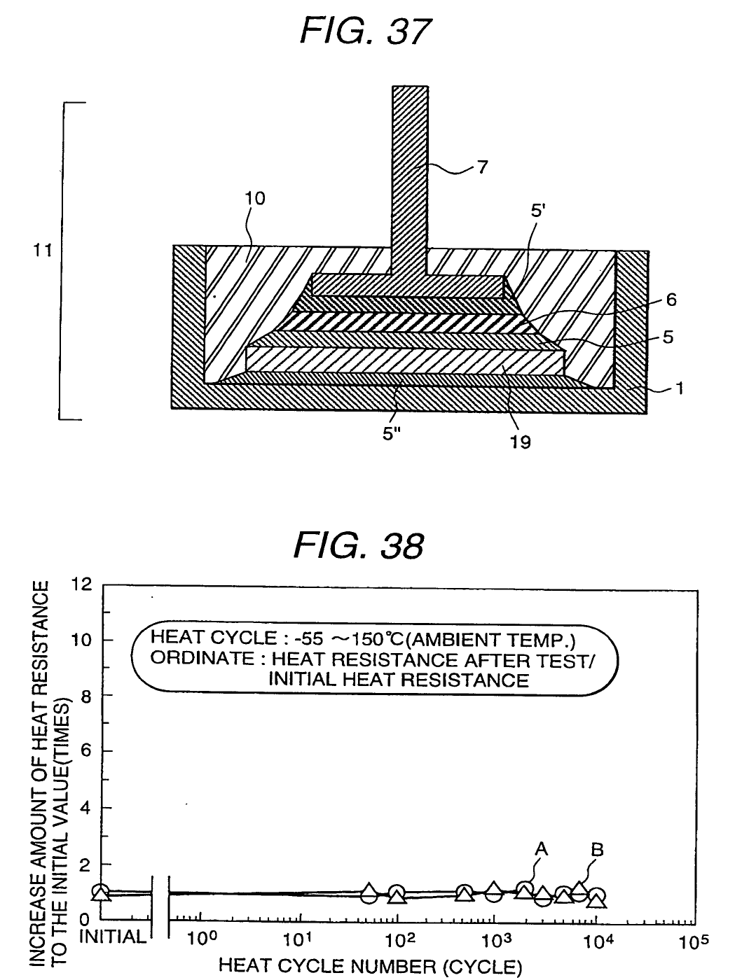

FIG. 37 is a diagrammatic sectional view showing the semiconductor device according to this embodiment.

Numeral 1 designates a Cu container as the wiring member, and the Ni plating layer (thickness: 3 to 7 μm, not shown) is formed on the surface. Thermal expansion reducing material 19 is installed on the bottom of container 1 by solder layer 5″. Semiconductor bas e body 6 is bonded on thermal expansion reducing material 19 with solder layer 5, and Cu lead 7 is bonded on semiconductor base body 6 through solder layer 5′. Moreover, resin layer 10 (coefficient of thermal expansion: 450 ppm/° C., Young's modulus: 1.27 Mpa, and RTV silicone rubber comprised of silicone resin (75%) and calcium carbonate (25%)) which covers the surface of thermal expansion reducing material 19, Cu lead 7, solder layers 5, 5′, 51″, and semiconductor base body 6 is formed. Thermal expansion reducing material 19 is worked like the disk of 5 mm in diameter by a layered structure body [Cu (thickness: 0.2 mm)-imba (0.2 mm)-Cu(0.2 mm)] of a dissimilar metal board. A horizontal coefficient of thermal expansion of thermal expansion reducing material 19 is 10.6 ppm/° C., and thermal conductivities are 30.3 W/m·K in a vertical direction and 262 W/m·K in a horizontal direction.

The Ni plating layer (thickness: 3 to 7. m, not shown) is formed on the surface of thermal expansion reducing material 19 worked into the disk. A similar Ni plating layer is formed also on the surface of Cu lead 7. Semiconductor base body 6 is a diode comprised of Si, and is processed like the disc of 0.3 mm in thickness and 4 mm in diameter. Here, solder layer 5, 5′ and 5″ comprises the compound body where Ni powder 5B (particle size: 3. m) is distributed into matrix metal 5A comprised of Pb-50 wt % Sn-1.5 wt % Ag alloy, and the amount of addition of mixed powder 5B is adjusted to 15 vol %. Soldering is executed by the heat-treating of 350° C. under the hydrogen atmosphere after accumulating sheet-like solders 5, 5′, and 5″ between each members of Cu container, thermal expansion reducing material 19, semiconductor base body 6, and Cu lead 7. The range of 50 to 200 μm is preferable though the thickness of solder layer 5, 5′, and 5″ only has to be a range of 20 to 300 μm, considering the reliability, workability, and the yield, etc. required to semiconductor device 11. The alloy which uses Cu as a matrix can be used as lead 7 besides Cu. In this case, it is preferable to plate the metals such as Ag and Au on the surface besides Ni to give the wetting.

Thermal expansion reducing material 19 can be substituted by the material with high thermal conductivity and with the coefficient of thermal expansion close to the semiconductor base body like Mo, W. Cu-W composite material, Cu—Mo composite material, Cu—Cu₂O composite material, and Al—SiC composite material, etc. It is possible to substitute epoxy resin 10 with phenol resin (addition of calcium carbonate) whose coefficient of thermal expansion is 1˜3 ppm/° C. and Young's modulus is 1960 Mpa, silicone resin whose coefficient of thermal expansion is 30 ppm/° C. and Young's modulus is 11,000 MPa, polybutylene terephthalate resin whose coefficient of thermal expansion is 35 to 75 ppm/° C. and Young's modulus is 8,800 Mpa, poly phenylene sulphide whose coefficient of thermal expansion is 19 to 22 ppm/° C. and Young's modulus is 11,700 to 13,700 Mpa, and silicon gel resin whose coefficient of thermal expansion is 5 to 220 ppm/° C. and Young's modulus is 0.02 Gpa, etc.

Material installed in semiconductor device 11 as explained above, especially solder layer 5, 5′, and 5″ are completely enclosed with container 1, thermal expansion reducing material 19, semiconductor base body 6, Cu lead 7, and resin layer 10. Solder layer 5, 5′, and 5″ of such structural semiconductor device 11 comprises matrix metal 5A comprised of the Pb-50 wt % Sn-11.5 wt % Ag alloy and the compound body where Ni powder 5 is distributed. Therefore, it is possible to prevent the outflow of matrix metal 5A, and the short circuit (especially, between semiconductor base body 6 and thermal expansion reducing material 19, and between Cu lead 7 and semiconductor base body 6) due to the outflow even if the re-melt is caused when second mounting soldering described later is carried out.

FIG. 38 is a graph illustrating the transition of thermal resistance in the heat cycle test of the semiconductor device according to the present embodiment.

In the figure, A designates the case of semiconductor device 11 according to this embodiment, and B designates the case of the comparison example semiconductor device. Here, the part corresponding to solder layers 5, 5′, and 5″ in semiconductor device 11 according to this embodiment is Pb-50 wt % Sn-1.5 wt % Ag alloy (metal powder is not added) in the comparison example semiconductor device. Other components are the same configuration as this embodiment. The amount of increase of thermal resistance to the initial value in ordinate is shown by (thermal resistance after examination)/(initial thermal resistance). An initial thermal resistance value in sample A or B is maintained without thermal resistance increasing in the test up to 10,000 cycles.

The result suggests that it is possible to secure reliability even when metal powder 5B is added to solder layer 5, 5′, and 5″ like semiconductor device 11 of this embodiment as well as the case of no metal powder addition.

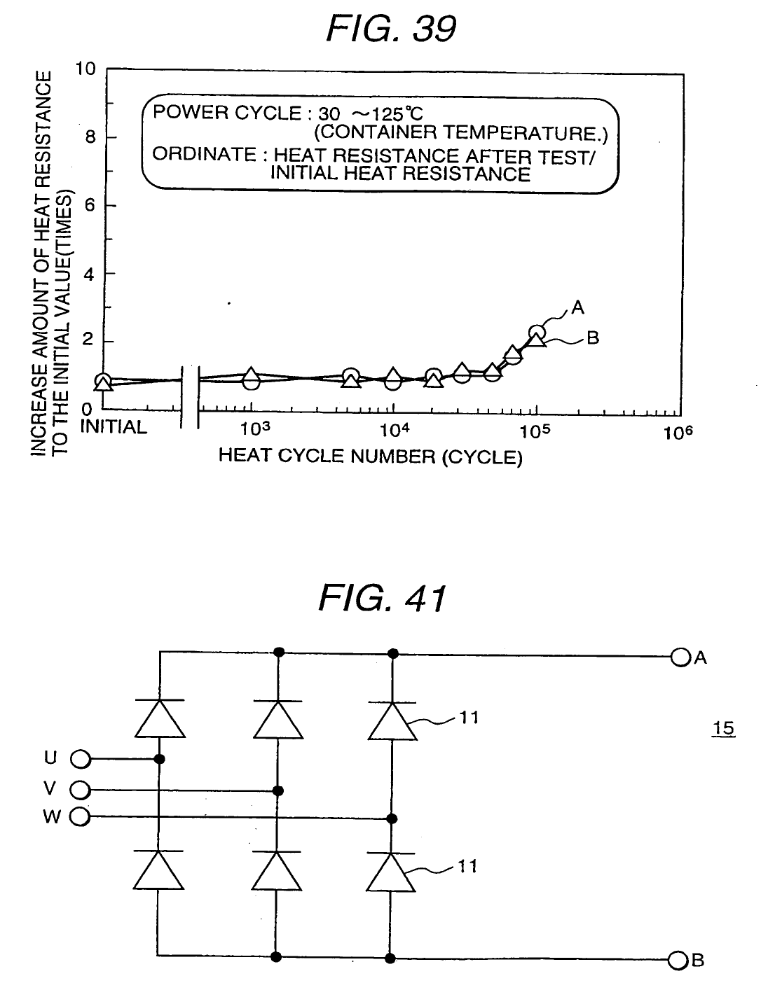

FIG. 39 is a graph showing the transition of thermal resistance in the power cycle test on the semiconductor device of this embodiment.

In this test, intermittent turn-on is given to semiconductor device 11 so that the temperature of container 1 may change from 30 to 125° C. A and B in figure are similar to the case of the heat cycle test shown in FIG. 38. Moreover, the aspect of the ordinate is also similar to the case of FIG. 38. Thermal resistance equal with an initial value is shown up to 50,000 cycles in both samples A and B. After 50,000 cycles are exceeded, an increase in thermal resistance is caused.

It can be confirmed also from this result that it is possible to secure reliability even when metal powder 5B is added to solder layer 5, 5′, and 5″ like semiconductor device 11 of this embodiment as well as the case of no metal powder addition.

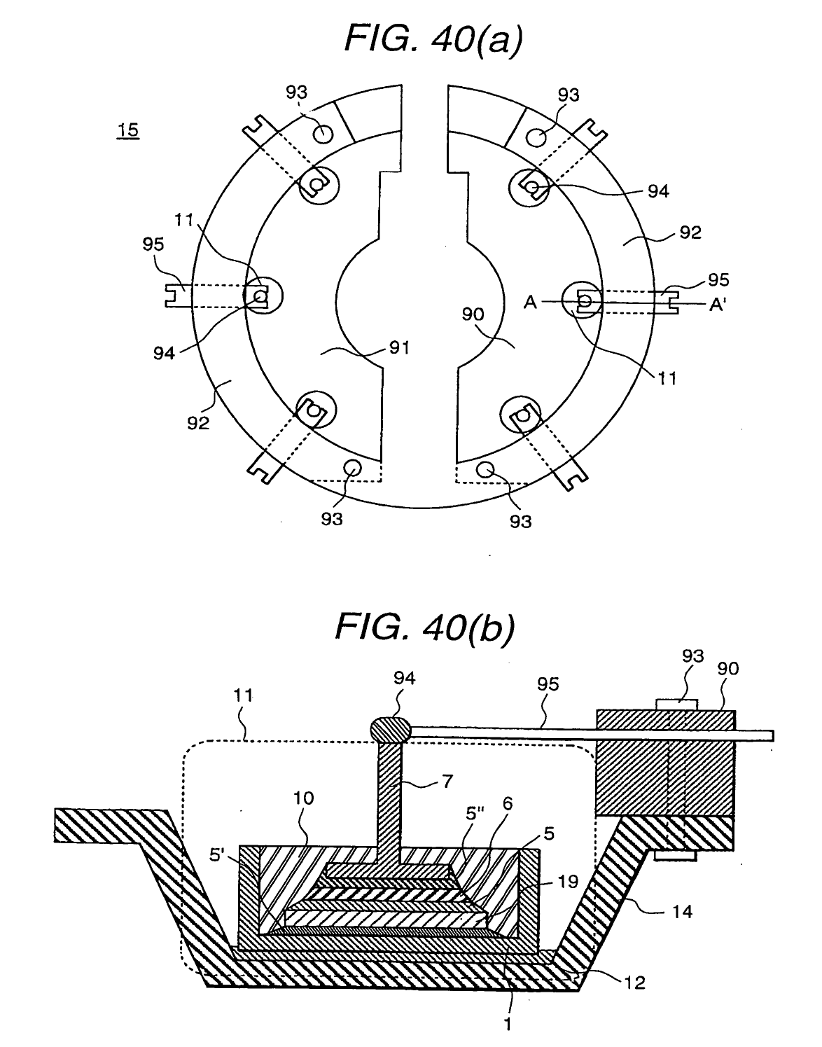

The above-mentioned semiconductor device 11 is applied to the full-wave rectification device as structural body 15. FIG. 40 is a plan view and a sectional view illustrating the full-wave rectification device.

(a) is a plan view of the full-wave rectification device as structural body 15, and (b) is an A-A′ sectional view. In the figure, semiconductor device 11 comprises Cu container 1, thermal expansion reducing materials 19 bonded to the bottom of Cu container 1 by solder layer 5′, semiconductors base body 6 bonded on thermal expansions reducing material 19 by solder layer 5, Cu lead 7 bonded on semiconductor base body 6 through solder layer 5″, and resin layer 10 which coats them. Three Cu container 1 of semiconductor devices 11 are bonded to first cooling wheel 90 which doubles with external wiring 13 and external wiring substrate 14 concurrently via external wiring connection layer 12. Moreover, three semiconductor devices 11 are similarly installed on second cooling wheel 91. That is, a plurality of semiconductor devices 11 are installed on the first cooling wheel 90 and the second cooling wheel 91 which mutually forms the pair. The direction of the rectification is arranged in each cooling wheel, and the cooling wheels are installed so that the directions of the rectification may differ from each other. Here, the Cu boards press-worked are used for the first cooling wheel 90 and the second cooling wheel 91. The role of cooling wheel 90 and 91 is to transmit efficiently the heat which semiconductor device 11 discharges to the outside and to transmit efficiently the electric power. The Al board can be used as cooling wheels 90 and 91 from this viewpoint. The first cooling wheel 90 and the second cooling wheel 91 mutually form the pair, and are installed on terminal block 92 composed of epoxy resin etc. through attachment member 93. Cu lead 7 are connected through solders 94 to Cu terminal 95 buried in terminal block 92 beforehand. The Pb-63 wt % Sn alloy is applied to solders 94 and external wiring connection layer 12, and these soldering is executed by heat-treating of 260° C. It is possible to substitute this alloy with (1) Pb—Sn system alloy material such as Pb-5 wt % Sn-1.5 wt % Ag, Pb-10 wt % Sn, Pb-50 wt % Sn, and Pb-63 wt % Sn, (2) Metal composed of Sn, or (3) the alloy material which contains at least two kinds selected from a group of Sn, Sb, Ag, Cu, Ni, P. and the group of Bi, Zn, Au, and In. The defective (disappearance of the circuit function by the short circuit) generation rate of semiconductor device 11 on structural body 15 of this embodiment is 0.00055%, and this is an extremely low value. This is due to the effect of the outflow prevention of solders 5 by the addition of Ni powder 5B. This effect of the outflow prevention is based upon the control of the cubical expansion of re-melted solders 5 by Ni powder 5B, the control of liquidity, and the clogging phenomena.

FIG. 41 is a circuit diagram showing the full-wave rectifier of the structural body of this embodiment.

This full-wave rectification device 15 is installed in the three-phase alternating current dynamo for a vehicle. The alternating current is generated by the interlinkage of the magnetic field and rotor coil installed in the rotor whose rotation power is transmitted from an engine of the vehicle. U, V, and W terminals of full-wave rectification device 15 are connected to the above-mentioned rotor coil. Therefore, the alternating current via U, V, and W terminals is converted into the direct current by each semiconductor device 11, and supplied to the load as a dc power through terminals A and B. Full-wave rectification device 15 is installed in the engine room of the automobile with three-phase alternating current dynamo 100 in which this is installed. The running test of 200,000 km is given to this automobile. Three-phase alternating current dynamo 100 and full-wave rectification device 15 are always in the state of operation for this running test period, and an electric function is maintained equally to an initial state.

As a reason why an excellent durability performance like this can be obtained, the following points is given.
(1) The point that the outflow due to the remelting of solder layers 5, 5′, and 5″ inside of semiconductor device 11 is completely controlled.
(2) The point that each material in semiconductor device 11 is connected by solder layer 5, 5′, and 5″ with excellent reliability as shown in FIG. 37 and FIG. 38.

The full-wave rectification device is not limited in the form alone described in this embodiment.

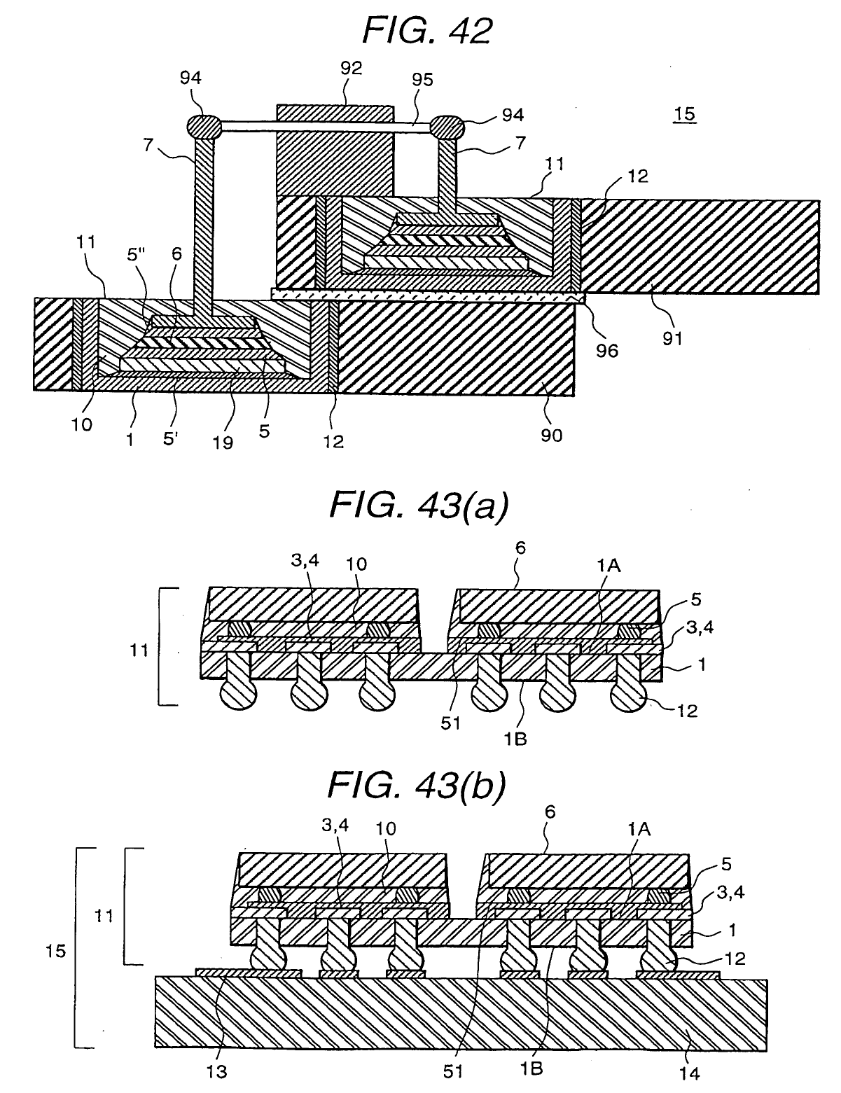

FIG. 42 is a diagrammatic sectional view showing the full-wave rectification device in another form.

In the figure, semiconductor devices 11 are bonded to the through holes of the first cooling wheel 90 and the second cooling wheel 91 by solder layer 12 for the external wiring connection. Insulation seat 96 comprised of the silicone resin is interleaved between the first cooling wheel 90 and the second cooling wheel 91. That is, a plurality of semiconductor devices 11 are bonded to the first cooling wheel 90 and the second cooling wheel 91 which mutually forms the pair. The direction of the rectification is arranged in each cooling wheel, and the cooling wheels are installed so that the directions of the rectification may differ from each other. The first cooling wheel 90 and the second cooling wheel 91 mutually forms the pair. Cu lead 7 of each semiconductor device 11 is connected to metallic terminal 95 connected to terminal block 92 beforehand through solders 94. The above-mentioned structural full-wave rectification device 15 composes the full-wave rectifier shown in FIG. 40. This full-wave rectification device 15 can be also used by installing it in the three-phase alternating current dynamo for a vehicle.

(Embodiment 19)

In this embodiment, MCM (Multi Chip Module) type semiconductor device 11 and structural body 15 where semiconductor device 11 is installed in the external wiring substrate.

FIG. 43 is a diagrammatic sectional view illustrating a semiconductor device of this embodiment and a structural body using the same. Semiconductor device 11 is made as shown in (a).

Wiring pattern 4 (Cu and thickness: 25. m and Ni plating of 5. m in thickness and the Au plating of 1 μm in thickness are formed in order) is provided on first main respect 1A of glass epoxy substrate 1 (18.8 mm×16.8 mm×0.65 mm and four layer wiring). Chip parts composed of four kinds of integrated circuit element base bodies 6 (4.7 mm×8.2 mm×0.35 mm, 3.9 mm×4.9 mm×0.35 mm, 4.9 mm×4.7 mm×0.35 mm, 6.0 mm×6.0 mm×0.35 mm) are connected electrically to this wiring pattern 4 by solder layer 5 (pitch:0.1 mm). Solder layer 5 comprises the compound body where Ni powder 5B (particle size: 0.05 to 15 μm) is distributed into matrix metal 5A comprised of Sn-3.5 wt % Ag alloy, and the amount of addition of mixed powder 5B is adjusted to 15 vol %. Epoxy resin 10 is filled to the gap (about 50, m) between the integrated circuit element base body 6 and glass epoxy substrate 1, and solder layer 5 is sealed completely so as to be intercepted from ambient air. Epoxy resin 10 comprises bisphenol A, methylic hexahydro phthalic anhydride as the anhydride system hardener, amine as the hardening accelerator, and organic acid. Here, the solder resist film is provided to the predetermined portions of the wiring pattern provided to the first main respect 1A (portions other than the area where solder layer 5 is formed). Moreover, wiring pattern 4 doubles with external electrode layer 3 concurrently, and solder ball 12 (diameter: about 0.15 mm) for the external wiring connection is formed aiming at the second main respect 1B side of substrate 1. Solder ball 12 comprises the compound body where metal powder 12B comprised of Cu powder (particle size: 0.05 to 25 μm) is added to matrix metal 12A comprised of Sn-3 wt % Ag-0.7 wt % Cu by 15 vol %. In semiconductor device 11 explained above, solder layer 5 comprises the compound body where Ni powder 5B (particle size: 0.05 to 15 μm) is distributed into matrix metal 5A comprised of Sn-3.5 wt % Ag alloy, and the amount of addition of mixed powder 5B is adjusted to 15 vol %. Therefore, it is possible to prevent the outflow of matrix metal 5A, and the short circuit and the disconnection due to the outflow even if the re-melt is caused when second mounting soldering described later is carried out.

Next, structural body 15 which uses above-mentioned semiconductor device 11 is made as shown in (b). Semiconductor devices 11 are bonded to external wiring 13 of wiring substrate 14 having the same material as embodiment 2 (Cu and thickness: 25 μm) with solder ball 12 for the external wiring connection. In this case, the second mounting soldering with solder ball 12 is executed at 260° C. The defective (disappearance of the circuit function by the short circuit or the disconnection) generation rate of semiconductor device 11 in structural body 15 of this embodiment is 0.00015%, and this is an extremely low value. This is due to the effect of the outflow prevention of solders 5 by the addition of Ni powder 5B. This effect of the outflow prevention is based upon the control of the cubical expansion of re-melted solders 5 by Ni powder 5B, the control of liquidity, clogging phenomena, and the decrease of the substantial contact area between melted matrix metal 5A and wiring pattern 4. Moreover, even if structure body 15 is installed in the other substrates by heat-treating (third mounting soldering), the outflow of the matrix metal 12A and the short circuit and the disconnection due to the outflow can be prevented, because Cu powder 12B is added to solder ball 12 for the external wiring connection of structural body 15 of this embodiment.

The heat cycle test of 30 to 125° C. is given to structural body 12 of this embodiment.

Here, the circuit function disappearance of semiconductor device 11 based on the crack destruction in solder layer 5 is paid to attention. In tests up to 2000 times, something wrong due to the circuit function disappearance of semiconductor device 11 is not shown in structural body 15 of this embodiment.

Semiconductor device 11 explained above and structural body 15 are finally installed in a three-band small radio (AM/FM stereo/TV) with the television function of the size of 80×40×12.8 mm.

(Embodiment 20)

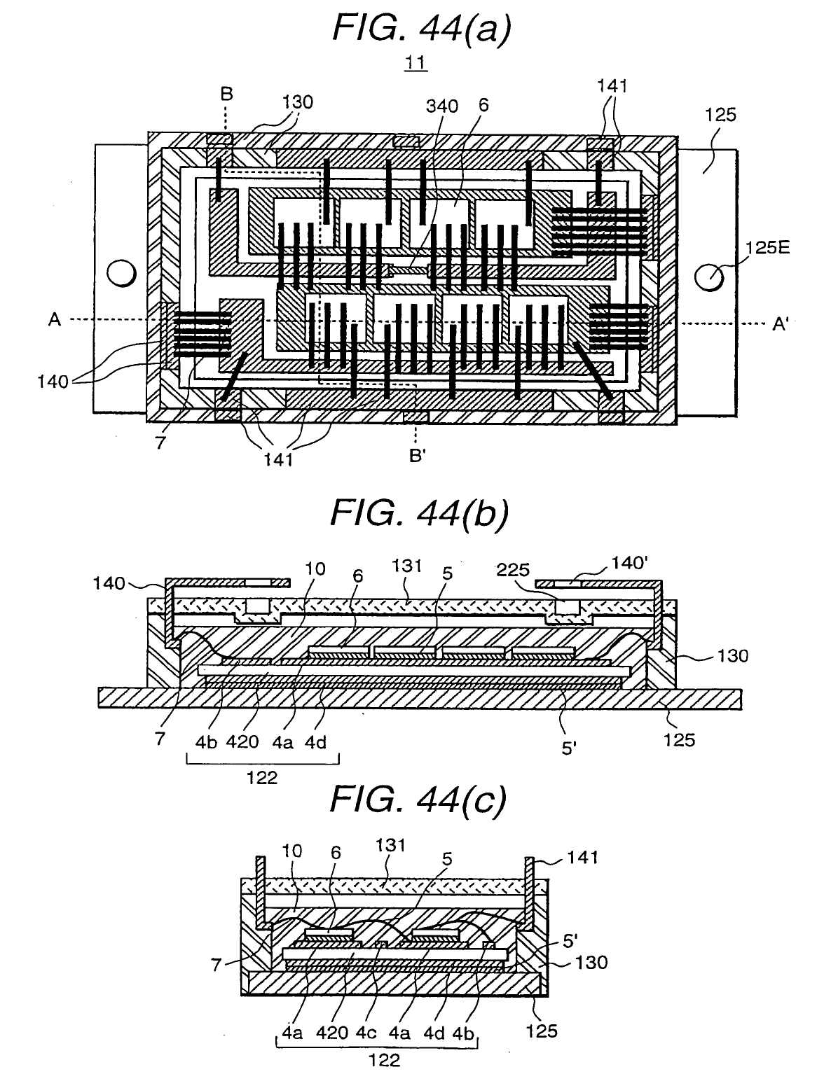

FIG. 44 is a diagrammatic plane and section view illustrating the power module device according to another form of the present invention. This insulation type semiconductor device 11 is 400A class. After Ceramic insulation substrate 122 and semiconductor device base body 6 are coupled onto support member 125, epoxy resin case 130, thin metallic wire 7, and epoxy resin lid 131 are provided, and silicon gel resin 10 is filled in this case.

FIG. 44(a) is a plane view, FIG. 44(b) is a sectional view taken along A-A′ line of FIG. 44(a), and FIG. 44(c) is a sectional view taken along B-B′ line of FIG. 44(a).

Here, ceramic base materials 122 on support member 125 are bonded by using solder 5′ (thickness: 200 μm), and MOS FET element base body 6 (size: 7 mm×7 mm×0.3 mm) comprised of eight Si is bonded on sheet copper 4a of ceramic base material 122 with solder layer 5 (thickness: 200 μm). Each element base body 6 is given the wire bonding by Al line 7 (diameter: 400. m), and is connected to main terminal 140 and supplementary terminal 141 installed in source electrode 4b, drain electrode 4a, and epoxy resin case 130 beforehand. Moreover, thermistor element 340 for the temperature detection is bonded to sheet copper 4c on ceramic base material 122 with solder layer 5 (not shown). Thin metallic wire 7 is bonded in wire between sheet copper 4c and supplementary terminal 14 to communicate with the outside. Epoxy resin case 130 and support member 125 is fixed by using silicon adhesive resin 135 though not shown in the figure. Dent 225 is provided in the thick wall part of epoxy resin lid 131, and hole 140′ is provided in main terminal 140, into which the screw (not shown) to connect insulation type semiconductor device 11 to the external circuit wiring is housed main terminal 140 and supplementary terminal 141 is made by punching and forming the sheet copper, and giving the Ni plating. They are installed in epoxy resin case 130 by the transfer molding method.

Here, solder layer 5 and 5′ are made by adding Cu powder 5B (particle size: 1 to 12 μm) to Sn-5 wt % Sb alloy as matrix metal 5A by 10 vol %. Support member 125 consists of Al—SiC complex metal material, and has the physical properties of a coefficient of thermal expansion: 8.0 ppm/° C. and thermal conductivity: 170 W/m-K. The matrix of support member 125 is a compound body where SiC particles 125B are distributed in Al matrix 125A. The Ni plating layer (thickness: 5. m) is formed on the surface. The size of support member 125 is 74.0 mm×42.4 mm×3 mm. Installation hole 125E (diameter: 5.6 mm) is provided to the fringing part.

Ceramic base insulating substrate 122 is made by bonding sheet copper 4a (drain combined electrode), 4b (source combined electrode), 4c (for thermistor) of 300. m in thickness, and sheet copper 4d of 250 μm in thickness to both sides of AlN sintered compact 420 (coefficient of thermal expansion:4.3 ppm/° C. and thermal conductivity:160 W/m·K) which has size of 50 mm×30 mm×0.63 mm by using Ag-28 wt % Cu wax (not shown and thickness: 20 μm) to which Ti as the revitalization metal is added by 2 wt %. The Ni layer of 5 μm in thickness is formed on these surfaces by electroless plating. As an alternative thing of AlN sintered compact 12, nitride silicon sintered compact (coefficient of thermal expansion: 3.1 ppm/° C., thermal conductivity: 120 w/m·K) can be used.

The occurrence of something wrong such as the outflow of solder layer 5 or 5′ and the displacement of parts 6, 340 etc. can be prevented even when semiconductor device base body 6 overheats when semiconductor device 11 is operated, and solder layer 5 or 5′ melts again according to the above-mentioned configuration. As a result, the predetermined performance of semiconductor device 11 can be maintained.

(Embodiment 21)

Solders 5′ is explained in this embodiment.

FIG. 45 shows a diagrammatic illustration of embodiments of the solders of the present invention.

(a) shows pasty solders 5′ according to a first form. The pasty solders 5, is the composition made by mixing metal powder (particle size: 15-60. m) 5A for matrix metal comprised of Sn-5 wt % Sb alloy (melting point: 230-240° C.) which becomes the matrix metal after heat-treating of soldering, metal powder (particle size: 15-50 μm and melting point: 779° C.) 5B for dispersion which contains Ag-28 wt % Cu as principal ingredient, and flux material 5C which contains organic substance [weight ratio: WW rosin (100)-adipic acid (1)-tori ethanol amine (1)-aniline hydrochloride (2)]. The amount of addition of the flux material 5C to solders 5′ is about 11 wt %.

Moreover, the amount of addition is adjusted so that metal powder 5B for dispersion may occupy 50 vol % after heat-treating of soldering, and the amount of addition is adjusted so that metal powder 5A for the matrix metal may also occupy 50 vol % after heat-treating of soldering. Paste solders 5′ explained above is supplied to the desired connection part by the print method and the dispense method, etc. The soldering processing is done in the foaming gas where hydrogen is added to nitrogen, in nitrogen, or in air. Flux material 5C plays the role to remove the surface oxide as well as the surface cleaning in the metalized area of metal powder 5A for the matrix metal, metal powder 5B for dispersion, parts to be coupled, and the substrate to be connected.

For instance, material (Cu) to be connected is made clean by the following reaction for the organic amine hydrochloride system flux material 5C.
2R.NH2.HCl+CuO→CuCl2+2RNH2+H2O (1)
2CuCl2+Sn (melted tin)→SnCl4+2Cu (2)

Moreover, the material of the following models can be used for instance for the flux material 5C.
(1) Made of Senju Metal Industry Co., Ltd.——-Sparkle flux
   PO—F-1010S, PO—F-1010K, ES-1040, PO—F-009M, PO—F-710, ZR-86, ZR-93, SR-209, SR-12, WF-3041, WF-2050,T-1
(2) Made of Nihon Superior Co., Ltd.
   NS-827, NS-828A, NS-828B, NS-828B-ne, NS-829, NS-501A, NS-316F-6, NS-316F-7, NS-316F-8, NS-334, RM-5, NS-52, NS-91, NS-30, NS-45, NS-23, NS-22, NS-72, NS-65, RA-3, RA-5, RA-943, RA-51A, RA-51M, RA-51T, RA-A21, RMA-1, RMA-2, RMA-M160, RMA-M293, RMA-M293T, RMA-355T, NC-40, NC-52
(3) Made of Nihon Solder Company
   lappics R, lappics RMA, lappics RA, lappics P5, lappics G150, lappics G130, lappics ZRMA, lappics ZRA, lappics E3, lappics E-6, lappics AX-BP1, lappics 92K, lappics BA-1, lappics SSR-100, lappics SSR-101, lappics SSR-102, lappics CZ7, lappics FW1, lappics AD2, lappics 1000, and lappics 2000
(4) Made of Nihon Almit Company
   HM-1, RMAV14L, SSHA-SN, and A-65.
(5) Made of Solder Coat Company
   TAS-LF221, TAS-LF220, TAS-LF219, TAS-LF217, TAS-LF215, TAS-350, TAS-550, TAS-SH285, TAS-SLL 70, TAS-650, TAS-SM180
(6) Made of Harima Chemicals, Inc.
   F-40, F-50, LF-300, FR-30, FR-38
(7) Made of Tarutin Kester Co., Ltd.
   R-101, R-500, R-501, R-504, HA-78TS-M, HA-90TS-M, L-881, L-570, L571, C-903, S-150
(8) Made of Tamura Kaken Corp.
   EC-19S-8 and EC-15
(9) Made of Tamura Corp.
   ULF-10P, ULF-45, VOF-19, VOC-007V, EC-15, EC-19S
(10) Made of Showa Denko K.K.
   9ZSNO₅M2, 8ZSNO₅M2, 8Z3B05N2
(11) Made of Nihon Filler Metals Co., Ltd.
   M180, K180, M200, A554, AF07, and AZ30
   (b) shows sheet-like or ribbon-like solders 5′ according to a second embodiment. The sheet-like solders 5′ comprises matrix metal 5A comprised of Sn-5 wt % Sb alloy (melting point: 230-240° C.), and metal powder (particle size: 15-50. m and melting point: 779° C.) 5B for dispersion which contains Ag—28 wt % Cu dispersed into metal as principal ingredient. Matrix metal 5A and metal powder 5B for dispersion respectively may occupy 50 vol %, the addition amount is adjusted after heat-treating of soldering. Sheet-like solders 5′ explained above is supplied to lie between materials to be connected, and the soldering processing is done in the foaming gas where hydrogen is added to nitrogen, in nitrogen, or in hydrogen.

The operation, the effect, and the advantage not obtained by the conventional solders as well as the above-mentioned embodiment can be brought according to above-mentioned solders 5′.

Even when metal 5A for matrix comprises the metal comprised of Sn, or the alloy comprised of two kinds or more selected from a group of Sn, Sb, Zn, Cu, Ni, Au, Ag, P, Bi, In, Mn, Mg, Si, Ge, Ti, Zr, V, Hf, Pd, and Pb, and metal powder 5B for dispersion comprises the alloy comprised of one kind of metal or more selected from a group of Sn, Au, Fe, Ge, Mn, Ni, Sb, Si, Zn, Pd, Pt, P, an d Al as well as Ag and/or Cu as the principal ingredient, the same operation, the effect, and the advantage can be obtained.

(Embodiment 22)

In this embodiment, instead of solders 5 used in embodiment 6, different solders 5 is used, where quaternary alloy powder (particle size: 25-90. m and addition amount: 40 vol %) 5B comprised of Sn-40 wt % Sb-10 wt % Ag-Bwt % Cu is distributed to matrix metal PA comprised of Sn-3 wt % Ag-0.5 wt % Cu. As a result, semiconductor device 11 and structural body 15 of FIG. 16 are obtained. Configuration and the manufacturing methods other than the material for solders 5 are the same as embodiment 6. The short circuit rejection rate of structural body 15 of this embodiment is 0.0044%, and this is an excellent yield.

This result suggests that the interface is not flaked off by the cubical expansion and the re-melting of solders 5 according to the second mounting soldering without decreasing the joint power on the contact boundary face between chip parts, wiring patterns 4, substrates 1, and resin layers 10 even in case of being in the state that moisture invades internally through resin layer 10. This is an effect of the addition of Fe-36 wt % Ni alloy powder 5B.

Moreover, it comes to dissolve easily in matrix metal 5A if the composition of four former alloys of this embodiment shifts from a proper range, the effect of the present invention cannot be obtained by the disappearance of the particle form.

However, the same effect as the case of

Sn-40 wt % Sb-10 wt % Ag-8 wt % Cu alloy powder 5B is achieved if the composition is in the range of (25-66) wt % Sn-(22˜70) wt % S-(4.5˜31) wt % Ag-(2.3˜18) wt % Cu.

This embodiment structural body 15 is turned on to the heat cycle test of −40 to 125° C. Here, the circuit function disappearance of semiconductor device 11 based on the crack destruction in solder layer 5 is paid to attention. In the tests up to 2000 times, structural body 15 of this embodiment did not show something wrong due to the disappearance of the circuit function of semiconductor device 11. Moreover, in (25˜66) wt % Sn-(22˜70) wt % Sb-(4.5˜31) wt % Ag-(2.3˜18) wt % Cu alloy powder 5B, similar connection reliability can be maintained.

As explained above, a semiconductor device which can prevent from the outflow of solders, and the short circuit, the disconnecting and the displacement of the chip parts due to the outflow when the semiconductor device where the chip parts are installed on the wiring member by the solders, and the soldered parts are sealed up with resin is installed secondly in an external wiring substrate, a structural body using the semiconductor device, or an electronic equipment using them are provided.

1. A semiconductor device in which a solder layer bonding chip parts and wiring members are enclosed with the resin layer, and the solder layer is comprised of a compound body in which metal powder is distributed in the matrix metal.

2. A semiconductor device in which a solder layer bonding chip parts and wiring members are enclosed with the resin layer, and the solder layer is comprised of a compound body in which metal powder different from said matrix metal is distributed in the matrix metal.

3. A semiconductor device in which a solder layer bonding chip parts and wiring members are enclosed with the resin layer, and the solder layer is comprised of a compound body in which metal powder which has a higher melting point than the melting point of said matrix metal is distributed in the matrix metal.

4. A semiconductor device according to claim 1, wherein said matrix metal is the metal of which the principal ingredient is Sn, or alloy which contains two kinds or more selected from a group of Sn, Sb, Zn, Cu, Ni, Au, Ag, P, Bi, In, M n, Mg, Si, Ge, Ti, Zr, V, Hf, and Pd, and wherein said metal powder is one metal selected from a group of Al, Co, Cr, Cu, Fe, Ge, Mn, Mo, Ni, Sb, Si, W, Zn, Ti, Pd, Ta, Pt, and Ag, or alloy which contains at least one selected from a group of Al, Co, Cr, Cu, Fe, Ge, Mn, Mo, Ni, Sb, Si, W, Zn, Ti, Pd, Ta, Pt, Ag, C, and P.

5. A semiconductor device according to claim 1, wherein said metal powder of particle size 0.05 to 60 μm is added to said matrix metal by 3-75 vol %.

6. A semiconductor device according to claim 1, wherein said resin layer has Young's modules of 90 Pa-50 GPa or coefficient of thermal expansion of 5-9600 ppm/° C.

7. A semiconductor device according to claim 1, wherein said resin layer is at least one selected from a group of epoxy resin, silicone resin, polybutylene terephthalate resin, poly penylene sulfide resin, polyethylene terephthalate resin, silicon gel resin, silicone rubber resin, polyurethane resin, and phenol resin.

8. A semiconductor according to claim 1 wherein said wiring member is one in which metal wiring is provided on the matrix comprises of ceramics, resin or semiconductor.

9. A semiconductor device according to claim 1, wherein a matrix of said wiring member is one kind of ceramics selected from a group of glass ceramics, alumina, nitride aluminum, nitride silicon, glass, and beryllia; or compound resin in which one kind of resin selected from a group of epoxy resin, phenol resin, polyimide resin, bismarade resin, and triazine resin is soaked into one kind of base selected from a group of glass fabric, glass nonwoven cloth, aramid nonwoven cloth, and paper; or film resin selected from a group of polyester, polyimide, and polyimide amid.

10. A semiconductor device according to claim 1, wherein said wiring member is alloy or metal which contains Cu, Fe, Ni, Co, Al as principal ingredient.

11. A semiconductor device according to claim 1, wherein said wiring member is formed like the lead frame.

12. A structural body in which a semiconductor device, in which a solder layer boding chip parts and wiring members are sealed with the resin layer and the solder layer is comprised of a compound body in which metal powder is distributed in the matrix metal, is bonded to an external wiring member through a connection layer.

13. A structural body including a wiring member which has the wiring pattern, chip parts bonded on said wiring pattern of and said wiring member through the solder layer, a resin layer provided to seal said solder layer, an external electrode layer provided to said wiring member, and an external wiring member bonded electrically with said outside electrode layer, wherein said solder layer is comprised of a compound body in which metal powder is distributed in the matrix metal.

14. a structural body according to claim 12 wherein the solder layer is comprised of a compound body in which metal powder different from said matrix metal is distributed in the matrix metal.

15. A structural body according to claim 12, wherein the melting point of said connection layer is lower than that of said solder layer.

16. A structural body according to claim 12, wherein the material of said connection layer is solders.

17. A structural body according to claim 16, wherein the materials of said solder layer and said connection layer are Pb free solders.

18. A structural body according to claim 12,
wherein said outside wiring member is board member of glass epoxy in which epoxy resin is soaked into glass fabric or glass nonwoven cloth; paper phenol in which phenol resin is soaked into paper; paper epoxy in which epoxy resin is soaked into paper; or glass polyimide material in which polyimide is soaked into glass fabric; or composite material in which the external wiring is formed on any one film member of polyester, polyimide and polyimide amid, and
wherein said outside wiring is metal comprised of at least one selected from a group of Ni, Cu, Sn, Sb, Zn, Au, Ag, Pt, and Pd.

19. A structural body according to claim 12, wherein the matrix of said outside wiring member is glass material.

20. A structural body according to claim 12 wherein said matrix metal is metal comprised of Sn, or alloy comprised of two kinds or more selected from a group of Sn, Sb, Zn, Cu, Ni, Au, Ag, P, Bi, In, Mn, Mg, Si, Ge, Ti, Zr, V, Hf, and Pd, and wherein said metal powder is one kind of metal selected from a group of Al, Co, Cr, Cu, Fe, Ge, Mn, Mo, Ni, Sb, Si, W, Zn, Ti, Pd, Ta, Pt, and Ag, or alloy which contains at least one selected from a group of Al, Co, Cr, Cu, Fe, Ge, Mn, Mo, Ni, Sb, Si, W, Zn, Ti, Pd, Ta, Pt, Ag, C, and P.

21. A structural body according to claim 12, wherein said metal powder of particle size 0.05 to 60 μm is added to said matrix metal by 3-75 vol %.

22. An electric equipment in which a semiconductor device, in which a solder layer bonding chip parts and wiring members are enclosed with the resin layer and the solder layer is comprised of a compound body in which metal powder is distributed in the matrix metal, is installed.

23. An electronic equipment in which a structural body in which a semiconductor device, in which a solder layer bonding chip parts and wiring members are sealed with the resin layer and the solder layer is comprised of a compound body in which metal powder is distributed in the matrix metal, is bonded to an external wiring member through a connection layer, is built.

24. An electronic equipment according to claim 1, wherein said metal powder is the alloy which contains Ag or Cu as the principal ingredient, and one or more metals selected from a group of Sn, Au, Fe, Ge, Mn, Ni, Sb, Si, Zn, Pd, Pt, P, Pb, and Al.
